(19) United States
(12) Patent Application Publication
(10) Pub. No.: US 2007/0220902 A1
(43) Pub. Date: Sep. 27, 2007

(54) Thermoelectric Converter

(75) Inventors: Akio Matsuoka, Takahama-city (JP); Isao Kuroyanagi, Anjo-city (JP); Takashi Yamamoto, Okazaki-city (JP); Yukinori Hatano, Okazaki-city (JP); Makoto Uto, Ichinomiya-city (JP); Yasuhiko Niimi, Handa-city (JP); Hirokazu Yoshino, Okazaki-city (JP); Fumiaki Nakamura, Kariya-city (JP); Satoshi Mizutani, Nagoya-city (JP); Jiro Ebihara, Nukata-gun (JP)

Correspondence Address: HARNESS, DICKEY & PIERCE, P.L.C., P.O. BOX 828, BLOOMFIELD HILLS, MI, 48303, US

(73) Assignee: DENSO CORPORATION, KARIYA-CITY AIRCHI-PREF JAPAN (JP)

(21) Appl. No.: 11/597,972

(22) PCT Filed: May 31, 2005
(86) PCT No.: PCT/JP05/09914

§ 371 Date: Nov. 29, 2006

(30) Foreign Application Priority Data
May 31, 2004 (JP) 2004-162384
Sep. 8, 2004 (JP) 2004-261422
Sep. 24, 2004 (JP) 2004-277789
Sep. 24, 2004 (JP) 2004-277795
Oct. 1, 2004 (JP) 2004-290484
Oct. 18, 2004 (JP) 2004-303244
Nov. 25, 2004 (JP) 2004-341162
Feb. 8, 2005 (JP) 2005-032114

(51) Int. Cl. F25B 21/02; H01L 35/30

(52) U.S. Cl. 62/3.3

(57) ABSTRACT

A thermoelectric converter comprises a thermoelectric element assembly that includes a plurality of P-type thermoelectric elements and a plurality of N-type thermoelectric elements which are arranged in a predetermined arrangement pattern; and a heat-exchange element assembly provided with a plurality of heat exchange elements and a retaining plate retaining the plurality of the heat exchange elements, the plurality of the heat exchange elements being retained in a predetermined arrangement condition corresponding to a arrangement condition of the thermoelectric elements. Then, a plurality of joining sites between the thermoelectric element assembly and the heat-exchange element assembly are all together joined by joining members in a state in which the thermoelectric element assembly and the heat-exchange element assembly are stacked on each other.

### FIELD OF THE INVENTION

This invention relates to a thermoelectric converter having N-type thermoelectric elements and P-type thermoelectric elements connected in series.

### BACKGROUND ART

There are conventionally known thermoelectric converters disclosed in Japanese Patent Publication No. 3166228 (U.S. Pat. No. 5,254,178), Japanese Unexamined Patent Publication No. H5-175556, and U.S. Pat. No. 6,521,991.

In the above conventional art, a plurality of N-type thermoelectric elements and a plurality of P-type thermoelectric elements are alternately connected in series. These junctions are lowered or increased in temperature by the Peltier effect depending on the direction of the current passage. The low-temperature area is called a heat-absorbing area or cooling area, and the high-temperature area is called a heat-dissipating area or heating area. The conventional art discloses further the structure in which a member for facilitating heat exchange is mounted on the junction. For example, the structure in which a fin is provided for facilitating heat exchange with air is disclosed. The conventional art discloses also an array of a plurality of thermoelectric elements in a plate form. Further, the structure in which plate-shaped members are placed on the two faces of such an array of thermoelectric elements is disclosed.

However, in the above-described conventional art, because a large number of thermoelectric elements, electrode members and heat-exchanging members are arranged and joined together, an improvement in productivity is difficult. Further, a reduction in size of apparatus makes it difficult to offer the required electric insulation.

It is an object of the present invention to solve the problems associated with the aforementioned conventional art. It is an object of the present invention to improve productivity of a thermoelectric converter. It is an object of the present invention to provide a thermoelectric converter which is excellent at productivity. It is another object of the present invention to provide a thermoelectric converter which ensures the required electric insulation and at the same time, is easily fabricated. The objects of the present invention are achieved by providing a thermoelectric converter of a new structure or a new manufacturing method.

### SUMMARY OF THE INVENTION

To attain the above-described object, technical means described in claim 1 to claim 33 is employed. Specifically, the invention described in claim 1 comprises: a thermoelectric element assembly (10) that includes a plurality of P-type thermoelectric elements (12) and a plurality of N-type thermoelectric elements (13) which are arranged in a predetermined arrangement pattern; a heat-exchange element assembly (20, 30) provided with a plurality of heat exchange elements (22, 32) and a retaining plate (21, 31) retaining the plurality of the heat exchange elements (22, 32), the plurality of heat exchange elements (22, 32) being retained in a predetermined arrangement condition corresponding to a arrangement condition of the thermoelectric elements (12, 13); and a joining member that joins all together a plurality of joining sites between the thermoelectric element assembly (10) and the heat-exchange element assembly (20, 30) in a state in which the thermoelectric element assembly (10) and the heat-exchange element assembly (20, 30) are stacked on each other.

According to the invention described in claim 1, after the thermoelectric element assembly (10) and the heat-exchange element assembly (20, 30) have been constructed, they are stacked and the plurality of the joining sites between them are joined all together, so that the achievement of superior productivity is possible.

In this connection, as the joining member, an adherent member intended for thermal joining, for example, an adhesive, may be used. Also, the joining member may be constituted of a plurality of joining members independent of each other. Alternatively, a plurality of joining sites may be collected and joined. For example, a sheet of plate-shaped adhesive may be used.

Further, as the joining member, an electrically-conductive joining member intended for both the thermal joining and the electrical joining, for example, soldering or the like, may be used. The plurality of the joining sites between the thermoelectric element assembly (10) and the heat-exchange element assembly (20, 30) are set on the P-type thermoelectric elements (12) and the N-type thermoelectric elements (13) connected in series, for example.

Further, the plurality of the joining sites are set between each heat exchange element (22, 32) and each pair of the P-type thermoelectric elements (12) and the N-type thermoelectric elements (13) which are connected in series. The heat exchange element (22, 32) can be provided by use of a material having satisfactory conductivity. It should be noted that when the heat exchange elements (22, 32) are formed of an electrically conductive material, they can be electrically insulated from each other.

Further, the heat-exchange element assembly (20, 30) may be placed only on the heat absorbing side in which the passage of electric current results in a low temperature state or on the heat dissipating side in which it results in a high temperature state. Alternatively, the heat-exchange element assembly (20, 30) may be placed on each of the heat absorbing and heat dissipating sides.

The invention described in claim 2 is characterized in that: the thermoelectric element assembly (10) is provided with a plurality of electrode members (16) making series electrical connection between the plurality of the P-type thermoelectric elements (12) and the plurality of the N-type thermoelectric elements (13); each of the plurality of the heat exchange elements (22, 32) is respectively provided a corresponding one of the plurality of the electrode members (16); and

the joining member is one of a plurality of joining members, each of which joins between a corresponding one of the plurality of the heat exchange elements (22, 32) and a corresponding one of the plurality of the electrode members (16).

According to the invention described in claim 2, after the thermoelectric element assembly (10) has been provided with connection in series and assembled, the heat-exchange element assembly (20, 30) is joined to the thermoelectric element assembly (10), resulting in reliable quality of the assemblies (10, 20, 30).

The invention described in claim 3 is characterized in that: each of the heat exchange elements (22, 32) is provided with an electrode (25, 35), which makes series electrical connection between the plurality of the P-type thermoelectric elements (12) and the plurality of the N-type thermoelectric elements (13), and a heat-exchanger portion (26, 36), which extends from the electrode (25, 35) for heat exchange with a heat exchange medium; and

the joining member joins between the electrode (25, 35) of the heat exchange element (22, 32), one of the P-type thermoelectric elements (12), and one of the N-type thermoelectric elements (13) to each other.

According to the invention described in claim 3, because the electrode (25, 35) is formed integrally with the heat exchange element (12, 13), there is an effect of reducing the thermal resistance or reducing the number of parts. The structure of the invention may be used in conjunction with the thermoelectric element assembly (10) including the plurality of the electrode members (16) electrically connecting in series the plurality of the P-type thermoelectric elements (12) and the plurality of the N-type thermoelectric elements (13) to each other.

The invention described claim 4 is characterized in that: the heat-exchange element assembly (20, 30) includes a heat-absorbing side heat-exchange element assembly (20) placed in a heat absorbing side and a heat-dissipating side heat-exchange element assembly (30) placed in a heat dissipating side; and

the joining member is provided with a first joining member that joins all together a plurality of joining sites between the thermoelectric element assembly (10) and the heat-absorbing side heat-exchange element assembly (20) in a state in which the thermoelectric element assembly (10) and the heat-absorbing side heat-exchange element assembly (20) are stacked on each other, and a second joining member that joins all together a plurality of joining sites between the thermoelectric element assembly (10) and the heat-dissipating side heat-exchange element assembly (30) in a state in which the thermoelectric element assembly (10) and the heat-dissipating side heat-exchange element assembly (30) are stacked on each other.

According to the invention described in claim 4, after both the heat-absorbing side and the heat-dissipating side are structured in advance as the heat-exchange element assemblies (20, 30), they are joined to the thermoelectric element assembly (10). An excellent productivity is able to be achieved. In this structure, the first joining member and the second joining member may be structured to go into the joining state one by one or simultaneously.

The invention described claim 5 is characterized in that: the retaining plate (21, 31) of the heat-exchange element assembly (20, 30) provides a wall for blocking a flow of the heat exchange medium between the heat absorbing side and the heat dissipating side of the thermoelectric element assembly (10).

According to the invention described claim 5, while achieving a high productivity, it is possible to use the member contributing to the increase in productivity to reduce undesired heat transfer between the heat absorbing side and the heat dissipating side. In this connection, as the heat exchange medium, gas or liquid can be used, for example, air, water or the like may be used.

The invention described claim 6 is characterized in that: the thermoelectric element assembly (10) is provided with a retaining plate (11) for retaining the plurality of the P-type thermoelectric elements (12) and the plurality of the N-type thermoelectric elements (13) in the predetermined arrangement pattern, and the retaining plate (11) provides a wall for blocking a flow of the heat exchange medium between the heat absorbing side and the heat dissipating side of the thermoelectric element assembly (10).

According to the invention described claim 6, while achieving a high productivity, it is possible to use the member contributing to the increase in productivity to reduce undesired heat transfer between the heat absorbing side and the heat dissipating side.

The invention described claim 7 is characterized in that: the thermoelectric element assembly (10) is provided with a retaining plate (11) for retaining the plurality of the P-type thermoelectric elements (12) and the plurality of the N-type thermoelectric elements (13) in the predetermined arrangement pattern, and the retaining plate (11) provides a wall for blocking a flow of the heat exchange medium between the heat absorbing side and the heat dissipating side of the thermoelectric element assembly (10); and a predetermined gap is formed as a thermal insulating layer between the heat-exchange element assembly (20, 30) and the retaining plate (11).

The invention described claim 7, while achieving a high productivity, it is possible to use the member contributing to the increase in productivity to reduce undesired heat transfer between the heat absorbing side and the heat dissipating side. In particular, the undesired heat transfer is able to be more reduced by forming the thermal insulating layer between the two walls.

Also, for example, air may be introduced into the thermal insulating layer. The thermal insulating layer may be formed on the two side faces of the thermoelectric element assembly (10) on the heat absorbing side and the heat dissipating side or only on one side face on the heat absorbing side and the heat dissipating side.

The invention described claim 8 is characterized in that: the retaining plate (21) of the heat-absorbing side heat-exchange element assembly (20) provides a heat-absorbing-side wall for blocking a flow of the heat exchange medium between the heat absorbing side and the heat dissipating side of the thermoelectric element assembly (10); the retaining plate (31) of the heat-dissipating side heat-exchange element assembly (30) provides a heat-dissipating-side wall for blocking a flow of the heat exchange medium between the heat absorbing side and the heat dissipating side of the thermoelectric element assembly (10); and a predetermined gap is formed as a thermal insulating layer between the heat-absorbing-side wall and the heat-dissipating-side wall.

The invention described claim 8, while achieving a high productivity, it is possible to use the member contributing to the increase in productivity to reduce undesired heat transfer between the heat absorbing side and the heat dissipating side. In particular, the undesired heat transfer is able to be more reduced by forming the thermal insulating layer between the two walls. Further, even when the thermoelectric element assembly (10) is structured to permit a flow of the heat exchange medium between the heat absorbing side and the heat dissipating side, the thermal insulating layer can be formed between the two retaining plates (21, 31).

The invention described claim 9 is characterized in that: the heat exchange element (22, 32) has a plate-shaped portion extending in a flow direction of the heat exchange medium; the heat exchange portion (26, 36) is formed in the plate-shaped portion and permits a flow of the heat exchange medium between the two faces of the plate-shaped portion; and the retaining plate (21, 31), which retains the heat exchange elements (22, 32), is provided with an aperture for retaining a part of the plate-shaped portion of the heat exchange element (22, 32), in which the heat exchange portion (26, 36) is not formed, wherein the heat exchange portion (26, 36) extends outward beyond an aperture width of the aperture.

According to the invention described claim 9, the heat exchange element (22, 32) includes the heat-exchanger portion (26, 36), thereby promoting the heat exchange with the heat exchange medium. In addition, a high level of the heat exchanging performance can be provided because the heat-exchanger portion (26, 36) can be extended outward beyond the width of the aperture formed in the retaining plate (21, 31) that retains the heat exchange element (12, 13).

The invention described claim 10 is characterized in that a majority of the plurality of the P-type thermoelectric elements (12) and the plurality of the N-type thermoelectric elements (13) is arranged so as to be connected in series in a flow direction of the heat exchange medium.

According to the invention described claim 10, the heat exchange medium flows along the long, narrow heat exchange element (22, 32) serving as an electrical connecting member required for series connection between the P-type thermoelectric element (12) and the N-type thermoelectric element (13). Because the heat exchange element (22, 32) has the heat-exchanger portion (26, 36) extending in the flow direction of the heat exchange medium, it is possible to provide the heat exchange face having the wide surface area along the long, narrow electrical connecting member.

The invention described claim 11 comprises: a thermoelectric element substrate (10) structured in such a way that thermoelectric element groups each formed by arranging a plurality of P-type thermoelectric elements (12) and a plurality of N-type thermoelectric elements (13) in alternate positions are provided in rows in a first insulating substrate (11) made of an insulating material;

a heat-absorbing electrode substrate (20) structured in such a way that a plurality of first heat-absorbing electrode members (22), each of which has a heat-absorbing electrode (25) for making electrical connection between the N-type thermoelectric element (13) and the P-type thermoelectric element (12) which are arranged adjacent to each other, and each of which also has a heat absorbing portion (26) for exchanging heat transferred from the heat-absorbing electrode (25), is arranged in a generally grid form on a second insulating substrate (21) made of an insulating material; and

a heat-dissipating electrode substrate (30) structured in such a way that a plurality of first heat-dissipating electrode members (32), each of which has a heat-dissipating electrode (35) for making electrical connection between the P-type thermoelectric element (12) and the N-type thermoelectric element (13) which are arranged adjacent to each other, and each of which also has a heat dissipating portion (36) for exchanging heat transferred from the heat-dissipating electrode (35), is arranged in a generally grid form on a third insulating substrate (31) made of an insulating material, characterized in that:

the thermoelectric element substrate (10) are assembled to be sandwiched between the heat-absorbing electrode substrate (20) and the heat-dissipating electrode substrate (30) such that the heat-absorbing electrode substrate (20) is structured in such a way that the heat-absorbing electrode (25) makes series connection between the N-type thermoelectric element (13) and the P-type thermoelectric element (12) which are arranged adjacent to each other, and the heat-dissipating electrode substrate (30) is structured in such a way that the heat-dissipating electrode (35) makes series connection between the P-type thermoelectric element (12) and the N-type thermoelectric element (13) which are arranged adjacent to each other.

According to the invention described claim 11, the assembly properties are improved because the thermoelectric elements (12, 13) which are ultra-small components, and the heat-dissipating electrode (35) and heat-absorbing electrode (25) which are connected to the thermoelectric elements (12, 13) are arranged in a generally grid form in the corresponding insulating substrates (11, 21, 31) and structured integrally.

Also, the substrates (10, 20, 30) each structured in one piece are stacked, thereby achieving the series connection between the plurality of the thermoelectric elements (12, 13). In consequence, the assembling working is simpler than that in a conventional method of stacking thermoelectric elements and electrode members in series.

Further, the electrical connection between the adjacent thermoelectric elements (12, 13) and the heat-dissipating electrode (35) or heat-absorbing electrode (25) is able to be implemented directly by interpose the thermoelectric element substrate to define the boundary between the heat absorbing side on one side and the heat dissipating side on the other side, resulting in efficient use of the heat generated at the connection.

The invention described claim 12 is characterized in that: an electrode member (16), which is made of a plate-shaped electrically-conductive material and makes electrical connection between the adjacent thermoelectric elements (12, 13), is joined to both end faces of the adjacent thermoelectric elements (12, 13) in the thermoelectric element substrate (10), and

when the thermoelectric element substrate (10) is assembled to be sandwiched between the heat-absorbing electrode substrate (20) and the heat-dissipating electrode substrate (30), the heat-absorbing electrode substrate (20) is structured in such a way that the heat-absorbing electrode (25) connects in series the N-type thermoelectric element (13) and the P-type thermoelectric element (12), arranged adjacent to each other, through the electrode member (16), and the heat-dissipating electrode substrate (30) is structured in such a way that the heat-dissipating electrode (35) connects in series the P-type thermoelectric element (12) and the N-type thermoelectric element (13), arranged adjacent to each other, through the electrode member (16).

According to the invention described claim 12, because the adjacent thermoelectric elements (12, 13) are joined to the electrode member (16) in series, an electrical test for faulty continuity between the electrode members (16) and the like are possible to be easily achieved only on the thermoelectric element substrate 10. Thus, as compared with the case where a test is carried out after the thermoelectric element substrate (10) is combined with the heat-absorbing electrode substrate (20) and the heat-dissipating electrode substrate (30), it is possible to detect a defective at an early stage and improve the assembly properties.

Further, the electrode member (16) is also an ultra-small component as in the case of the thermoelectric element (12, 13). The plurality of the electrode members (16) are mounted on the thermoelectric elements (12, 13). Hence, the electrode member (16) is structured integrally with the first insulating substrate (11), resulting in the improvement of the assembly properties.

The invention described in claim 13 is characterized in that: an electrode member (16), which is made of a plate-shaped electrically-conductive material and makes electrical connection between the adjacent thermoelectric elements (12, 13) in the thermoelectric element substrate (10) in the heat-absorbing electrode substrate (20), is joined to an end face of the heat-absorbing electrode (25), and an electrode member (16), which is made of a plate-shaped electrically-conductive material and makes electrical connection between the adjacent thermoelectric elements (12, 13) in the thermoelectric element substrate (10), is joined to an end face of the heat-dissipating electrode (35) in the heat-dissipating electrode substrate (30), and

when the thermoelectric element substrate (10) is assembled to be sandwiched between the heat-absorbing electrode substrate (20) and the heat-dissipating electrode substrate (30),

the heat-absorbing electrode substrate (20) is structured in such a way that the heat-absorbing electrode (25) connects in series the N-type thermoelectric element (13) and the P-type thermoelectric element (12), arranged adjacent to each other, through the electrode member (16), and the heat-dissipating electrode substrate (30) is structured in such a way that the heat-dissipating electrode (35) connects in series the P-type thermoelectric element (12) and the N-type thermoelectric element (13), arranged adjacent to each other, through the electrode member (16).

According to the invention described in claim 13, because the plurality of the ultra-small sized electrode members (16) are structured integrally with the first heat-absorbing electrode members (22) and the first heat-dissipating electrode members (32), that is, the second and third insulating substrates (21, 31), the improvement of the assembly properties is achieved.

The invention described in claim 14 is characterized in that: the second insulating substrate (21) and the third insulating substrate (31) are formed by integral molding in such a way that the electrode member (16) is arranged in a generally grid form and a recessed groove (24, 34) is formed in an end face side of the electrode member (16), the heat-absorbing electrode (25) of the heat-absorbing electrode substrate (20) is fitted into the groove (24) and joined to an end face of the electrode member (16), and the heat-dissipating electrode (35) of the heat-dissipating electrode substrate (30) is fitted into the groove (34) and joined to an end face of the electrode member (16).

According to the invention described in claim 14, the integral structure of the electrode members (16), the first heat-absorbing electrode members (22) and the first heat-dissipating electrode members (32), and the second insulating substrate (21) and the third insulating substrate (31) can be facilitated and the alignment of the joining points can be facilitated.

The invention described in claim 15 includes an electrode member (16), which is made of a plate-shaped electrically-conductive material and makes electrical connection between the adjacent thermoelectric elements (12, 13) in the thermoelectric element substrate (10), and an electrode substrate (40) structured in such a way that the plurality of the electrode members (16) are arranged in a generally grid form in a fourth insulating substrate (41) made of an insulating material, are provided, and when the heat-absorbing electrode substrate (20), the electrode substrate (40), the thermoelectric element substrate (10), the electrode substrate (40) and the heat-dissipating electrode substrate (30) are stacked to combine together,

the heat-absorbing electrode substrate (20) is structured in such a way that the heat-absorbing electrode (25) connects in series the N-type thermoelectric element (13) and the P-type thermoelectric element (12), arranged adjacent to each other, through the electrode member (16), and the heat-dissipating electrode substrate (30) is structured in such a way that the heat-dissipating electrode (35) connects in series the P-type thermoelectric element (12) and the N-type thermoelectric element (13), arranged adjacent to each other, through the electrode member (16).

According to the invention described in claim 15, the integral structure of the plurality of the ultra-small sized electrode members (16) with the fourth insulating substrate (41) results in the improvement of the assembly properties.

The invention described in claim 16 is characterized in that the electrode member (16) is shaped to have a thickness greater than each of plate thicknesses of the heat-absorbing electrode (25) formed in the first heat-absorbing electrode member (22) and the heat-dissipating electrode (35) formed in the first heat-dissipating electrode member (32).

According to the invention described in claim 16, the plate thickness of the electrode member (16) is determined depending upon the allowable current passing through the thermoelectric elements (12, 13). The first heat-absorbing electrode member (22) or the first heat-dissipating electrode member (32) having the heat absorbing portion (26) or the heat dissipating portion (36) formed therein has a thickness smaller that that of the electrode member (16), thereby improving the machinability for the heat absorbing portion (26) or the heat dissipating portion (36).

Further, in the case of the combination of the adjacent thermoelectric elements (12, 13) connected in series by the first heat-absorbing electrode member (22) or the first heat-dissipating electrode member (32) without the use of the electrode member (16), the heat-absorbing electrode (25) or the heat-dissipating electrode (35) requires the plate thickness in accordance with the allowable current. In consequence, by providing the electrode member (16), the weight of the first heat-absorbing electrode member (22) and the first heat-dissipating electrode member (32) can be reduced.

The invention described in claim 17 is characterized in that each of the heat-absorbing electrode (25) and the heat-dissipating electrode (35) has a plate-thickness of generally 0.1 to 0.3 mm, but the electrode member (16) has a plate-thickness of at least generally 0.2 to 0.5 mm, which is thicker than that of each of the heat-absorbing electrode (25) and the heat-dissipating electrode (35).

According to the invention described in claim 17, the plate thickness of the above-described values provides an improvement in heat conduction to the heat-exchanger portion for using the heat generated at the joining section.

The invention described in claim 18 is characterized in that the electrode member (16) and the heat-absorbing electrode (25), and the electrode member (16) and the heat-dissipating electrode (35) are joined to each other through insulating coating layers (17) made of an insulating material.

According to the invention described in claim 18, if, for example, an insulating material maintaining a high level of electrical insulating properties and having a low thermal resistance is used, a joining section of a low thermal resistance can be formed, resulting in no reduction in thermoelectric conversion efficiency. In addition, the first heat-absorbing electrode member (22) and the first heat-dissipating electrode member (32) are not required to be subjected to electric insulating treatment or to have a gap providing for electrical insulation from each other.

The invention described in claim 19 is characterized in that: in the first insulating substrate (11) a plurality of engagement holes (14) are formed for alternately arranging the P-type thermoelectric elements (12) and the N-type thermoelectric elements (13) in a generally grid form, and in the thermoelectric element substrate (10) before the heat-absorbing electrode substrate (20) and the heat-dissipating electrode substrate (30) are combined, the plurality of the P-type thermoelectric elements (12) and the plurality of the N-type thermoelectric elements (13) are alternately arranged in the engagement holes (14) to form the rows of the thermoelectric element groups.

According to the invention described in claim 19, structuring the thermoelectric element substrate (10) involves the mounting operation for arranging in alternate positions the plurality of the thermoelectric elements (12, 13) of ultra-small components in the first insulating substrate (11). The first insulating substrate (11) is placed on any one of the electrode substrates (20, 30) such that the engagement holes (14) are aligned with the electrodes (25, 35) of the electrode substrate, and then the thermoelectric elements (12, 13) can be arranged in the engagement holes (14).

Further, for the integral structure of the thermoelectric elements (12, 13), there is a molding method of alternately arranging the thermoelectric elements (12, 13) in a molding die in advance, and then infusing an insulating material, but is not so limited. For example, a robot method may be used to arrange the thermoelectric elements (12, 13) in the engagement holes (14) as in the case of the invention. In this case, the molding die is simple.

The invention described in claim 20 is characterized in that the thermoelectric element substrate (10) is formed by alternately arranging the plurality of the P-type thermoelectric elements (12) each having a rod shape and the plurality of the N-type thermoelectric elements (13) each having a rod shape in a molding die in a generally grid form, then performing a molding process for infusing an insulating material into the molding die to form an uncut thermoelectric element substrate (10a), and then performing a cutting process for cutting the uncut thermoelectric element substrate (10a) into plates each having a desired thickness.

According to the invention described in claim 20, after the thermoelectric elements (12, 13) of ultra-small components have been formed in a rod shape and the uncut thermoelectric element substrate (10a) has been fabricated by the molding process, it is subjected to the cutting process. Thereby, the fabrication of the thermoelectric element substrate (10) is made simple and the use of the rod-shaped thermoelectric elements (12, 13) causes an improvement in assembly properties.

The invention described in claim 21 is characterized in that: as a material forming the first insulating substrate (11), a plurality of sheets having a plurality of grooves (15) extending linearly, in which the P-type thermoelectric elements (12) each having a rod shape and the N-type thermoelectric elements (13) each having a rod shape are alternately arranged, are prepared, and the thermoelectric element substrate (10) is formed by arranging alternately the P-type thermoelectric elements (12) each having a rod shape and the N-type thermoelectric elements (13) each having a rod shape in the grooves (15) of the material, then integrating the plurality of the sheets of the material, which forms the first insulating substrate (11) through joining, and then performing a cutting process to form the first insulating substrate (11) having a desired plate-thickness.

According to the invention described in claim 21, the rod-shaped thermoelectric element (12, 13) has properties relatively sensitive to molding pressure. In terms of this, by use of the joining and cutting processes in addition to the molding process, the fabrication of the thermoelectric substrate (10) can be simplified and the thermoelectric element substrate (10) with higher precision than that described in claim 11 can be structured.

The invention described in claim 22 is characterized in that: convex portions (11b) each having a protrusion shape are formed on both faces of the thermoelectric element substrate (10) between the P-type thermoelectric element (12) and the N-type thermoelectric element (13) which are adjacent to each other, and fitting portions (25b, 35b), which fit with the convex portions (11b), are formed in the heat-absorbing electrode (25) and the heat-dissipating electrode (35); and the first heat-absorbing electrode member (22) and the first heat-dissipating electrode member (32) make the fitting portions (25b, 35b) fit with the convex portions (11b).

According to the invention described in claim 22, by forming the convex portion (11b) and the fitting portion (25b, 35b), the electrical connection between the adjacent thermoelectric elements (12, 13) and the heat-dissipating electrode (35) or the heat-absorbing electrode (25) can be implemented with reliability.

The invention described in claim 23 is characterized in that: the heat-absorbing electrode substrate (20) is structured in such a way that an end face of the second insulating substrate (21) is placed near a joining portion of the heat-absorbing electrode (25), and the heat-dissipating electrode substrate (30) is structured in such a way that an end face of the third insulating substrate (31) is placed near a joining portion of the heat-dissipating electrode (35).

According to the invention described in claim 23, for example, the first heat-absorbing electrode member (22) is structured in such a way that the heat-absorbing electrode (25) is not protruded from the second insulating substrate (21), whereby the heat-absorbing electrode (25) alone is exposed to the thermoelectric elements (12, 13). As a result, the thermoelectric elements (12, 13) themselves generate heat by Joule heating, and the side faces of the thermoelectric elements (12, 13) go into a high temperature state. Hence, because of the convection occurring from the side faces of the thermoelectric elements (12, 13), the amount of heat transfer toward the first heat-absorbing electrode member (22) which is to be at the low temperature side can be reduced. Thereby, the amount of heat absorption at the joining section on the low temperature side is not reduced, resulting in an improvement in thermoelectric conversion efficiency.

The invention described in claim 24 is characterized in that: the heat-absorbing electrode substrate (20) is structured in such a way that one end face of the second insulating substrate (21) is placed to the other end opposite the heat-absorbing electrode (25), and the heat-dissipating electrode substrate (30) is structured in such a way that one end face of the third insulating substrate (31) is placed to the other end opposite the heat-dissipating electrode (35).

According to the invention described in claim 24, since the heat-absorbing electrode (25) and the heat-dissipating electrode (35) produce electrical connecting sections, if the other end of the electrode substrate opposed to the electrodes (25, 35) is joined to the second or third insulating substrate (21, 31), the electrical insulation between the adjacent first heat-absorbing electrode members (22) and the adjacent heat-dissipating electrode members (32) can be implemented with reliability. Further, the other end can be used as a casing member forming an air passage.

The invention described in claim 25 is characterized in that: the thermoelectric element substrate (10) serves as a dividing wall and a casing member (28, 38) is provided to form air duct passages on both sides of the thermoelectric element substrate (10), and the casing member (28, 38) covers either the first heat-absorbing electrode members (22) or the first heat-dissipating electrode members (32).

According to the invention described in claim 25, the heat generated at the heat-absorbing electrodes (25) or the heat-dissipating electrodes (35) is easily separated into a cooling fluid and a fluid to be cooled, and also it is possible to effectively use the heat.

The invention described in claim 26 is characterized in that a whole shape of each of the first heat-absorbing electrode member (22) and the first heat-dissipating electrode member (32) is formed in an approximate U shape, the heat-absorbing electrode (25) of a flat shape or the heat-dissipating electrode (35) of a flat shape is formed on the bottom of the corresponding U shape, and a molding process is perform to form either a louver shape or an offset shape in a flat face extending outward from the heat-absorbing electrode (25) or the heat-dissipating electrode (35).

According to the invention described in claim 26, if the above-described shapes are used, a plurality of heat-absorbing electrodes (25), heat-dissipating electrodes (35) and heat absorbing portions (26), heat dissipating portions (36) can be integrally machined and formed easily from a flat-plate-shaped metal plate by use of plastic working such as a pressing process or plastic working. This makes it possible to improve the productivity of the first heat-absorbing electrode member (22) and the first heat-dissipating electrode member (32).

The invention described in claim 27 is characterized in that, to form the first heat-absorbing electrode member (22) and the first heat-dissipating electrode member (32), a plurality of the heat-absorbing electrodes (25) or a plurality of heat-dissipating electrodes (35) are linked to be formed in a band shape extending along at least the thermoelectric element group, and are joined to the second or third insulating substrate (21, 31), and then the heat-absorbing electrodes (25) or the heat-dissipating electrodes (35) are electrically insulated from each other.

According to the invention described in claim 27, the heat-absorbing electrodes (25) or the heat-dissipating electrodes (35) are linked to each other. As a result, the plurality of the first heat-absorbing electrode members (22) and first heat-dissipating electrode members (32) can be structured in one piece in a band shape at least in a unit of a thermoelectric element group. This facilitates the operation of mounting the first heat-absorbing electrode members (22) and the first heat-dissipating electrode members (32) on the second and third insulating substrates (21, 31).

The invention described in claim 28 is characterized in that: the first heat-absorbing electrode member (22) is constituted of the heat-absorbing electrode (25) formed in a flat-plate shape and a heat-absorbing heat-exchange member (22a) exchanging heat generated at the heat-absorbing electrode (25); the first heat-dissipating electrode member (32) is constituted of the heat-dissipating electrode (35) formed in a flat-plate shape and a heat-dissipating heat-exchange member (32a) exchanging heat generated at the heat-dissipating electrode (35); and the heat-absorbing heat-exchange member (22a) and the heat-dissipating heat-exchange member (32a) are provided on the second or the third insulating substrate (21, 31) to be thermally conductively coupled to the heat-absorbing electrode (25) or the heat-dissipating electrode (35).

According to the invention described in claim 28, if the heat-absorbing electrode (25) and the heat-dissipating electrode (35) are structured independently of the heat-absorbing heat-exchange member (22a) and the heat-dissipating heat-exchange member (22a), at least the heat-absorbing electrode (25) and the heat-dissipating electrode (35) are provided to the second or third insulating substrate (21, 31). This makes it possible to achieve the assembling operation easier than a conventional method of stacking the thermoelectric elements and the electrode members in series.

The invention described in claim 29 is characterized in that: the first heat-absorbing electrode member (22) is structured in such a way that the first heat-absorbing electrode member (22) is divided into at least two or more of the heat-absorbing electrodes (25) and the heat absorbing portions (26), which are formed integrally from a flat-plate-shaped plate material to be disposed as an L shape on the second insulating substrate (21), and each of the heat-absorbing electrodes (25) is pressed into a substrate hole drilled in the second insulating substrate (21) and then is bent along an end face of the second insulating substrate (21), whereby each of the heat-absorbing electrodes (25) is formed and the heat-absorbing electrodes (25) are coupled to each other, and

the first heat-dissipating electrode member (32) is structured in such a way that the first heat-dissipating electrode member (32) is divided into at least two or more of the heat-dissipating electrodes (35) and the heat dissipating portions (36), which are formed integrally from a flat-plate-shaped plate material to be disposed as an L shape on the third insulating substrate (31), and each of the heat-dissipating electrodes (35) is pressed into a substrate hole drilled in the third insulating substrate (31) and then is bent along an end face of the third insulating substrate (31), whereby each of the heat-dissipating electrodes (35) is formed and the heat-dissipating electrodes (35) are coupled to each other.

According to the invention described in claim 29, the heat-absorbing electrode (25) or heat-dissipating electrode (35) and the heat absorbing portion (26) or heat dissipating portion (36), which are divided into at least two or more parts, are formed integrally from a flat-plate-shaped material. Thereby, in particular, the time required for the molding process for forming the heat absorbing portion (26) or heat dissipating portion (36) can be shorter than that of the case where a plurality of portions is formed. As a result, a reduction of the number of manufacturing process-steps can be achieved.

In addition, the number of heat absorbing portions (26) or heat dissipating portions (36) can be easily increased, thereby improving the heat exchange efficiency of the heat absorbing portions (26) or heat dissipating portions (36). Moreover, the heat-absorbing electrodes (25) or heat-dissipating electrodes (35) of the heat absorbing or heat dissipating portions are structured to be pressed into the substrate holes formed in the second insulating substrate (21) or third insulating substrate (31), thereby eliminating the need of hermetic sealing for the gap formed in the substrate hole.

Further, by forming a flat portion on one end face of the second insulating substrate (21) or third insulating substrate (31), if the heat-absorbing electrodes (25) or heat-dissipating electrodes (35) are formed in an L shape, the flatness of the electrode is more easily secured than the case when the electrode is formed in an approximately U shape or an approximately comb-teeth shape, thus increasing the joining area between the thermoelectric elements (12, 13) and the heat-absorbing electrodes (25) or heat-dissipating electrodes (35). In consequence, the improvement of the heat conductive efficiency is achieved, which in turn makes it possible to perform downsizing.

The invention described in claim 30 is characterized in that: the plurality of the heat-absorbing electrodes (25) are coupled to each other through a coupling portion (223) when the heat-absorbing electrode (25) and the heat absorbing portion (26) of the first heat-absorbing electrode member (22) are integrally formed, and the plurality of the heat-dissipating electrodes (35) are coupled to each other through a coupling portion (323) when the heat-dissipating electrode (35) and the heat dissipating portion (36) of the first heat-dissipating electrode member (32) are integrally formed.

According to the invention described in claim 30, a large number of first heat-absorbing electrode members (22) or first heat-dissipating electrode members (32) can be formed in a short time. In consequence, the shape of the invention enables a further reduction in the number of manufacturing process-steps.

The invention described in claim 31 is characterized in that the heat-absorbing electrode substrate (20) is subjected to a potting process using a sealing material made of a resin material applied to a gap between the outer surface of the first heat-absorbing electrode member (22) and the second insulating substrate (21).

According to the invention described in claim 31, the heat absorption causes condensation to occur on the first heat-absorbing electrode member (22), but the condensed water does not flow onto the end face side of the heat-absorbing electrode (25), that is, onto the connecting section side of the thermoelectric elements (12, 13). Thereby, corrosion damage to the thermoelectric elements 12, 13 and the connecting section thereof is prevented. Further, moisture vapor, chemicals, dust, contaminant and the like included in the air flowing through the heat absorbing portion (26) or heat dissipating portion (36), besides the condensed water, are prevented from entering into the area of the thermoelectric elements (12, 13).

The invention described in claim 32 is characterized in that any one of the thermoelectric element substrate (10), the heat-absorbing electrode substrate (20), the heat-dissipating electrode substrate (30) and the electrode substrate (40) is made up of a combination of a plurality of segmented units.

According to the invention described in claim 32, the heat generated at the connecting section of the thermoelectric elements (12, 13) causes heat distortion to appear, but because each of the substrates (10.20, 30, 40) is divided and formed, it is possible to decrease the heat distortion.

The invention described in claim 33 comprises: a plurality of P-type thermoelectric elements (12) and a plurality of N-type thermoelectric elements (13); a heat-absorbing electrode substrate (20) structured in such a way that a plurality of first heat-absorbing electrode members (22), each of which has a heat-absorbing electrode (25) making electrical connection between the N-type thermoelectric element (13) and the P-type thermoelectric element (12) which are arranged adjacent to each other, and a heat absorbing portion (26) for exchanging heat transferred from the heat-absorbing electrode (25), are arranged in a generally grid form on a second insulating substrate (21) made of an insulating material; and a heat-dissipating electrode substrate (30) structured in such a way that a plurality of first heat-dissipating electrode members (32), each of which has a heat-dissipating electrode (35) making electrical connection between the P-type thermoelectric element (12) and the N-type thermoelectric element (13) which are arranged adjacent to each other, and a heat dissipating portion (36) for exchanging heat transferred from the heat-dissipating electrode (35), are arranged in a generally grid form on a third insulating substrate (31) made of an insulating material, characterized in that rows of thermoelectric element group formed by arranging the P-type thermoelectric elements (12) and the N-type thermoelectric elements (13) in alternate positions are provided on one end face of either the heat-absorbing electrodes (25) or the heat-dissipating electrodes (35), and the thermoelectric element group is sandwiched between the heat-absorbing electrode substrate (20) and the heat-dissipating electrode substrate (30) and combined therewith, whereby the heat-absorbing electrode substrate (20) is structured in such a way that the heat-absorbing electrodes (25) connect in series the N-type thermoelectric element (13) and the P-type thermoelectric element (12), arranged adjacent to each other, and the heat-dissipating electrode substrate (30) is structured in such a way that the heat-dissipating electrodes (35) connect in series the P-type thermoelectric element (12) and the N-type thermoelectric element (13), arranged adjacent to each other.

According to the invention described in claim 33, each of the heat-dissipating electrodes (35) or heat-absorbing electrodes (25) connected to at least the thermoelectric elements (12, 13) is placed on the second, third insulating substrate (21, 31), thus making the assembly operation easier than that of the conventional method in which the thermoelectric elements (12, 13) and the first heat-absorbing electrode members (22) or first heat-dissipating electrode members (32) are stacked in series.

Further, because the electrical connection between the adjacent thermoelectric elements (12, 13) and the heat-dissipating electrode (35) or heat-absorbing electrode (25) is able to be implemented directly, the heat generated at the connecting section can be efficiently used.

The invention described in claim 34 is a thermoelectric converter which comprises: a thermoelectric element substrate (10) structured in such a way that a thermoelectric element group formed by arranging a plurality of P-type thermoelectric elements (12) and N-type thermoelectric elements (13) in alternate positions is provided in rows in a first insulating substrate (11) made of an insulating material; and an electrode member (22, 32) having an electrode (25, 35) formed of a flat-plate-shaped electrically-conductive material and making electrical connection between the P-type thermoelectric elements (12) and N-type thermoelectric elements (13) which are arranged adjacent to each other in the thermoelectric element substrate (10), and a heat-exchanger portion (26, 36) for absorbing or dissipating heat transferred from the electrode (25, 35), the plurality of the electrode members (22, 32) being arranged in such a way as to connect each of the electrodes (25, 35) in series to two ends of the P-type thermoelectric elements (12) and N-type thermoelectric elements (13) which are adjacent to each other. The thermoelectric converter is characterized in that the plurality of the electrode members (22, 32) are arranged and temporarily fixed in a generally grid form on a second insulating substrate (21, 31) made of an insulating material to be structured integrally with the second insulating substrate (21, 31), and then the electrodes (25, 35) of the electrode members (22, 32) are simultaneously joined to the end faces of the P-type thermoelectric elements (12) and N-type thermoelectric elements (13) which are adjacent to each other.

According to the invention described in claim 34, the plurality of the electrode members (22, 32) are joined after they have been arranged and temporarily fixed in a generally grid form on the second insulating substrate (21, 31), whereby the electrode members (22, 32) are able to be joined to predetermined positions of a plurality of the thermoelectric elements (12, 13) without coming out of position before they are joined to the thermoelectric elements (12, 13). In consequence, the increase of the reliability of the joining section is achieved.

The invention described in claim 35 is characterized in that the electrode member (22, 32) is structured in such a way that a substrate hole formed in the second insulating substrate (21, 31) is coated with an adhesive, and then the electrode (25, 35) is inserted into the substrate hole and temporarily fixed to the second insulating substrate (21, 31).

According to the invention described in claim 35, specifically, by using an adhesive to temporarily fix the electrode (25, 35), it is possible to prevent occurrence of deviation from alignment before the electrode (25, 35) is joined.

The invention described in claim 36 is characterized in that the electrode member (22, 32) is structured in such a way the electrode (25, 35) is pressed into a substrate hole formed in the second insulating substrate (21, 31) and is temporarily fixed to the second insulating substrate (21, 31).

According to the invention described in claim 36, it is possible to prevent occurrence of deviation from alignment before the electrode (25, 35) is joined. Further, in this case, the structure in which the electrode member (22, 32) has somewhat back-lash with respect to the second insulating substrate (21, 31) when being temporarily fixed may be employed. In this structure, even if the second insulating substrate (21, 31) has somewhat warpage, the pressing can be performed with a pressure evenly applied to the joining section, resulting in an increase in reliability of the joining section.

The invention described in claim 37 comprises: a mounting step of picking up P-type thermoelectric elements (12) and N-type thermoelectric elements (13) and alternately arranging the plurality of the P-type thermoelectric elements (12) and the N-type thermoelectric elements (13) in substrate holes formed in a generally grid form in a first insulating substrate (11) made of an insulating material and placed in advance, so as to provide rows of thermoelectric element groups for a thermoelectric element substrate (10); a molding process step of integrally forming, from a flat-plate-shaped electrically conductive material, an electrode member (22, 32) having a flat-shaped electrode (25, 35) making electrical connection between the P-type thermoelectric element (12) and the N-type thermoelectric element (13) which are arranged adjacent to each other in the thermoelectric element substrate (10), and a heat-exchanger portion (26, 36) for absorbing or dissipating heat transferred from the electrode (25, 35); an electrode-member mounting step of picking up rear faces of the electrodes (25, 35) of the electrode members (22, 32) formed in the molding process step, and inserting or pressing the electrodes (25, 35) into substrate holes formed in a generally grid form in a second insulating substrate (21) made of an insulating material and placed in advance, to arrange the plurality of the electrodes (25, 35) in a generally grid form in a temporary fixing state; and a joining step of disposing each of the electrodes (25, 35) of the electrode members (22, 32), mounted in the electrode-member mounting step, on two ends of the P-type thermoelectric element (12) and the N-type thermoelectric element (13) which are arranged adjacent to each other in the thermoelectric element substrate (10), and then of joining the two ends of the N-type thermoelectric element (13) and the electrode (25, 35) to each other by soldering.

According to the invention described in claim 37, by providing the electrode-member mounting step for arranging and temporarily fixing the plurality of the electrodes (25, 35) in a generally grid form before the joining step, the plurality of the electrode members (22, 32) are able to be joined to the predetermined positions of the thermoelectric elements (12, 13) without deviation from alignment occurred before they are joined to the thermoelectric elements (12, 13). Thereby, the reliability of the joining section is increased.

The invention described in claim 38 is characterized in that the electrode-member mounting step is placed in the end of the molding process step, and the electrode member (22, 32) formed in the molding process step is disposed directly in the substrate hole of the second insulating substrate (21, 31).

According to the invention described in claim 38, in a usual manufacturing method using separate steps, finished-products manufactured in a molding process-step are collected temporarily, and then they are mounted in the electrode-member mounting step, but these process-steps can be omitted by continuously linking the molding process step and the electrode-member mounting step, resulting in a substantial reduction in the number of manufacturing process-steps.

The invention described in claim 39 is characterized in that, in the electrode-member mounting step, the electrode member (22, 32) is mounted by coating the substrate hole formed in the second insulating substrate (21, 31) with an adhesive, and inserting the electrode (25, 35) into the substrate hole and temporarily fixing it to the second insulating substrate (21, 31).

According to the invention described in claim 39, specifically, by using an adhesive to temporarily fix the electrode member (22, 32), it is possible to prevent occurrence of deviation from alignment before the electrode member (22, 32) is joined.

The invention described in claim 40 is characterized in that, in the electrode-member mounting step, the electrode member (22, 32) is mounted by pressing the electrode (25, 35) into the substrate hole formed in the second insulating substrate (21, 31) to temporarily fixing it to the second insulating substrate (21, 31).

According to the invention described in claim 40, it is possible to prevent deviation from alignment before the joining. Further, in this case, because the electrode member (22, 32) is temporarily fixed to the second insulating substrate (21, 31) while having somewhat back-lash, even if the second insulating substrate (21, 31) has somewhat warpage, the pressing can be performed with a pressure evenly applied to the joining section, resulting in an increase in reliability of the joining section.

The invention described in claim 41 is characterized in that, in the molding process step, the electrode member (22, 32) is formed from a coiled plate material by shearing, bending and blanking.

According to the invention described in claim 41, the manufacture for forming the plurality of the electrode members (22, 32) can be carried out by use of pressing process and the like, for example. For example, since the electrode (25, 35) and the heat exchange portion (26, 36) are continuously formed as one piece, a reduction in manufacturing costs is possible.

The invention described in claim 42 comprises: a thermoelectric element substrate (10) structured in such a way that a thermoelectric element group formed by arranging a plurality of P-type thermoelectric elements (12) and N-type thermoelectric elements (13) in alternate positions is provided in rows in a first insulating substrate (11) made of an insulating material; and a pair of heat-absorbing and heat-dissipating electrode substrates (20, 30) placed as opposed to each other on both sides of the thermoelectric element substrate (10) and each having a structure in which a plurality of electrode members (22, 32), each of which has an electrode (25, 35) formed in a flat shape for making electrical connection between the P-type thermoelectric element (12) and the N-type thermoelectric element (13) which are arranged adjacent to each other in the thermoelectric element substrate (10), and each of which also has a heat absorbing portion (26, 36) for absorbing or dissipating heat transferred from the electrode (25, 35), is arranged in a generally grid form on a second insulating substrate (21, 31) made of an insulating material, characterized in that the heat-absorbing and heat-dissipating electrode substrates (20, 30) each have a structure in which each of the electrode members (22, 32) is connected in series through each of the electrodes (25, 35) to two ends of the P-type thermoelectric element (12) and the N-type thermoelectric element (13) which are arranged adjacent to each other, and the electrode member (22, 32) is formed in a shape facilitating mounting and fixing of it to the second insulating substrate (21, 31) and structured integrally with the second insulating substrate (21, 31).

According to the invention described in claim 42, the thermoelectric elements (12, 13) and the electrode members (22, 32) are ultra-small components and also are arranged in plural in a grid form, so that the improvement of assembly properties is required. Accordingly, in the invention, the electrode member (22) is formed in a shape facilitating the mounting and fixing of the electrode member to the second insulating substrate (21, 31). Thereby, the mounting of the plurality of the electrode members (22, 32) to the second insulating substrate (21, 31) can be easily performed by using an existing robot apparatus or an existing mount apparatus which is an apparatus for mounting electronic components, or the like, resulting in the improvement of the assembly properties.

Further, the thermoelectric elements (12, 13) and the electrode members (22, 32) connected thereto are formed integrally with the corresponding first and second insulating substrates (11, 21), thus making the assembly operation easier than that of the conventional method in which the thermoelectric elements and the electrode members are stacked in series. In addition, since the electrical connection between the adjacent thermoelectric elements (12, 13) and the electrode members (22, 32) is able to be implemented directly, the heat generated at the connecting section can be efficiently used.

The invention descried in claim 43 is characterized in that a convex protrusion (22a, 32a) extending outward in a direction perpendicular to the electrode (25, 35) is formed in the electrode member (22, 32), and the protrusion (22a, 32a) is pressed into a substrate hole (21a, 31a) formed in the second insulating substrate (21, 31) and mounted and fixed therein, whereby the electrode member (22, 32) is structured integrally with the second insulating substrate (21, 31).

According to the invention described in claim 43, the assembly by an existing manufacture apparatus can be easily performed. Thereby, the improvement of the assembly properties is achieved. For example, an apparatus of picking up the electrode members (22, 32) may be used. For example, an apparatus of adsorbing and picking up the electrode members may be used.

The invention described in claim 44 is characterized in that the electrode member (22, 32) is formed in an approximate C shape of a plate form, and the open end of the electrode member (22, 32) is inserted into a substrate hole (21a, 31a) formed in the second insulating substrate (21, 31), and then is bent along an face of the second insulating substrate (21, 31) to form, mount and fix the electrode (25, 35), whereby the electrode member (22, 32) is structured integrally with the second insulating substrate (21, 31).

According to the invention described in claim 44, the electrodes (25, 35) are able to be obtained by a simple process, bending. Because of this, the assembly by an existing manufacturing apparatus can be facilitated. As a result, the improvement of the assembly properties is achieved.

The invention described in claim 45 is characterized in that the electrode member (22, 32) is formed in an approximate hat shape including the electrode (25, 35) of a flange shape, and the electrode (25, 35) is inserted into a substrate hole (21a, 31a) formed in the second insulating substrate (21, 31) and mounted and fixed therein, whereby the electrode member (22, 32) is structured integrally with the second insulating substrate (21, 31).

According to the invention described in claim 45, the assembly is able to be easily performed. Thereby, the improvement of the assembly properties is achieved.

The invention described in claim 46 comprises: a thermoelectric element substrate (10) structured in such a way that a thermoelectric element group formed by arranging a plurality of P-type thermoelectric elements (12) and N-type thermoelectric elements (13) in alternate positions is provided in rows in a first insulating substrate (11) made of an insulating material; and a pair of heat-absorbing and heat-dissipating electrode substrates (20, 30) placed as opposed to each other on both sides of the thermoelectric element substrate (10) and each having a structure in which a plurality of first electrode members (22, 32), each of which has an electrode (25, 35) making electrical connection between the P-type thermoelectric element (12) and the N-type thermoelectric element (13) which are arranged adjacent to each other in the thermoelectric element substrate (10), and a heat absorbing portion (26, 36) for absorbing or dissipating heat transferred from the electrode, are arranged in a generally grid form on a second insulating substrate (21, 31) made of an insulating material, characterized in that the heat-absorbing and heat-dissipating electrode substrates (20, 30) each have a structure in which each of the electrodes (25, 35) is connected in series to two ends of the P-type thermoelectric element (12) and the N-type thermoelectric element (13) which are arranged adjacent to each other, and an end face of the second insulating substrate (21, 31) is placed around a joining face between the electrode (25, 35) and, the P-type thermoelectric element (12) and the N-type thermoelectric element (13).

According to the invention described in claim 46, since the second insulating substrates (21, 31) are placed as opposed to each other on both sides of the first insulating substrate (11), the first electrode members (32) constituting the high temperature side and the first electrode members (22) constituting the low temperature side are blocked from each other by the first insulating substrate (11), thus inhibiting the heat transfer from the high temperature side to the low temperature side.

Further, by placing one end face of the second insulating substrate (21, 31) near the joining face of the thermoelectric elements (12, 13), it is possible to minimize the surface area of the low-temperature-side first electrode member (22) exposed to the thermoelectric elements (12, 13). For example, the first electrode member (22) can be structured such that the electrode (25) does not protrude from the end face of the second insulating substrate (21). With this structure, the electrode (25) of the first electrode member (22) alone is exposed to the thermoelectric elements (12, 13). Accordingly, it is possible to restrict the amount of heat transfer, caused by convection or radiation from the side faces of the thermoelectric elements (12, 13), to the low-temperature-side first electrode member (22). Thereby, the thermoelectric conversion efficiency can be increased.

The invention described in claim 47 is characterized in that one of the heat-absorbing and heat-dissipating electrode substrates (20, 30), which is provided with the first electrode members (22, 32) having the electrodes (25, 35) on a low temperature side, has an end face of the second insulating substrate (21, 31) placed around the joining face between the electrode (25, 35) and, the P-type thermoelectric element (12) and the N-type thermoelectric element (13).

According to the invention described in claim 47, it is possible to reduce the exposed surface area of the low-temperature-side first electrode member (22).

The invention described in claim 48 is characterized in that, in the heat-absorbing and heat-dissipating electrode substrates (20, 30), a joining face between the electrode (25, 35) and both the P-type thermoelectric element (12) and the N-type thermoelectric element (13) is desirably located away from an end face of the second insulating substrate (21, 31) within a range of a protruding length (L), which is calculated by adding a plate thickness (t1) of the second insulating substrate (21, 31) to a plate thickness (t2) of the electrode (25, 35), and more desirably is located inwardly relative to an end face of the second insulating substrate (21, 31).

According to the invention described in claim 48, a reduction in the amount of heat transfer toward the low-temperature-side first electrode member (22) is made possible. The protrusion length (L) of the first electrode member (22) satisfies the relational expression (t1+t2)>L. More preferably, the first electrode member (22) is structured such that the electrode (25) does not protrude from the end face of the second insulating substrate (21).

The invention described in claim 49 comprises: a thermoelectric element substrate (10) structured in such a way that a thermoelectric element group formed by arranging a plurality of P-type thermoelectric elements (12) and N-type thermoelectric elements (13) in alternate positions is provided in rows in a first insulating substrate (11) made of an insulating material; second electrode members (22a) making electrical connection between the P-type thermoelectric elements (12) and the N-type thermoelectric elements (13) which are arranged adjacent to each other in the thermoelectric element substrate (10); and a pair of metal substrates (20a) that are made of a metal material, placed as opposed to each other on both sides of the thermoelectric element substrate (10), and each have heat-exchanger portions (26) formed on its one face for absorbing or dissipating heat transferred from the second electrode members (22a), characterized in that ends of the P-type thermoelectric element (12) and the N-type thermoelectric element (13) arranged adjacent to each other are connected in series to each other through the second electrode member (22a), and the metal substrates (20a) are each structured in such a way as to form an insulating layer (21a), made of an insulating material, on a position facing the second electrode members (22a), and to join the second electrode members (22a) to the insulating layer (21a).

According to the invention described in claim 49, in the thermoelectric converter of the type in which the metal substrates (301, 303) and the heat-exchanger portions (26) are electrically insulated, the interposition of the first insulating substrate (11) between the metal substrates (301, 303) makes it possible to block the high-temperature-side second electrode members (16) and the low-temperature-side second electrode members (16) from each other with the first insulating substrate (11) to prevent the heat transfer from the high temperature side to the low temperature side. Further, because the insulating layers (305) are formed on the metal substrates (301, 303) and the second electrode members (16) are joined to the insulating layers (305), it is possible to reduce the surface area of the low-temperature-side second electrode member (16) exposed to the thermoelectric elements (12, 13). It is in turn possible to reduce the amount of heat transfer caused by the convection from the side faces of the thermoelectric elements (12, 13) toward the low-temperature-side second electrode member (16). Hence, the amount of heat absorption on the joining section on the low temperature side is not reduced, resulting in the improvement of the thermoelectric conversion efficiency.

The invention described in claim 50 comprises: a thermoelectric element substrate (10) structured in such a way that a thermoelectric element group formed by arranging a plurality of P-type thermoelectric elements (12) and N-type thermoelectric elements (13) in alternate positions is provided in rows in a first insulating substrate (11) made of an insulating material; plate-type electrode members (16) arranged in such a way as to make electrical connection in series between end faces of the P-type thermoelectric elements (12) and end faces of the N-type thermoelectric elements (13) which are arranged adjacent to each other; and a plurality of heat exchange members (432) joined to the electrode members (16) with a thermal conduction capability in such a way as to divide heat generated at a joining face, on which the electrode member (16) and the end faces of the thermoelectric elements (12, 13) are connected to each other, into a plurality of paths from near the joining face for conduction.

According to the invention described in claim 50, a plurality of heat exchange members (432) extending from the respective electrode members (16) is used. Because of this, an increase in the heat exchanging area is possible. Further, heat is able to be dispersed toward the plurality of the heat exchange members (432). In consequence, a reduction in apparatus size is achieved without a reduction in the heat exchange efficiency.

The invention described in claim 50 is characterized in that the heat exchange member (432) is formed in a shape of either a thin-and-flat-shaped plate member (432a) or a rod-shaped pin member (432b), and extends from one face of the electrode member (16).

According to the invention described in claim 51, an increase in the heat exchanging area is possible.

The invention described in claim 52 is characterized in that fastening members (431a, 431b) formed of a rod-shaped electrical insulating material are provided between the plurality of the heat exchange members (432) and electrically insulate them from each other.

According to the invention described in claim 52, it is possible to ensure electrical insulation between the plurality of the heat exchange members (432) provided for increasing the heat exchanging area.

The invention described in claim 53 is characterized in that fastening members (431c, 431d) formed of a plate-shaped electrical insulating material are provided between the plurality of the heat exchange members (432) and electrically insulate them from each other.

According to the invention described in claim 53, electrical insulation between the plurality of the heat exchange members (432) is able to be provided. The fastening member is provided as a plate member in which a groove or a hole of a shape corresponding to the plate member (432a) or the pin member (432b), for example, is formed, and the fastening member receives the heat exchange member (432) at the groove or the hole and fixes it therein.

The invention described in claim 54 comprises: a thermoelectric element substrate (10) structured in such a way that a thermoelectric element group formed by arranging a plurality of P-type thermoelectric elements (12) and N-type thermoelectric elements (13) in alternate positions is provided in rows in a first insulating substrate (11) made of an insulating material; and electrode members (532) each having an electrode (535) formed in a flat shape to make electrical connection between the P-type thermoelectric element (12) and the N-type thermoelectric element (13) which are arranged adjacent to each other in the thermoelectric element substrate (10), and a heat-exchanger portion (536) formed on the electrode (535) with a thermal conduction capability, characterized in that the electrode (535) is joined to the P-type thermoelectric element (12) and the N-type thermoelectric element (13) by soldering.

According to the invention described in claim 54, the thermoelectric elements (12, 13) and the electric members (532) are connected by a simple assembly process-step. Further, the joining by soldering makes it possible to efficiently use the heat generated at the connecting section. Thereby, a reduction in thermal resistance at the connection section is possible, so that the heat exchange efficiency of the apparatus is not decreased.

The invention described in claim 55 is characterized in that the heat-exchanger portion (536) is placed in such a way as to form a space on a rear face of the electrode (535) in a vertical direction.

According to the invention described in claim 55, because the electrode (55) has a space expanding in a vertical direction on its rear face, the use of a mount apparatus which is an apparatus for mounting electronic components such as a semiconductor or a control substrate is possible. Thereby, the assembly properties of the electrode members (532) which are ultra-small components and a large number of which are used are improved.

The invention described in claim 56 is characterized in that any shape of louver, slit, offset, flat and pin shapes is formed on a flat extending outward from the electrode (535) by a molding process to form the heat-exchanger portion (536).

According to the invention described in claim 56, the heat exchange efficiency of the heat-exchanger portion (536) is increased.

The invention described in claim 57 comprises: a molding process step for using a plate-shaped electrically conductive material to form an electrode member (532) that has a flat-shaped electrode (535) making electrical connection between a P-type thermoelectric element (12) and a N-type thermoelectric element (13) arranged adjacent to each other, and a heat-exchanger portion (526) thermally joined to the electrode (535);

a mounting step of picking up the P-type thermoelectric elements (12) and the N-type thermoelectric elements (13) and alternately arranging the P-type thermoelectric elements (12) and the N-type thermoelectric elements (13) in substrate holes formed in advance in a generally grid form in a first insulating substrate (11) made of an insulating material, to provide rows of thermoelectric element groups for a thermoelectric element substrate (10); and

a joining step of picking up a rear face of the electrode (535) of the electrode members (532) formed in the molding process step, then of placing the electrode (535) in a position making connection between the P-type thermoelectric element (12) and the N-type thermoelectric element (13) which are arranged adjacent to each other in the thermoelectric element substrate (10), and then of joining them to each other by soldering.

According to the invention described in claim 57, the thermoelectric elements (12, 13) which are ultra-small components and a large number of which are used are easily handled in the manufacturing process-steps. Further, because the rear face of the electrode (535) is used to pick up the electrode (535), the electrode (535) is easily handled. In consequence, a high level of productivity can be offered.

The invention described in claim 58 is characterized in that the mounting step for the thermoelectric element substrate (10) and the joining step are performed by use of a mount apparatus. According to this invention, the use of the mount apparatus for mounting electronic components causes an improvement in assembly properties.

The invention described in claim 59 is characterized in that, in the molding process step, the electrode member (532) is formed by performing a molding process of shearing, bending or blanking on a plate shaped electrically-conductive material in a coiled form. According to this invention, for example the pressing process or the like can be used to manufacture the electrode members (532). As a result, a reduction in manufacturing costs is possible.

The invention described in claim 60 is characterized in that, in the molding process step, a plate shaped electrically-conductive material is subjected to an etching process to form the heat-exchanger portion (536), and then is subjected to a molding process of bending or blanking to form the electrode member (532). According to this invention, the micromachining can be implemented by the etching process. As a result, the heat exchange member having an accurate shape can be provided at low manufacturing-costs.

The invention described in claim 61 is characterized in that, in the molding process step, a plate shaped electrically-conductive material is subjected to an extruding process to form a sectional portion, and then to blanking to form the electrode member (532). According to this invention, by using the extruding process for forming, a reduction in manufacturing costs is possible.

It should be noted that the parenthesized reference numeral for each of the above-described means indicates a corresponding relation with specific means described in the following embodiments.

### BRIEF DESCRIPTION OF THE DRAWINGS

FIG. 1 is a sectional view illustrating a thermoelectric converter of a first embodiment according to the present invention.

FIG. 2 is an exploded view of the thermoelectric converter of the first embodiment.

FIG. 3 is a partial plan view illustrating an array of thermoelectric elements of the first embodiment.

FIG. 4 is a sectional view of the thermoelectric converter of the first embodiment.

FIG. 5 is an exploded view of a thermoelectric converter of a second embodiment.

FIG. 6 is an exploded view of a heat-absorbing electrode substrate of the second embodiment.

FIG. 7 is an exploded view of a thermoelectric converter of a third embodiment.

FIG. 8 is a sectional view illustrating a thermoelectric converter of a fourth embodiment.

FIG. 9 is a sectional view illustrating a thermoelectric converter of a fifth embodiment.

FIG. 10 is a sectional view of the thermoelectric converter of the fifth embodiment.

FIG. 11 is a sectional view illustrating a thermoelectric converter of a sixth embodiment.

FIG. 12 is a sectional view illustrating a thermoelectric converter of a seventh embodiment.

FIG. 13 is an exploded view of the thermoelectric converter of the seventh embodiment.

FIG. 14 is a sectional view illustrating a thermoelectric converter of an eighth embodiment.

FIG. 15 is a perspective view illustrating the structure of a thermoelectric element substrate of a ninth embodiment.

FIG. 16 is a perspective view illustrating a thermoelectric element substrate of a modified example of the ninth embodiment.

FIG. 17 is a sectional view illustrating a thermoelectric converter of a tenth embodiment.

FIG. 18 is a partial plan view illustrating an array of thermoelectric elements of the tenth embodiment.

FIG. 19 is a sectional view illustrating a thermoelectric converter of an eleventh embodiment.

FIG. 20 is a sectional view illustrating a thermoelectric converter of a twelfth embodiment.

FIG. 21 is a sectional view illustrating a process-step for manufacturing an electrode member of the twelfth embodiment.

FIG. 22 is a sectional view illustrating a process-step for manufacturing the electrode member of the twelfth embodiment.

FIG. 23 is a plan view illustrating the form of a half-manufactured electrode member of the twelfth embodiment.

FIG. 24 is a sectional view illustrating a first heat-absorbing electrode member of the twelfth embodiment.

FIG. 25 is an exploded view illustrating a thermoelectric element substrate of a thirteenth embodiment.

FIG. 26 is a plan view illustrating a thermoelectric element substrate of a fourteenth embodiment.

FIG. 27 is a sectional view illustrating a thermoelectric converter of a fifteenth embodiment.

FIG. 28 is an enlarged sectional view of the thermoelectric converter of the fifteenth embodiment.

FIG. 29 is a sectional view illustrating a side face of the thermoelectric converter of the fifteenth embodiment.

FIG. 30 is a sectional view illustrating a louver of the fifteenth embodiment, which is taken along the A-A line in FIG. 28.

FIG. 31 is a sectional view illustrating thermoelectric elements of the fifteenth embodiment, which is taken along the A-A line in FIG. 27.

FIG. 32 is a diagram illustrating process-steps for manufacturing the thermoelectric converter of the fifteenth embodiment.

FIG. 33 is a sectional view illustrating a side face of a thermoelectric converter of a seventeenth embodiment.

FIG. 34 is a sectional view illustrating a side face of a thermoelectric converter of the seventeenth embodiment.

FIG. 35 is a sectional view illustrating a side face of a thermoelectric converter of an eighteenth embodiment.

FIG. 36 is a sectional view illustrating the front face of the thermoelectric converter of the eighteenth embodiment.

FIG. 37 is a sectional view illustrating a side face of a thermoelectric converter of a nineteenth embodiment.

FIG. 38 is a bottom view illustrating the thermoelectric converter of the nineteenth embodiment.

FIG. 39 is a sectional view illustrating of a thermoelectric converter of a twentieth embodiment.

FIG. 40 is an enlarged sectional view illustrating the thermoelectric converter of the twentieth embodiment.

FIG. 41 is a side view illustrating the thermoelectric converter of the twentieth embodiment.

FIG. 42 is a sectional view illustrating a thermoelectric converter of a twenty-first embodiment.

FIG. 43 is a side view illustrating the thermoelectric converter of the twenty-first embodiment.

FIG. 44 is a bottom view illustrating the thermoelectric converter of the twenty-first embodiment.

FIG. 45 is a sectional view illustrating a thermoelectric converter of a twenty-second embodiment.

FIG. 46 is an enlarged sectional view illustrating an assembly process-step in the twenty-second embodiment.

FIG. 47 is a sectional view illustrating a thermoelectric converter of a twenty-third embodiment.

FIG. 48 is an enlarged sectional view illustrating an assembly process-step in the twenty-third embodiment.

FIG. 49 is a sectional view illustrating a thermoelectric converter of a twenty-fourth embodiment.

FIG. 50 is an exploded view illustrating the thermoelectric converter of the twenty-fourth embodiment.

FIG. 51 is an enlarged sectional view illustrating the thermoelectric converter of the twenty-fourth embodiment.

FIG. 52 is an enlarged sectional view illustrating a thermoelectric converter of a twenty-fifth embodiment.

FIG. 53 is a sectional view illustrating a thermoelectric converter of a twenty-sixth embodiment.

FIG. 54 is a sectional view illustrating a thermoelectric converter of a twenty-seventh embodiment.

FIG. 55 is a sectional view illustrating a thermoelectric converter of a twenty-eighth embodiment.

FIG. 56 is a sectional view illustrating a thermoelectric converter of a twenty-ninth embodiment.

FIG. 57 is a sectional view illustrating a thermoelectric converter of a thirtieth embodiment.

FIG. 58 is a sectional view illustrating a thermoelectric converter of a thirty-first embodiment.

FIG. 59 is a sectional view illustrating a thermoelectric converter of a thirty-second embodiment.

FIG. 60 is a sectional view illustrating a thermoelectric converter of a thirty-third embodiment.

FIG. 61 is a sectional view illustrating a thermoelectric converter of a thirty-fourth embodiment.

FIG. 62 is a sectional view illustrating a thermoelectric converter of a thirty-fifth embodiment.

FIG. 63 is a sectional view illustrating the thermoelectric converter of the thirty-fifth embodiment.

FIG. 64 is an exploded view illustrating the thermoelectric converter of the thirty-fifth embodiment.

FIG. 65 is a diagram illustrating a process-step for manufacturing the thermoelectric converter of the thirty-fifth embodiment.

FIG. 66 is a sectional view illustrating a thermoelectric converter of a thirty-sixth embodiment.

FIG. 67 is a sectional view illustrating the thermoelectric converter of the thirty-sixth embodiment.

FIG. 68 is a sectional view illustrating a thermoelectric converter of a thirty-seventh embodiment.

FIG. 69 is a sectional view illustrating the thermoelectric converter of the thirty-seventh embodiment.

FIG. 70 is a sectional view illustrating the thermoelectric converter of the thirty-seventh embodiment.

FIG. 71 is a sectional view illustrating a thermoelectric converter of a thirty-eighth embodiment.

FIG. 72 is a sectional view illustrating the thermoelectric converter of the thirty-eighth embodiment.

FIG. 73 is a sectional view illustrating the thermoelectric converter of the thirty-eighth embodiment.

FIG. 74 is a sectional view illustrating a thermoelectric converter of a thirty-ninth embodiment.

FIG. 75 is a sectional view illustrating the thermoelectric converter of the thirty-ninth embodiment.

FIG. 76 is a sectional view illustrating the thermoelectric converter of the thirty-ninth embodiment.

FIG. 77 is a perspective view illustrating a thermoelectric converter of a fortieth embodiment.

FIG. 78 is a perspective view illustrating a thermoelectric converter of a forty-first embodiment.

FIG. 79 is a partially enlarged sectional view illustrating a thermoelectric converter of a forty-second embodiment.

FIG. 80 is a plan view illustrating a thermoelectric converter of a forty-second embodiment.

### BEST MODE FOR CARRYING OUT THE INVENTION

Embodiments of a thermoelectric converter according to the present invention will be described below. In the following, a plurality of embodiments according to the present invention are described.

### First Embodiment

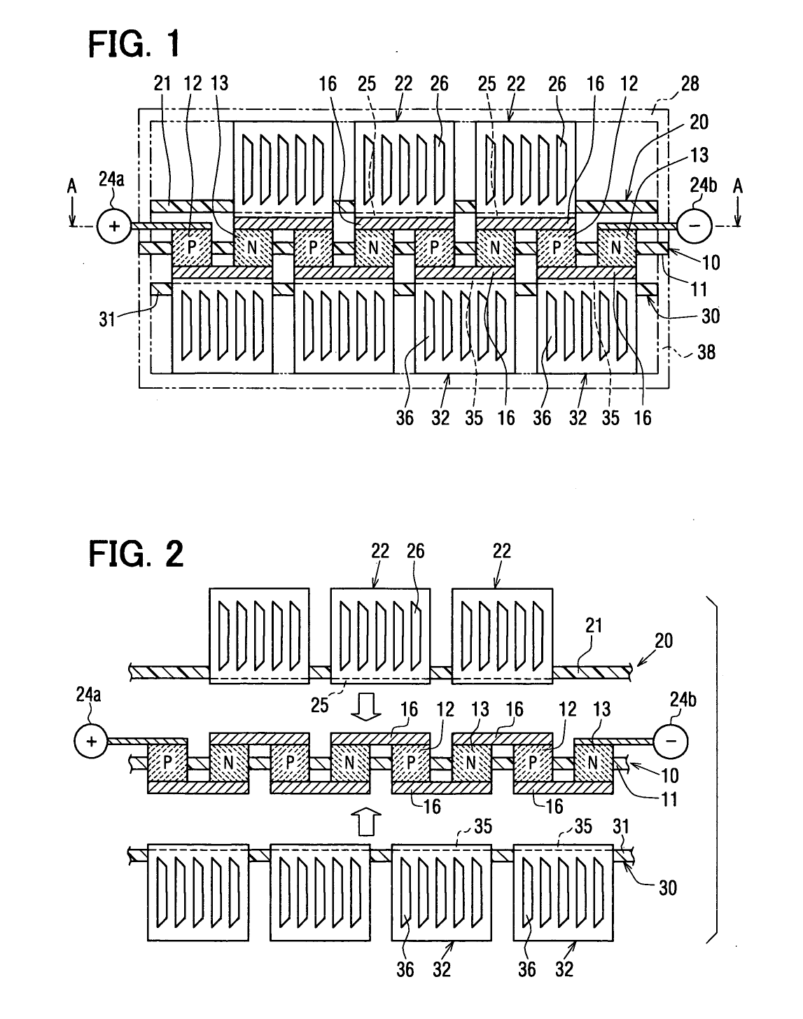

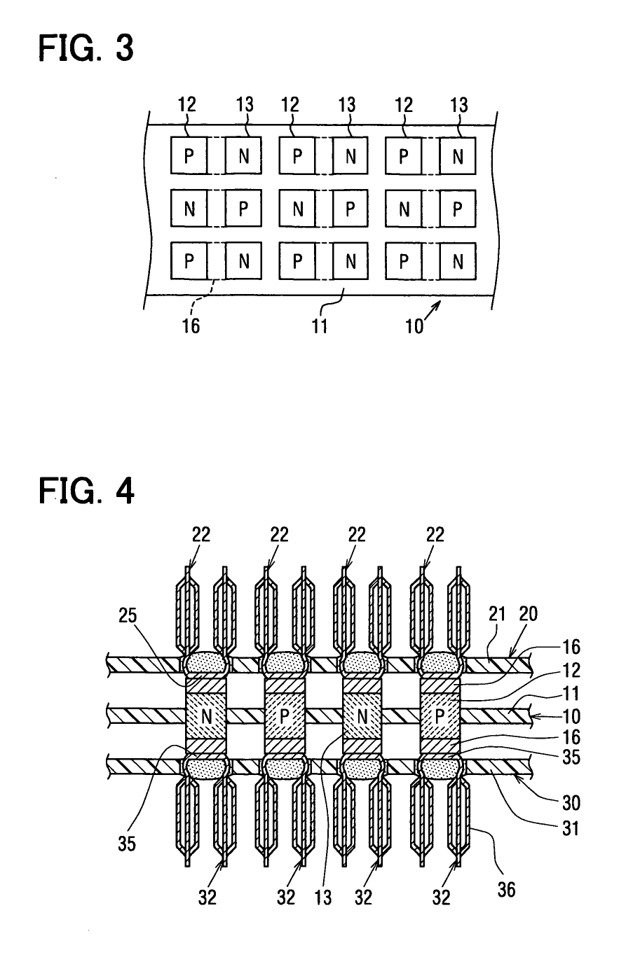

FIG. 1 is a sectional view illustrating the entire structure of a thermoelectric converter in the embodiment. FIG. 2 is an exploded view of the embodiment. FIG. 3 is a partial plan view illustrating an array of thermoelectric elements. FIG. 3 shows a view from the direction indicated by arrows A-A in FIG. 1. FIG. 4 is a sectional view showing a cross section perpendicular to FIG. 1.

The thermoelectric converter is composed of a thermoelectric element substrate 10, a heat-absorbing electrode substrate 20, a heat-dissipating electrode substrate 30, and a pair of casing members 28, 38. The thermoelectric converter can be used to cool air on one side and to heat air on the other side. For example, the thermoelectric converter can be used as part of an air conditioner in a vehicle.

The thermoelectric element substrate 10 is composed of a first insulating substrate 11 serving as a retaining plate, a plurality of P-type thermoelectric elements 12, a plurality of N-type thermoelectric elements 13, and a plurality of electrode members 16.

The P-type thermoelectric element 12 is constituted of a P-type semiconductor formed from a Bi—Te compound. The N-type thermoelectric element is constituted by an N-type semiconductor formed from a Bi—Te compound. The thermoelectric elements 12, 13 are ultra-small components.

The thermoelectric element substrate 10 has the first insulating substrate 11 formed of a plate-shaped electric-insulating material. The first insulating substrate 11 is made of, for example, a glass epoxy, a PPS resin, an LCP resin, a PET resin or the like. The first insulating substrate 11 has a plurality of through holes formed therein. The P-type thermoelectric elements 12 and the N-type thermoelectric elements 13 are respectively received in and fixed to the plurality of through holes. The P-type thermoelectric elements 12 and the N-type thermoelectric elements 13 are arranged in a generally grid form. These thermoelectric elements 12, 13 are formed integrally with the first insulating substrate 11. The P-type thermoelectric elements 12 and N-type thermoelectric elements 13 are formed such that the top end face and the bottom end face of each of them protrude from the first insulating substrate 11. A zigzag current-carrying path is defined on the first insulating substrate 11. The plurality of the P-type thermoelectric elements 12 and the plurality of the N-type thermoelectric elements 13 are arranged in alternate positions along the current-carrying path to form a thermoelectric element group.

The two adjacent thermoelectric elements 12, 13 arranged along the current-carrying path are electrically connected by the electrode member 16 either on the front side or on the rear side of the first insulating substrate 11 to short-circuit them. For example, the electrode member 16 is joined by a conductive material to the front end face of one thermoelectric element 12 and to the front end face of the thermoelectric element 13 adjacent thereto. A plurality of the electrode members 16 are alternately placed so as to make a series connection of the plurality of the thermoelectric elements 12, 13 along the current-carrying path. The electrode member 16 is formed of a plate-shaped conductive metal such as a copper material. The electrode member 16 is a rectangle extending over two thermoelectric elements 12, 13. The joint is provided by solder, for example. For example, after a thin coat of paste solder or the like has been uniformly pre-applied to the end faces of the thermoelectric elements 12, 13 by screen printing, the electrode member 16 is placed on the thermoelectric elements 12, 13. Then they are heated to solder the electrode member 16 to the thermoelectric elements 12, 13. Instead of solder, an adhesive providing a high thermal conductivity may used as a member providing a thermal joint. Alternatively, in order to achieve a plurality of joints collectively, for example, a sheet of adhesive may be used.

The sectional area of the electrode member 16 is determined on the basis of an electric current flowing through the thermoelectric elements 12, 13. In the embodiment, the plate thickness of the electrode member 16 is greater than the plate thickness of a first heat-absorbing electrode member 22 and that of a first heat-dissipating electrode member 32, which will be described later. For example, the plate thickness of the electrode member 16 may be set at about 0.2 mm to 0.5 mm.

The heat-absorbing electrode substrate 20 has a second insulating substrate 21 serving as a retaining plate, and a plurality of the first heat-absorbing electrode members 22 serving as heat exchange elements. The heat-dissipating electrode substrate 30 has a third insulating substrate 31 serving as a retaining plate and a plurality of the first heat-dissipating electrode members 32 serving as heat exchange elements. The second insulating substrate 21 and the third insulating substrate 31 are each formed of a plate insulating material; for example, a glass epoxy, a PPS resin, an LCP resin, a PET resin or the like. The heat-absorbing electrode members 22 are mounted integrally with the second insulating substrate 21. The heat-dissipating members 32 are mounted integrally with the third insulating substrate 31. The heat-absorbing electrode substrate 20 and the heat-dissipating substrate 30 have an approximately symmetrical arrangement. However, the heat-absorbing electrode substrate 20 and the heat-dissipating substrate 30 have differing displacements of the plurality of heat exchange elements provided thereon. In addition, the shape and displacement of various components provided on the heat-absorbing electrode substrate 20 may be different from those on the heat-dissipating substrate 30 because of the displacement of a power supply terminal and the like.

The first heat-absorbing electrode member 22 and the first heat-dissipating electrode member 32 are identical in shape. The electrode members 22, 32 are formed of a thin plate material made of a conductive metal such as a copper material. The electrode members 22, 32 each have an approximate U shape in a cross section as shown in FIG. 4. A flat-shaped heat-absorbing electrode 25 and a flat-shaped heat dissipating electrode 35 are respectively formed at the bottoms of the electrode members 22, 32. The electrodes 25, 35 are joined to the corresponding electrode members 16. Plate-shaped fins extend from the two sides of each of the electrodes 25, 35 in such a way as to stand in an upright position. These fins extend outward. Louvers 26, 36 for promoting the heat exchange with air are formed in the fins. The fins and the louvers constitute a heat exchanger portion. The louvers 26, 36 absorb and dissipate the heat conducted from the heat-absorbing and heat-dissipating electrodes 25, 35. The louvers 26, 36 are formed integrally with the electrodes 25, 35 through a machining process such as a cutting and raising process. As an alternative to the louvers 26, 36 formed by beveling the fin plates, an offset structure in which the fin plates are displaced from each other in parallel may be used.

The first heat-absorbing electrode members 22 and the first heat-dissipating electrode members 32 are arranged such that the bottom face of each of the heat-absorbing electrodes 25 is placed on the electrode member 16 and the bottom face of each of the heat-dissipating electrodes 35 is placed on the electrode member 16. The first heat-absorbing electrode members 22 and the first heat-dissipating electrode members 32 are secured such that end faces of the respective heat-absorbing and heat-dissipating electrodes 25, 35 slightly protrude from end faces of the second insulating substrate 21 and the third insulating substrate 31. The first heat-absorbing electrode member 22 and the first heat-dissipating electrode member 32 which are adjacent to each other are arranged at a predetermined interval so as to be electrically insulated from each other. The first heat-absorbing and heat-dissipating electrode members 22, 32 are arranged in a grid form. The heat-absorbing electrodes 25 of the first heat-absorbing electrode members 22 are joined to the electrode members 16 which are arranged on the upper side in the figure. The heat-dissipating electrodes 35 of the first heat-dissipating electrode members 32 are joined to the electrode members 16 which are arranged on the lower side in the figure.

The first heat-absorbing electrode member 22 and the first heat-dissipating electrode member 32 may each have a plate thickness of about 0.1 mm to 0.3 mm. The thickness of these electrode members is determined in consideration of the workability of forming the louvers 26, 36. The plate thickness of the first heat-absorbing electrode member 22 and the first heat-dissipating electrode member 32 is below that of the electrode member 16 in view of the workability and the heat-exchanging capabilities as a heat exchange member. This structure offers the advantage of a reduction in weight.

The terminations of the thermoelectric elements 12, 13 which are placed at the right and left ends in the figures are respectively connected electrically to terminals 24a, 24b. When the thermoelectric converter is operated, the terminal 24a is connected to the positive terminal of a DC power source (not shown), and the terminal 24b is connected to the negative terminal.

A casing member 28 for forming an air duct passage housing the fin and louver 26 is placed on the upper side in the figure. A casing member 38 for forming an air duct passage housing the fin and louver 36 is placed on the lower side in the figure. Air is sent into the air duct passages from an air blower shown in the figure. For example, the air duct passage placed in the upper side of the figure is for sending air into a room.

With the above structure, the plurality of the P-type thermoelectric elements 12 and the plurality of the N-type thermoelectric elements 13 are electrically connected in series. The electrical connection is achieved mainly by the electrode members 16, and also the first heat-absorbing electrode members 22 and the first heat-dissipating electrode members 32 establish the electrical connection in a supplemental way. The electrode members 16, the first heat-absorbing electrode members 22 and the first heat-dissipating electrode members 32 form a heat transfer member, which thus transfers the low temperature or high temperature generated by the Peltier effect. Further, the first heat-absorbing electrode members 22 and the first heat-dissipating electrode members 32 provide for a capability as a member of heat exchange with air.

For example, upon the connection of the DC power source between the terminals 24a, 24b, the electrode members 16 on the lower side of the figure are brought to a high temperature state by the Peltier effect, while the electrode members 16 on the upper side of the figure are brought to a low temperature state by the Peltier effect. In this case, the fins and louvers 26 on the upper side of the figure constitute a heat-absorbing heat exchanger portion which is the heat-absorbing area, thus cooling the air which is a fluid to be cooled. On the other hand, the fins and louvers 36 on the lower side of the figure constitute a heat-dissipating heat exchanger portion which is the heat-dissipating area, thus dissipating heat into the air which is a cooling fluid.

The method of manufacturing the thermoelectric converter with the above-described structure and the method of assembly are described below. In a process-step, the thermoelectric element substrate 10 is manufactured as a thermoelectric element assembly. In the process-step, a plurality of the thermoelectric elements 12, 13 are arranged and fixed to the first insulating substrate 11. Then, the electrode members 16 are soldered in such a way as to make series electrical connection between the two ends of the adjacent thermoelectric elements 12, 13. These process-steps can be carried out by use of a mount apparatus which is a manufacturing unit for mounting a semiconductor, an electronic component and the like on a circuit substrate. At this stage, the thermoelectric element substrate 10 is subjected to an electrical continuity test. As a result, electrical tests for faulty continuity between a plurality of components and the like are achieved simply by a test only on the thermoelectric element substrate 10. Thus, as compared with the case where a test is carried out after the thermoelectric element substrate 10 is combined with the heat-absorbing electrode substrate 20 and the heat-dissipating electrode substrate 30, it is possible to detect a defective at an early stage and improve the assembly properties in the subsequent process-steps.

Before, after or at the same time as the above process-step, the heat-absorbing electrode substrate 20 and the heat-dissipating electrode substrate 30 which constitute a heat-exchange element assembly are fabricated. The heat-absorbing electrode substrate 20 is fabricated by fitting a plurality of the first heat-absorbing electrode members 22 into substrate holes drilled in the second insulating substrate 21. The heat-dissipating electrode substrate 30 is fabricated by fitting a plurality of the first heat-dissipating electrode members 32 into substrate holes drilled in the third insulating substrate 31. The bottom face of the heat-absorbing electrode 25 is arranged to be approximately flush with or to slightly protrude from the flat face of the second insulating substrate 21. The bottom face of the heat-dissipating electrode 35 is arranged to be approximately flush with or to slightly protrude from the flat face of the third insulating substrate 31.

Next, the heat-absorbing electrode substrate 20 and the heat-dissipating electrode substrate 30 are stacked with the thermoelectric element substrate 10 in between. At this point, each of the heat-absorbing electrodes 25 is disposed on the corresponding electrode member 16, and each of the heat-dissipating electrodes 35 is disposed on the corresponding electrode members 16. In addition, the heat-absorbing electrode 25 and the electrode member 16, and the heat-dissipating electrode 35 and the electrode member 16 are electrically connected to each other so as to allow a heat transfer. In the embodiment, the electrodes 25, 35 and the electrode members 16 are soldered together. After the thermoelectric element substrate 10, the heat-absorbing electrode substrate 20 and the heat-dissipating electrode substrate 30 have been individually assembled in this way, the manufacturing method of sandwiching the thermoelectric element substrate 10 between the heat-absorbing electrode substrate 20 and the heat-dissipating electrode substrate 30 is adopted. In consequence, a reliable electrical connection can be offered through a simple assembly process-step. It should be noted that either the heat-absorbing electrode substrate 20 or the heat-dissipating electrode substrate 30 may be structured without fins. Such structure can be adopted for application to heat exchange based on heat conduction or heat radiation. In the structure, the productivity is improved as in the case of the embodiment.

Then a seal material is applied from the outside of the heat-absorbing electrode substrate 20. The seal material is a resin material of electrical insulating properties. The seal material is applied through the potting process. The seal material provides for air sealing so that when the heat absorption causes moisture condensation, the condensed water is prevented from entering into the electrode member 16. In consequence, it is possible to minimize corrosion damage to the thermoelectric elements 12, 13 and the connecting part therebetween. It is further possible to restrain the entry of moisture vapor, chemicals, dust, contaminant and the like into the area of the thermoelectric elements 12, 13. The seal material may be applied to the outer face of the first heat-absorbing electrode member 22 and the gap between the first heat-absorbing electrode member 22 and the second insulating substrate 21. In addition, the seal material may be applied to a recess formed in the rear face of the heat absorbing electrode to the extent that it fills the recess. The seal material may be also applied to the heat-dissipating electrode substrate 30.

Then, the casing members 28, 38 are mounted. In this structure, the thermoelectric element substrate 10, the heat-absorbing electrode substrate 20 and the heat-dissipating electrode substrate 30 provide a partition wall between the low temperature side and the high temperature side. The partition wall provides functions as a partition wall that blocks an undesired flow between air passages and a partition wall that prevents the heat transfer between the low temperature side and the high temperature side. In addition, an air layer is formed in at least one of the areas between the heat-absorbing electrode substrate 20 and heat-dissipating electrode substrate 30, between the heat-absorbing electrode substrate 20 and thermoelectric element substrate 10, and between the heat-dissipating electrode substrate 30 and thermoelectric element substrate 10. The air layer provides a thermal partition wall between the low temperature side and the high temperature side. In consequence, a thermal barrier between the low temperature side and the high temperature side is fully obtained.

In the thermoelectric converter of the embodiment, because the bottom faces of the first heat-absorbing electrode members 22 alone are exposed from the second insulating substrate 21 in the direction of the thermoelectric elements 12, 13, the heat transfer from the thermoelectric elements 12, 13 to the first heat-absorbing electrode members 22 is able to be suppressed. In addition, the amount of protrusion of the electrode members 22, 32 beyond the insulating substrates 21, 31 can be minimized, and an undesired heat transfer from the thermoelectric elements 12, 13 can be minimized. Further, the provision of the first insulating substrate 11 creates a division between the upper-placed heat-absorbing electrodes 25 and the lower-placed heat-dissipating electrodes 35, resulting in the prevention of heat transfer from the high temperature side to the low temperature side.

In the embodiment, each of the first heat-absorbing electrode members 22 and each of the first heat-dissipating electrode members 32 are manufactured as independent components, and then the electrode members 22, 23 are mounted integrally with the second and third insulating substrates 21, 31. Instead of this structure, a manufacturing process-step using a corrugated component including a plurality of heat-absorbing electrodes 25 or heat-dissipating electrodes 35 may be adopted. In this process-step, a corrugated component provides a plurality of electrode members 22, 32 corresponding to a plurality of thermoelectric element groups arranged at least in a row. For example, a process-step of assembling the corrugation-shaped component to the insulating substrates 21, 31 and then cutting the corrugation-shaped component to divide it into the plurality of the electrode members 22, 32 is able to be adopted. This process-step makes it possible to use a relatively simple technique such as roller forming to mold the first heat-absorbing electrode members 22 and the first heat-dissipating electrode members 32. Further, a plurality of the first heat-absorbing electrode members 22 and first heat-dissipating electrode members 32 are obtained by use of a single corrugated component, so that the assembly operation to the second and third insulating substrates 21, 31 is facilitated.

In the embodiment, the first heat-absorbing electrode members 22 and the first heat-dissipating electrode members 32 are incorporated into the substrate holes drilled in the second and third insulting substrate 21, 31. As an alternative to this, a plurality of the first heat-absorbing electrode members 22 and a plurality of the first heat-dissipating electrode members 32 may be arranged, and then the second insulating substrate 21 and the third insulating substrate 31 may be integrally formed by use of insert molding, for example.

The positive terminal of the DC power source may be connected to the terminal 24b and the negative terminal to the terminal 24a. In this case, however, the upper side in the figure forms the heat-dissipating heat exchanger portion and the lower side in the figure forms the heat-absorbing heat exchanger portion.

The present invention may include the following embodiments. The possibility of modification of the components in the first embodiment is demonstrated by the embodiment described below. In the descriptions of the following embodiments, the components having functions or shapes identical to those of the components described in the foregoing first embodiment are indicated with the same reference numerals and the description is omitted.

### Second Embodiment

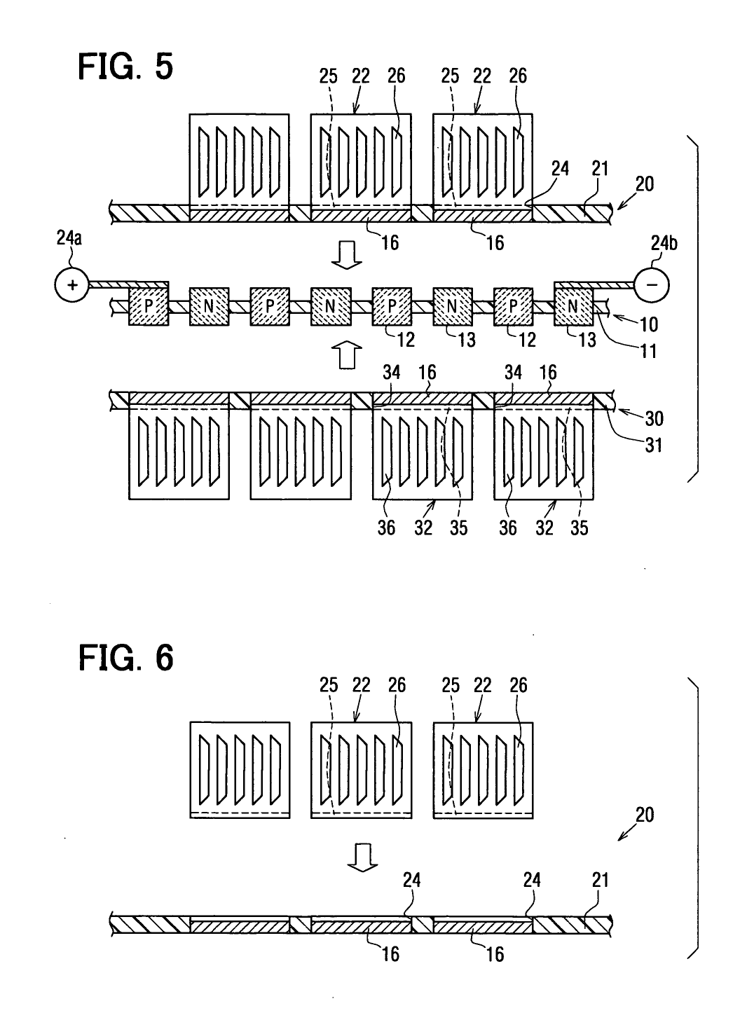

In the foregoing first embodiment, the electrode members 16 are integral with the thermoelectric element substrate 10. As an alternative to this, in the second embodiment illustrated in FIG. 5 and FIG. 6, the electrode members 16 are integrally assembled to the heat-absorbing electrode substrate 20 and the heat-dissipating electrode substrate 30.

In FIG. 5 and FIG. 6, the heat-absorbing electrode substrate 20 includes the electrode members 16 joined to the heat-absorbing electrodes 25 of the first heat-absorbing electrode members 22. Likewise, the heat-dissipating electrode substrate 30 includes the electrode members 16 joined to the heat-dissipating electrodes 35 of the first heat-dissipating electrode members 32. This structure is achieved by inserting the first heat-absorbing electrode members 22 and the electrode members 16 into holes 24 of the second insulating substrate 21, and also by inserting the first heat-dissipating electrode members 32 and the electrode members 16 into holes 34 of the third insulating substrate 31. The thermoelectric element substrate 10 without the electrode members 16 is placed between the heat-absorbing electrode substrate 20 and the heat-dissipating electrode substrate 30 to form a stack, and then the electrode members 16 and the thermoelectric elements 12, 13 are connected.

In the embodiment, the electrode member 16 barely protrudes beyond the flat face of the second insulating substrate 21. Also, the electrode member 16 barely protrudes beyond the flat face of the third insulating substrate 31. In consequence, an undesired heat transfer from the side face of the electrode member 16 is reduced.

As shown in FIG. 6, when the second insulating substrate 21 is fabricated, the electrode members 16 may be formed by the insert molding, and then the first heat-absorbing electrode members 22 may be inserted into the holes 24. Likewise, when the third insulating substrate 31 is fabricated, the electrode members 16 may be formed by the insert molding, and then the first heat-dissipating electrode members 32 may be inserted.

### Third Embodiment

In this embodiment, electrode substrates 40 are provided between the thermoelectric element substrate 10 and the heat-absorbing electrode substrate 20 and between the thermoelectric element substrate 10 and the heat-dissipating electrode substrate 30. The plurality of the electrode members 16 are arranged in the electrode substrates 40. The electrode substrates 40 retain the plurality of the electrode members 16.

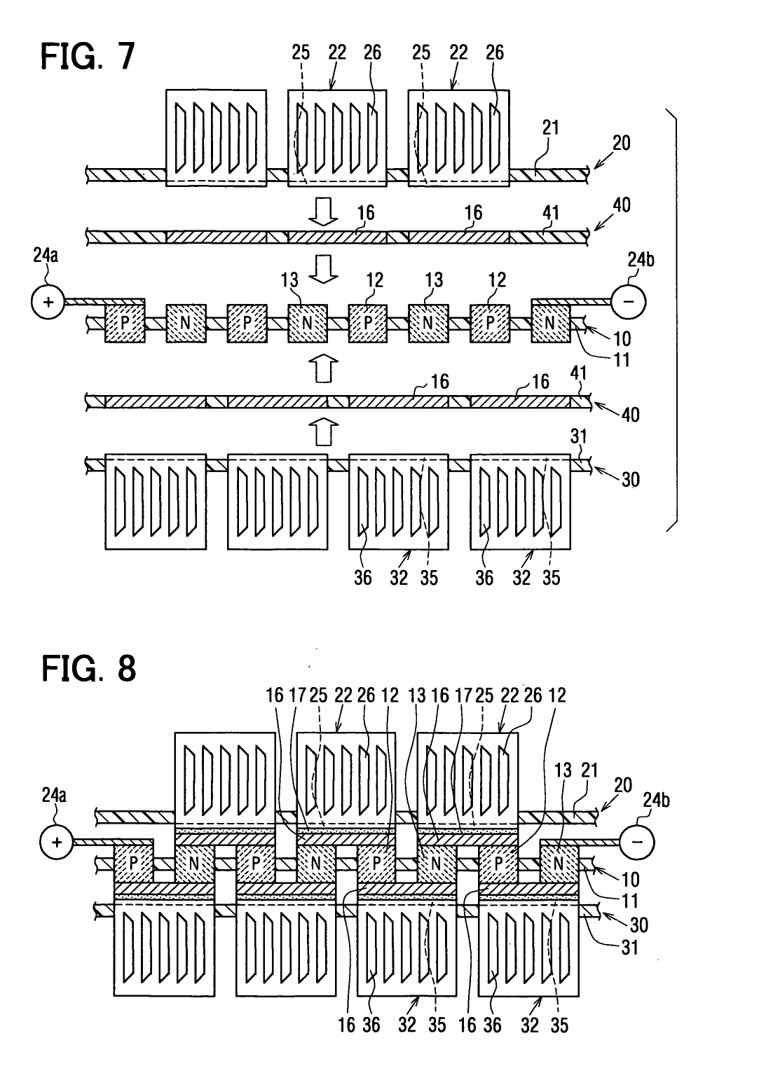

As illustrated in FIG. 7, the electrode substrate 40 has the plurality of the electrode members 16 joined in a fourth insulating substrate 41 made of an electric-insulating material by insert molding. For assembly, the plurality of the electrode members 16 may be inserted into holes in the fourth insulating substrate 41. This embodiment also uses the thermoelectric element substrate 10 with an array of the thermoelectric elements 12, 13 alone. In this embodiment, the heat-absorbing electrode substrate 20, the electrode substrate 40, the thermoelectric element substrate 10, the electrode substrate 40 and the heat-dissipating electrode substrate 30 are stacked in this order. Each of the components is arranged in a predetermined positional relationship in such a way as to provide an electrical and thermal connection similar to that in the embodiment described earlier. According to this embodiment, the handling of the plurality of the electrode members 16 is made easy and an improvement of assembly properties is achieved.

### Fourth Embodiment

In the above embodiment, solder is used for forming a joint between the electrode member 16 and the heat-absorbing electrode 25 and a joint between the electrode member 16 and the heat-dissipating electrode 35. In this embodiment, insulating layers are provided respectively between the electrode member 16 and the heat-absorbing electrode 25 and between the electrode member 16 and the heat-dissipating electrode 35.

As illustrated in FIG. 8, an insulating coating layer 17 formed of an insulating film having an electric-insulating effect is formed on one face of the electrode member 16. The insulating coating layer 17 can be applied by the lamination of an insulating film. The material of the insulating coating layer 17 is selected in view of its outstanding electrical insulating property and an outstanding heat transfer property. Instead of the insulating film, a layer formed through a depositing process-step such as one using a ceramics coating or an insulating electro-deposition coating may be used as the insulating coating layer. Alternatively, an insulating coating or an oxide layer may be formed only on the surface of the electrode member 16.

With this structure, the electric insulation in the first heat-absorbing electrode member 22 and the first heat-dissipating electrode member 32 can be simplified or omitted.

### Fifth Embodiment

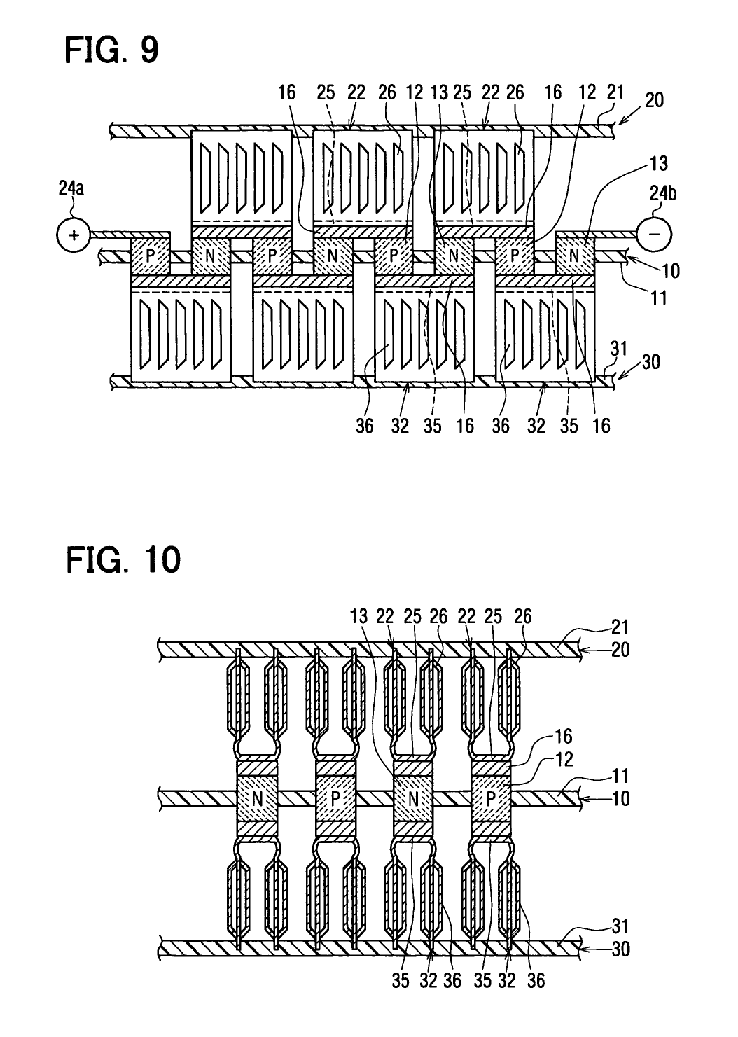

FIG. 9 and FIG. 10 illustrate a fifth embodiment according to the present invention. In this embodiment, the second insulating substrate 21 and the third insulating substrate 31 are arranged at the ends at a distance from the thermoelectric elements 12, 13. The heat-absorbing electrode substrate 20 is structured such that the second insulating substrate 21 is arranged at the ends of the first heat-absorbing electrode members 22 opposite the heat-absorbing electrodes 25. The heat-dissipating electrode substrate 30 is structured such that the third insulating substrate 31 is placed at the ends of the first heat-dissipating electrode members 32 opposite the heat-dissipating electrodes 35. The second insulating substrate 21 retains the plurality of the first heat-absorbing electrode members 22. The third insulating substrate 31 retains the plurality of the first heat-dissipating electrode members 32. In the structure, the second insulating substrate 21 and the third insulating substrate 31 form an air passage.

### Sixth Embodiment

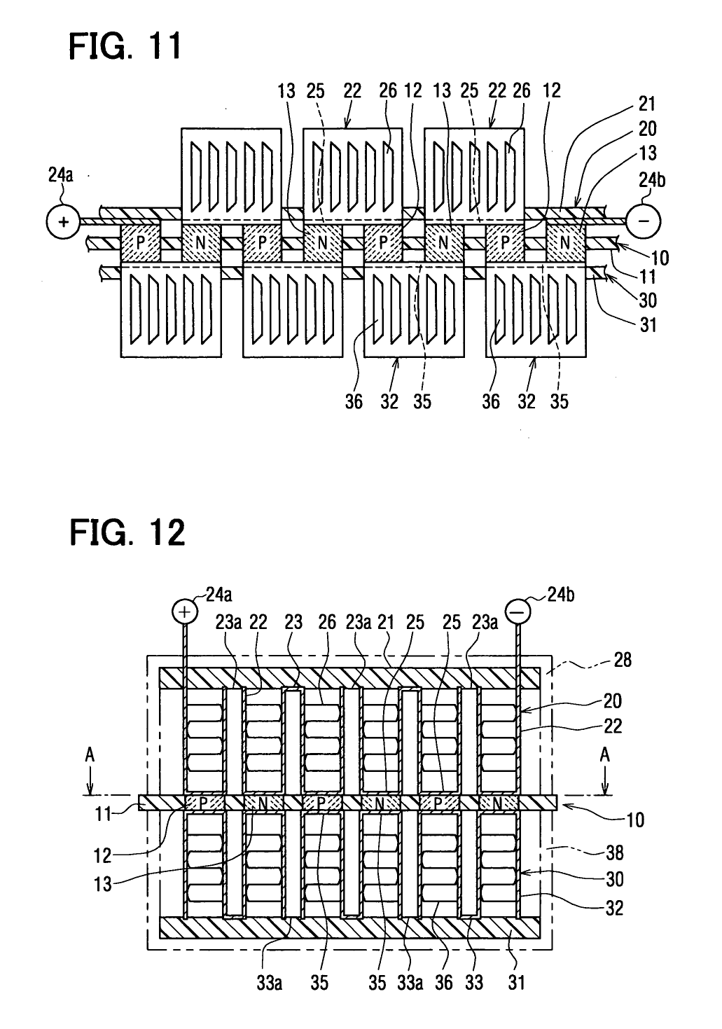

FIG. 11 is a sectional view illustrating a sixth embodiment according to the present invention. This embodiment does not provide the electrode members 16, and uses only the heat-absorbing electrodes 25 and the heat-dissipating electrodes 35 which are respectively formed integrally with fins as a heat exchange member to join the adjacent thermoelectric elements 12, 13 to each other. The heat-absorbing electrode 25 and the heat-dissipating electrode 35 each have a thickness required for minimizing the electric resistance. The structure makes it possible to reduce the number of parts. In addition, because of a low thermal resistance at the joint, the thermoelectric conversion efficiency increases.

### Seventh Embodiment

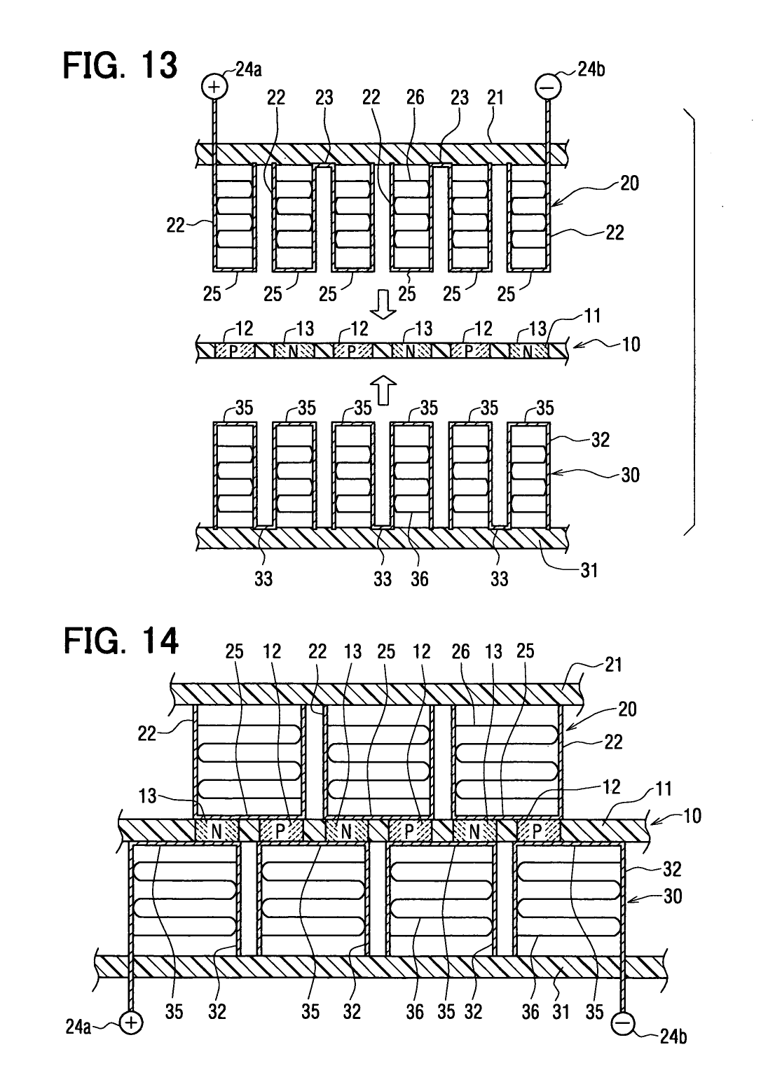

FIG. 12 and FIG. 13 illustrate a seventh embodiment according to the present invention. In this embodiment, the first heat-absorbing electrode members 22 and the first heat-dissipating electrode members 32 are manufactured by use of a plate material made of a conductive metal such as a copper material. The first heat-absorbing electrode members 22 and the first heat-dissipating electrode members 32 are provided entirely as a current-carrying member for the passage of electric current. The first heat-absorbing electrode members 22, and also the first heat-dissipating electrode members 32, are formed in an approximate comb-teeth shape in one piece. The bulk of the plurality of the first heat-absorbing electrode members 22 and the first heat-dissipating electrode members 32 are each shaped as a member having a W-shaped cross section. The W-shaped member is joined to the thermoelectric elements 12, 13 of which the two bottom faces must be mutually connected in series.

Of the first heat-absorbing electrode member 22 and the first heat-dissipating electrode member 32, the first heat-absorbing electrode member 22 will be described. The first heat-absorbing electrode member 22 is formed in a W shape so as to have two heat-absorbing electrodes 25 at its lower end, and have a connecting portion 23 at its upper end for making an electrical connection between the two heat-absorbing electrodes 25. The upper end including the connecting portion 23 is fixed to the second insulating substrate 21. The plurality of the first heat-absorbing electrode members 22 are electrically insulated from each other. A non-connecting portion 23a shown in FIG. 12 provides electrical insulation between adjacent first heat-absorbing electrode members 22. Also, the two first heat-absorbing electrode members 22 placed at the right and left ends in the figures are each formed in a U shape. These first heat-absorbing electrode members 22 respectively have the heat-absorbing electrodes 25 at their lower ends and the terminals 24a, 24b at their upper ends.

The first heat-dissipating electrode member 32 placed in the heat-dissipating electrode substrate 30 is formed as in the case of the above-described first heat-absorbing electrode member 22.

In addition, corrugated fins 26, 36 respectively serving as the heat-absorbing area and the heat-dissipating area are provided in the first heat-absorbing electrode member 22 and the first heat-dissipating electrode member 32. The corrugated fins 26, 36 are formed by bending a metal plate having a satisfactory thermal conductivity such as a copper plate in a ridged pattern.

The first heat-absorbing electrode members 22 and the first heat-dissipating electrode members 32 of the seventh embodiment may be fabricated from a ridged member continuously extending including the non-connecting portions 23a, 33a. For example, a ridged member including a plurality of hills and valleys may be secured to the second insulating substrate 21, and then subjected to the cutting machining to form the non-connecting portions 23a, 33a. This process-step facilitates the assembly working.

### Eighth Embodiment

FIG. 14 illustrates an eighth embodiment according to the present invention. In this embodiment, the first heat-absorbing electrode members 22 and the first heat-dissipating electrode members 32 are each formed in an approximate U shape. The bottom of each of the U shapes is joined to the adjacent thermoelectric elements 12, 13 except for the bottoms of the first heat-dissipating electrode members 32 placed at the two ends. The embodiment has an advantage of offering a simpler structure than that of the embodiment illustrated in FIG. 12 and FIG. 13.

### Ninth Embodiment

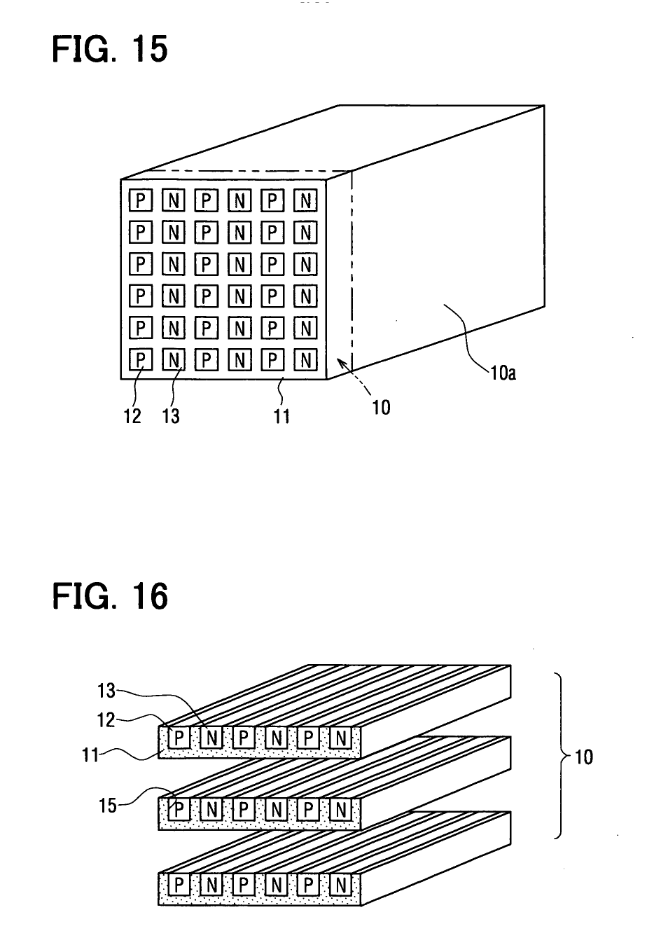

FIG. 15 illustrates a ninth embodiment according to the present invention. FIG. 15 illustrates a method for manufacturing a thermoelectric element array including the first insulating substrate 11 and the thermoelectric elements 12, 13.

First, a plurality of rod-shaped P-type thermoelectric elements 12 and a plurality of rod-shaped N-type thermoelectric elements 13 are prepared. The plurality of the rod-shaped P-type thermoelectric elements 12 and the plurality of the rod-shaped N-type thermoelectric elements 13 are arranged and fixed in alternate positions in a molding tool. Then, an insulating material is injected into the molding tool. As a result, a molding as illustrated in the figure is obtained. The molding is called an uncut thermoelectric element substrate 10a. Next, the molding is sliced into plates of a predetermined thickness. As a result, a plurality of thermoelectric arrays are obtained from a single molding. This facilitates the manufacture of the thermoelectric element substrate 10.

It should be noted that the rod-shaped thermoelectric elements 12, 13 are relatively sensitive to molding pressure. From this point of view, as illustrated in FIG. 16, a plurality of blocks may be stacked to fabricate a molding as shown in FIG. 15. In the embodiment shown in FIG. 16, a plurality of grooves are formed in a plurality of blocks 15 with grooves for arrangement of the rod-shaped P-type thermoelectric elements 12 and the rod-shaped N-type thermoelectric elements 13. The rod-shaped P-type thermoelectric elements 12 and the rod-shaped N-type thermoelectric elements 13 are arranged in the blocks 15 with grooves, and then the blocks 15 are stacked and joined together.

### Tenth Embodiment

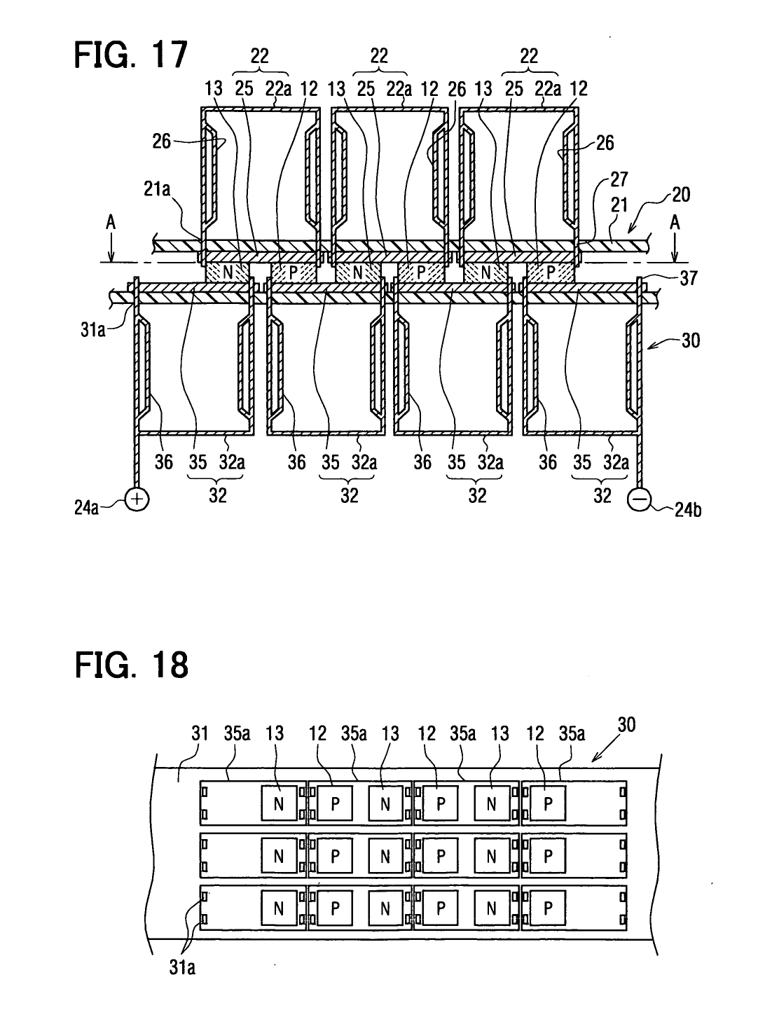

FIG. 17 and FIG. 18 illustrate a tenth embodiment according to the present invention. In this embodiment, the P-type thermoelectric elements 12 and the N-type thermoelectric elements 13 are pre-placed on either the heat-absorbing electrodes 25 or the heat-dissipating electrodes 35 to form a plurality of units, and the plurality of the units are arranged to form a thermoelectric converter.

The heat-absorbing electrode substrate 20 has the first heat-absorbing electrode members 22. Each of the first heat-absorbing electrode members 22 has a flat-plate-shaped heat-absorbing electrode 25 and a heat-absorbing heat-exchange member 22a which is thermally connected to the heat-absorbing electrode 25 for heat exchange with air. The heat-absorbing electrode 25 is fixed to one face of a second insulating substrate 21. The heat-absorbing heat-exchange member 22a is shaped in bracket form. Two arms of the heat-absorbing heat-exchange member 22a extend through the second insulating substrate 21. The two arms of the heat-absorbing heat-exchange member 22a are mechanically and thermally coupled to the two sides of the heat-absorbing electrode 25. The heat-absorbing heat-exchange member 22a has joining portions 27 connected to the heat-absorbing electrode 25. The joining portions 27 extend through the second insulating substrate 21 and the electrode 25 and joining holes 21a are provided for the mechanical and thermal connection.

The heat-dissipating electrode substrate 30 has the first heat-dissipating electrode members 32. Each of the first heat-dissipating electrode members 32 has a flat-plate-shaped heat-dissipating electrode 35 and a heat-dissipating heat-exchange member 32a which is thermally connected to the heat-dissipating electrode 35 for heat exchange with air. The heat-dissipating heat-exchange member 32a has joining portions 37 connected to the heat-dissipating electrode 35. The joining portions 37 extend through the third insulating substrate 31 and the heat-dissipating electrode 35 and joining holes 31a are provided for the mechanical and thermal connection. The first heat-dissipating electrode member 32 has a similar structure to that of the first heat-absorbing electrode member 22.

The thermoelectric elements 12, 13 are arranged and fixed onto the flat face of either the heat-absorbing electrodes 25 or the heat-dissipating electrodes 35. Accordingly, a thermoelectric element group is formed by arranging the P-type thermoelectric elements 12 and the N-type thermoelectric elements 13 on the heat-absorbing electrode substrate 20 or the heat-dissipating electrode substrate 30. In this structure, a structure that sandwiches the thermoelectric element group between the heat-absorbing electrode substrate 20 and the heat-dissipating electrode substrate 30 is also achieved.

Next, a method of assembling the thermoelectric converter will be described. Initially, the heat-dissipating electrode substrate 30 is assembled. Then, the thermoelectric elements 12, 13 are arranged in alternate positions on the heat-dissipating electrodes 35 arranged on the heat-dissipating electrode substrate 30 so as to form a thermoelectric element group. Then, before, after or at the same time as the above process-step, the heat-absorbing electrode substrate 20 is assembled. Then, the heat-absorbing electrode substrate 20 is stacked on the thermoelectric element group. Then, the heat-dissipating heat exchange members 32a and the heat-absorbing heat exchange members 22a are mounted by inserting the junctions 27, 37 into the junction holes 21a, 31a. The resulting assembly is put in a furnace for soldering.

Then, in the high-temperature furnace, soldering produces joints between the plurality of the thermoelectric elements 12, 13 and the heat-dissipating electrodes 35, between the plurality of thermoelectric elements 12, 13 and the heat-absorbing electrodes 25, between the joining portions 27 and the heat-absorbing electrodes 25, and between the joining portions 37 and the heat-absorbing electrodes 25.

It should be noted that, beforehand, the thermoelectric elements 12, 13 may be joined in advance to either the heat-dissipating electrodes 35 or the heat-absorbing electrodes 25. A process-step of mounting such electrodes with the thermoelectric elements onto the insulating substrates 21, 31 may be employed. Also, a plurality of louvers may be used instead of the corrugated fins.

With the thermoelectric converter of the embodiment, the assembly operation is facilitated. In addition, satisfactory thermal conductivity is achieved. Further, the assembly operation for the plurality of the heat exchange members 32a, 22a is facilitated.

### Eleventh Embodiment

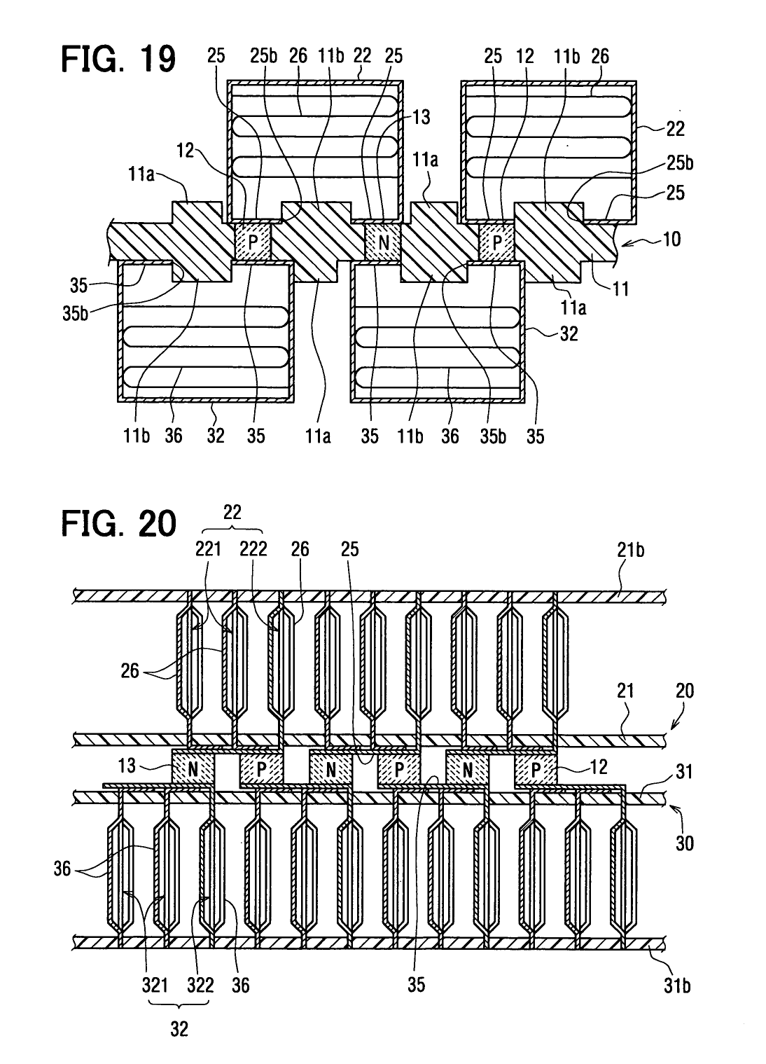

FIG. 19 illustrates an eleventh embodiment. In this embodiment, the first heat-absorbing electrode members 22 and the first heat-dissipating electrode members 32 are fitted to the thermoelectric element substrate 10.

Convex portions 11a, 11b are formed as protrusions from the two faces of the first insulating substrate 11 between the P-type thermoelectric element 12 and the N-type thermoelectric element 13 which are adjacent to each other. Receiving portions 25b, 35b into which the convex portions 11b are fitted are formed in the heat-absorbing electrode 25 and the heat-dissipating electrode 35. The fitting portions 25b, 35b are fitted over the convex portions 11b. The thermoelectric element substrate 10 is situated so as to be sandwiched between the first heat-absorbing electrode members 22 and the first heat-dissipating electrode members 32. It should be noted that the convex portion 11a is a convex portion electrically insulating the first heat-absorbing electrode member 22 and the first heat-dissipating electrode member 32 adjacent to each other.

With the above structure, the first heat-absorbing electrode member 22 and the first heat-dissipating electrode member 32 are positioned by being fitted over the convex portions 11b formed on the thermoelectric element substrate 10. For this reason, it is possible to reliably achieve an electrical connection between the thermoelectric elements 12, 13 fixed in the first insulating substrate 11 and the heat-dissipating electrode 35 and the heat-absorbing electrode 25. The plurality of the first heat-absorbing electrode members 22 and the plurality of the first heat-dissipating electrode members 32 may be coupled by a second insulating substrate and a third insulating substrate as in the cases of the foregoing embodiments.

### Twelfth Embodiment

FIG. 20 to FIG. 22 illustrate a twelfth embodiment according to the present invention. In this embodiment, the first heat-absorbing electrode member 22 is provided by coupling a plurality of members together. A similar structure is used for the first heat-dissipating electrode member 32. The structure of this embodiment may be used for either the first heat-absorbing electrode member 22 or the first heat-dissipating electrode member 32. The first heat-absorbing electrode member 22 will be described below and the corresponding parts of the first heat-dissipating electrode member 32 are indicated by parenthetical reference numerals.

The first heat-absorbing electrode member 22 (32) is formed by joining two second heat-absorbing electrode members 221 (321) and a third heat-absorbing electrode member 222 (322) together. The second heat-absorbing electrode members 221 (321) and the third heat-absorbing electrode member 222 (322) differ from each other in the length of a heat-absorbing electrode 25 (35) and the bending direction. They each have a flat-shaped heat-absorbing electrode 25 (35) and a heat absorbing portion 26 (36) for heat exchange with air. The heat absorbing portion 26 (36) provides a fin and louver. The second heat-absorbing electrode members 221 (321) and the third heat-absorbing electrode member 222 (322) extend through the second insulating substrate 21 (31), are bent in an L shape, and are fixed to the second insulating substrate 21 (31). The length of the heat-absorbing electrode 25 (35) of the third heat-absorbing electrode member 222 (322) can be set at a length extending through the adjacent thermoelectric elements 12, 13. The heat-absorbing electrode 25 (35) of the second heat-absorbing electrode member 221 (321) is set shorter. The heat-absorbing electrodes 25 (35) bent in an L shape and stacked are joined together by solder.

The ends of the second heat-absorbing electrode members 221 (321) and the third heat-absorbing electrode member 222 (322) are inserted into and fixed to grooves or holes formed in a casing member 21b (31b) made of an insulation material, and a space thereof is kept between the electrode members.

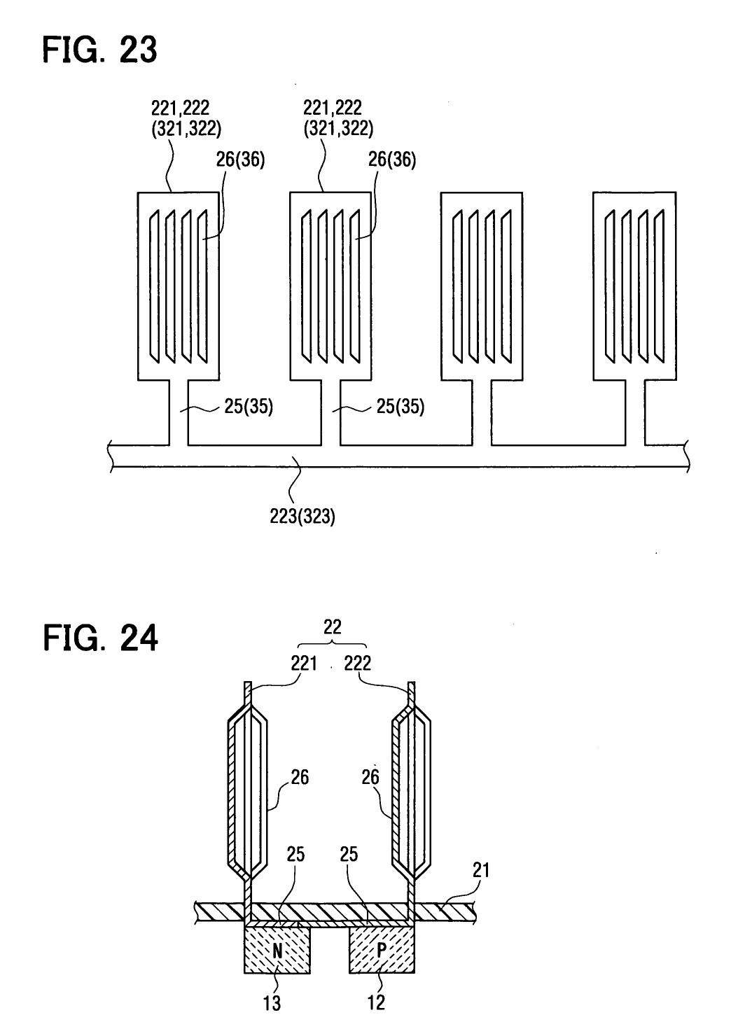

Next, a method for manufacturing the first heat-absorbing electrode member 22 (32) of the above structure will be described with reference to the drawings. First, the second heat-absorbing electrode members 221 (321) and the third heat-absorbing electrode member 222 (322) are fabricated. They are fabricated through a press forming process-step from a coiled electrically-conductive material, for example, copper material. For example, as shown in FIG. 23, a plurality of the electrode members 221, 222 (321, 322) each including the flat-shaped heat-absorbing electrode 25 (35) and the heat absorbing portion 26 (36) having a louver, which are coupled to each other by a coupling portion 223 (323), is fabricated.

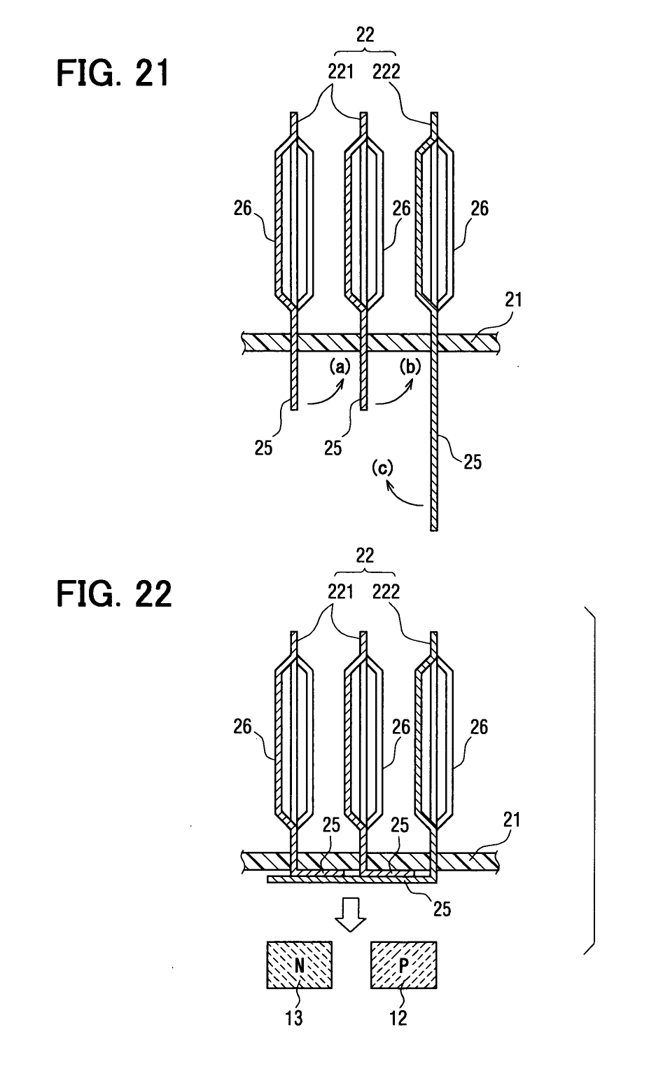

After that, as shown in FIG. 21, the coupling portion 223 (323) is cut off such that the heat-absorbing electrodes 25 (35) have predetermined lengths, to fabricate the plurality of the second heat-absorbing electrode members 221 (321) and the third heat-absorbing electrode members 222 (322). These second heat-absorbing electrode members 221 (321) and third heat-absorbing electrode members 222 (322) are pressed into rectangular-shaped holes which are formed in the second insulating substrate 21 (31), and then each heat-absorbing electrode 25 (35) is made to protrude to a required length. Then, the electrode members are subjected to a bending process-step in the order of a to c in the figure. The bending process-step can be performed after the surfaces of the heat-absorbing electrodes 25 (35) are coated with a solder paste. As a result, the heat-absorbing electrode 25 (35) of the third heat-absorbing electrode member 222 (322) and the heat-absorbing electrodes 25 (35) of the second heat-absorbing electrode members 221 (321) can be stacked and soldered. As a result, the structure illustrated in FIG. 22 is obtained.

As shown in FIG. 24, at least one second heat-absorbing electrode member 221 (321) and one third heat-absorbing electrode member 222 (322) may be joined to form the heat-absorbing electrode member 22 (32). Also, as an alternative to the stacking structure, a structure in which the two heat-absorbing electrodes 25 (35) are arranged with their end faces abutting against each other may be employed.

The heat-absorbing electrode substrate 20 or the heat-dissipating electrode substrate 30 which are thus fabricated can be used in any of the embodiments described above.

According to the twelfth embodiment, manufacturing advantages are offered. Also, because of the use of the structure in which the heat-absorbing electrodes 25 (35) are pressed into the rectangular-shaped holes formed in the second insulating substrate 21 (31), a gap is not easily produced between the hole and the electrode. Further, a plurality of portions for heat exchange can be provided, resulting in a high heat-exchanging capability.

### Thirteenth Embodiment

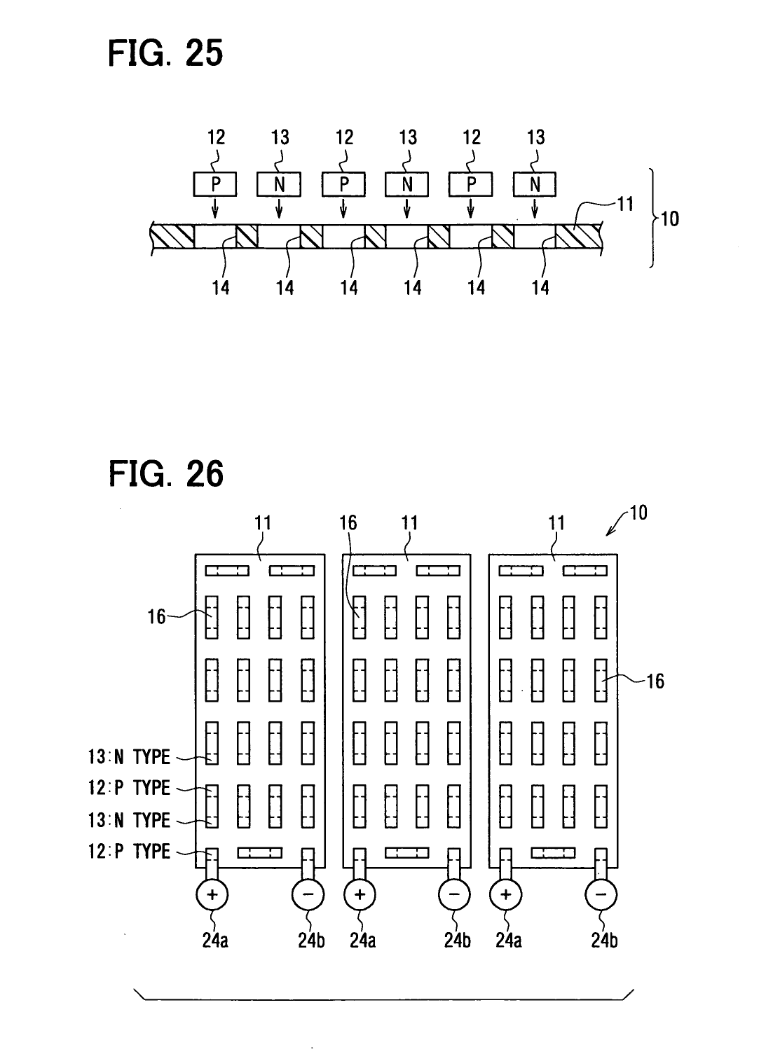

FIG. 25 illustrates a thirteenth embodiment according to the present invention. In this embodiment, a plurality of engaging holes 14 are pre-formed in the positions in the first insulating substrate 11 where the thermoelectric elements 12, 13 are to be placed. Then, the thermoelectric elements 12, 13 are alternately pressed into the engaging holes 14 through an assembly process-step using a robot, for example.

### Fourteenth Embodiment

FIG. 26 is a fourteenth embodiment according to the present invention. In this embodiment, at least one of the thermoelectric element substrate 10, heat-absorbing electrode substrate 20 and heat-dissipating electrode substrate 30 is provided by a combination of a plurality of unit assemblies. FIG. 26 illustrate the case of the thermoelectric element substrate 10 made up of three unit assemblies. The embodiment can be understood as a structure in which the thermoelectric element substrate 10 of the foregoing embodiments is divided into three. In this embodiment, the thermoelectric element substrate 10 made up of the three unit assemblies is placed between the single heat-absorbing electrode substrate 20 and the single heat-dissipating electrode substrate 30. Each of the unit assemblies has connecting portion 24a, 24b. The unit assemblies are electrically connected in series or in parallel.

Other substrates 20, 30, 40 in the foregoing embodiments may be constituted of a plurality of unit assemblies. Further, the thermoelectric converter may be constituted of a plurality of unit assemblies. In this case, each of the unit assemblies adopts the structure described in any of the embodiments. The adoption of a structure having a plurality of unit assemblies makes it possible to reduce the thermal strain.

### Fifteenth Embodiment

A thermoelectric converter in a fifteenth embodiment of the present invention will be described below. In the following description of the embodiment, the components having functions or shapes identical to those of the components described in the first embodiment described earlier are indicated with the same reference numerals and the description is omitted.

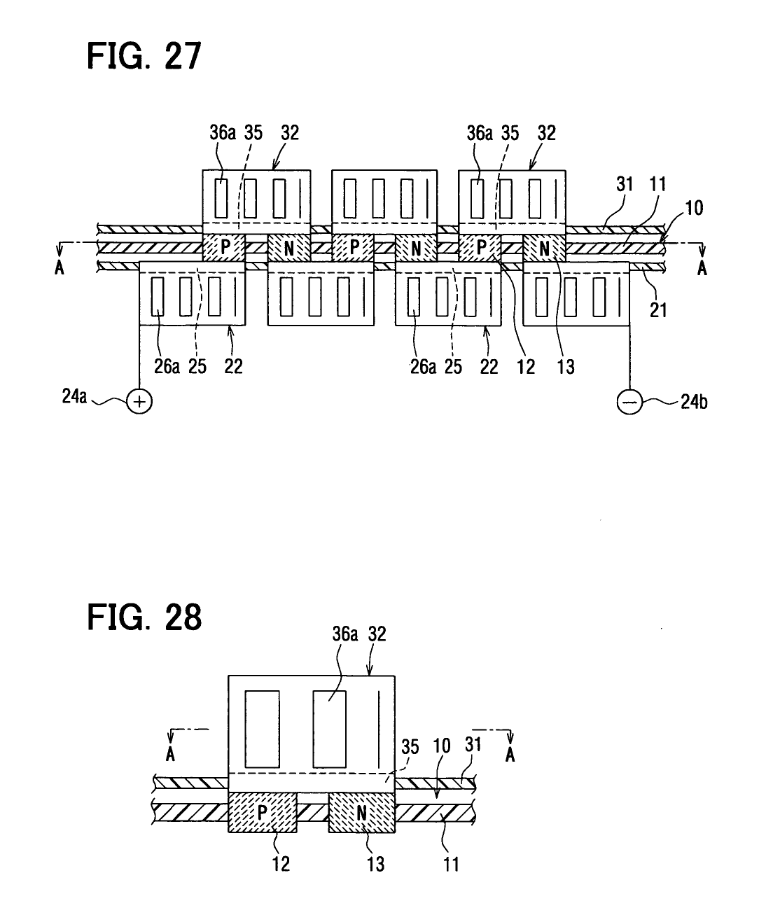

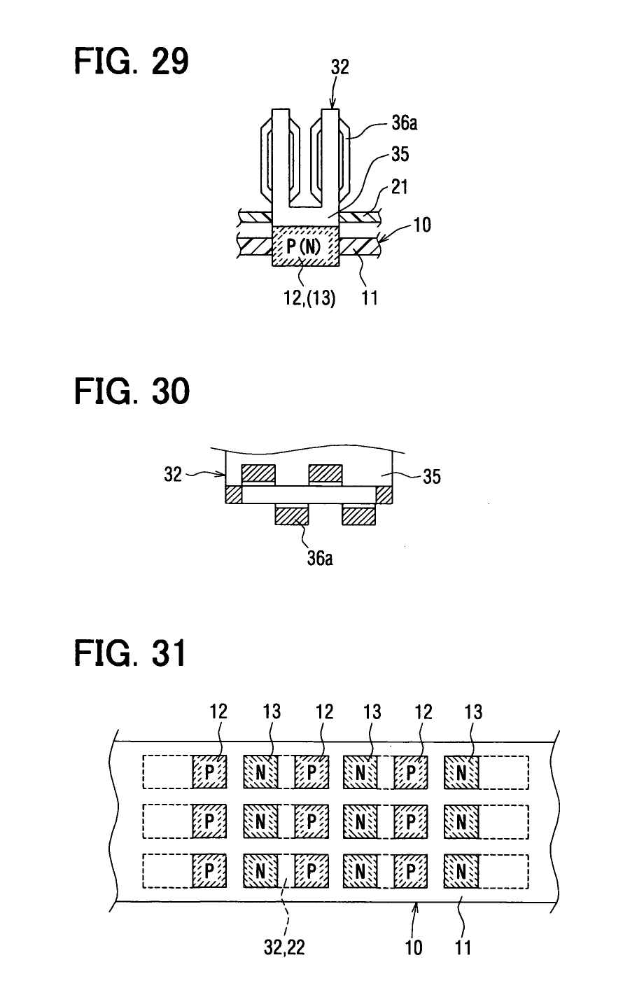

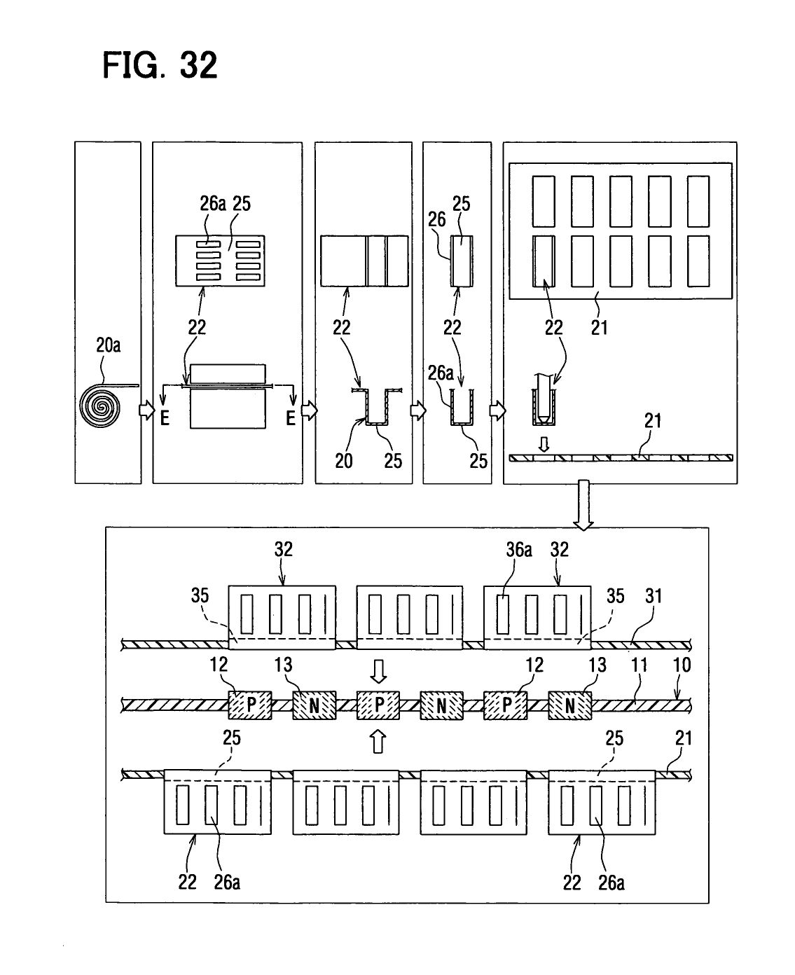

FIG. 27 to FIG. 31 illustrate sectional views of the embodiment. FIG. 32 illustrates the manufacturing process of the embodiment. In FIG. 27, a heat-dissipating side heat exchanger portion is placed in the upper side of the figure. In this embodiment, offset louvers 26a, 36a of a parallel protrusion type are employed in plate-shaped fins serving as a heat exchanger portion. The shape of the offset louvers 26a, 36a is distinctly illustrated in FIG. 28 to FIG. 30 showing a plan view, a side view and a sectional view. FIG. 31 illustrates the arrangement of the plurality of the P-type thermoelectric elements 12 and N-type thermoelectric elements 13 which are arranged in grid form.

The manufacturing process in the embodiment is shown in FIG. 32. The manufacturing process has a process-step for manufacturing the thermoelectric element substrate 10; a process-step for manufacturing the heat-absorbing electrode substrate 20; a process-step for manufacturing the heat-dissipating electrode substrate 30; and a joining process-step for stacking the thermoelectric element substrate 10, the heat-absorbing electrode substrate 20 and the heat-dissipating electrode substrate 30 and joining them together all at one time. FIG. 32 shows the process-step of manufacturing the heat-absorbing electrode substrate 20 and the joining process-step. For the process-step of manufacturing the thermoelectric element substrate 10, the description in other embodiments can be referred to. The process-step of manufacturing the heat-dissipating electrode substrate 30 is the same as that of the heat-absorbing electrode substrate 20.

Referring to FIG. 32, the top left block shows a process-step for feeding a plate material. In this case, a plate material 20a rolled in coil form is fed. The plate material 20a is carried into the subsequent pressing process-step. In the pressing process-step, a pressing machine is used to form an offset louver 26a. The top stage in each of the blocks in FIG. 32 shows a plan view and the bottom stage shows a side view. Then, in the bending process-step, the plate material is subjected to the bending process in a C shape in cross section. Then, in the cutting process-step, the plate material is cut into the individual shapes of the electrode members 22. These process-steps can be performed by the pressing machine. Accordingly, the plate material is subjected to a selective combination of processes, such as shearing, bending, blanking, to form the electrode members 22. Thus, the plurality of the electrode members 22 are manufactured. Then, in an assemble process-step, the electrode member 22 is inserted into a rectangular-shaped hole formed in the insulating substrate 21. In the embodiment, the inner wall face of the hole of the insulating substrate 21 is coated with an adhesive. FIG. 32 illustrates the situation in which a jig is placed in the electrode member 22 to insert it into the hole. The electrode members 22 are respectively inserted into a plurality of holes. Therefore, the electrode members 22 are bonded in the holes. As a result, the heat-absorbing electrode substrate 20 retaining the plurality of the electrode members 22 is manufactured.

Then, as illustrated in the lower stage in FIG. 32, the thermoelectric element substrate 10, the heat-absorbing electrode substrate 20 and the heat-dissipating electrode substrate 30 are stacked. A solder material is pre-placed between the electrode members 22, 23 and the thermoelectric elements 12, 13. After the stacking process-step, the whole is heated to melt the solder, and then the solder is cured again so that a plurality of joining sites is joined at a time.

In the structure, the adhesive has elasticity, so that the electrode member 22 is slightly movable in the hole of the insulating substrate 21. For this reason, even if a dimension error in the electrode member 22, a dimension error in the insulating substrate 21, deformation and the like occur, it is possible to absorb these errors and to put the electrode member 22 in place and reliably solder it in the joining process-step.

### Sixteenth Embodiment

Instead of the above-described embodiment, a structure in which the electrode member 22 is pressed into the hole of the insulating substrate 21 may be adopted. In this case, the adhesive can be applied in advance. The hole formed in the insulating substrate 21 and the electrode member 22 are fitted tightly together.

### Seventeenth Embodiment

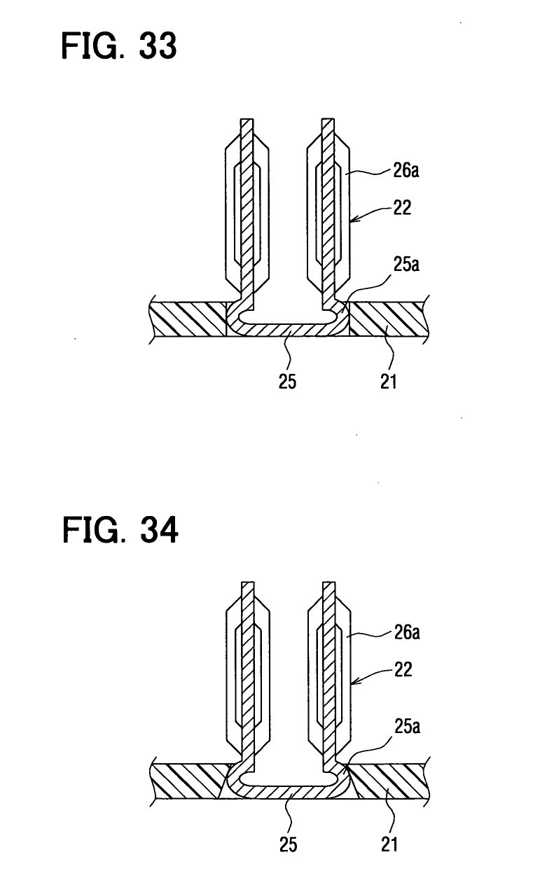

FIG. 33 illustrates a seventeenth embodiment. FIG. 33 is a sectional view showing the structure for temporarily fixing the insulating substrate 21 and the electrode member 22. A similar structure can be adopted between the insulating substrate 31 and the electrode member 32. In this embodiment, base portions 25a of the electrode member 22 are formed in a bend form. The base portions 25a provide an elastic force. The base portions 25a are formed at the two ends of the electrode 25. In this structure, the electrode member 22 is pressed into a hole of the insulating substrate 21. The base portions 25a are elastically changed in shape, so that the electric member 22 is retained in the hole.

FIG. 34 illustrates a modified example of the seventeenth embodiment. In FIG. 34, the insulating substrate 21 has a tapered hole. Since the bend-shaped base portions 25a provide an adequate elasticity, the base portions 25a are retained also in the tapered hole. In this structure, the elastic shape-change of the base portions 25a makes the electrode member 22 slightly movable in the hole of the insulating substrate 21. For this reason, even if a dimension error in the electrode member 22, a dimension error in the insulating substrate 21, deformation thereof and the like occur, it is possible to absorb these errors and to put the electrode member in place and reliably solder it in the joining process-step.

### Eighteenth Embodiment

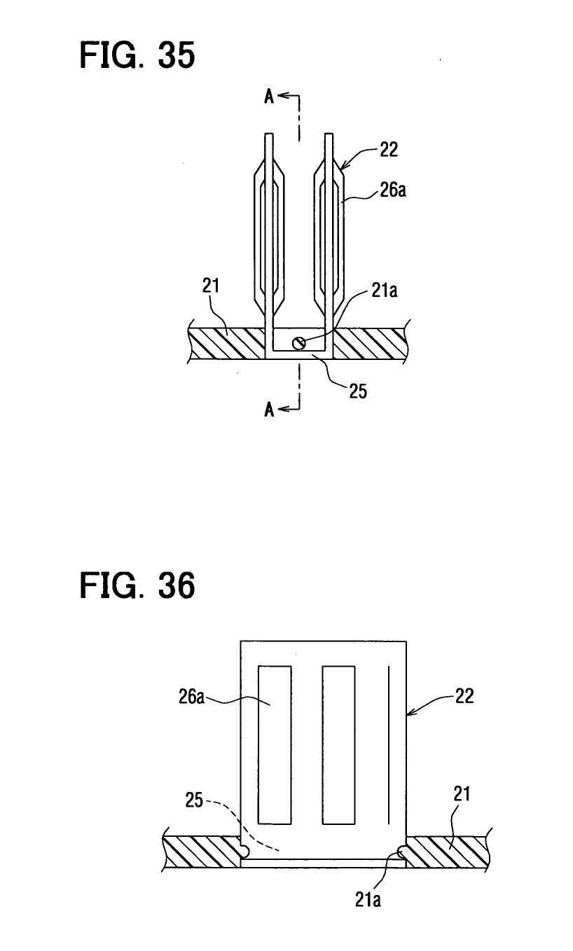

FIG. 35 and FIG. 36 illustrate an eighteenth embodiment. FIG. 35 and FIG. 36 are sectional views showing the structure for temporarily fixing the insulating substrate 21 and the electrode member 22. FIG. 35 is a sectional view when viewed from the side, and FIG. 36 is a sectional view. A similar structure may be adopted between the insulating substrate 31 and the electrode member 32. In this embodiment, protrusions 21a engaging with the electrode member 22 are provided on the inner face of the hole in the insulating substrate 21. The electrode member 22 is pressed into the hole in the insulating substrate 21, and engages with the protrusions 21a in place. As a result, the electrode member 22 is positioned. In this structure, the electrode member 22 is slightly movable in the hole in the insulating substrate 21. For this reason, even if a dimension error in the electrode member 22, a dimension error in the insulating substrate 21, deformation thereof and the like occur, it is possible to absorb these errors and to put the electrode member 22 in place and reliably solder it in the joining process-step.

### Nineteenth Embodiment

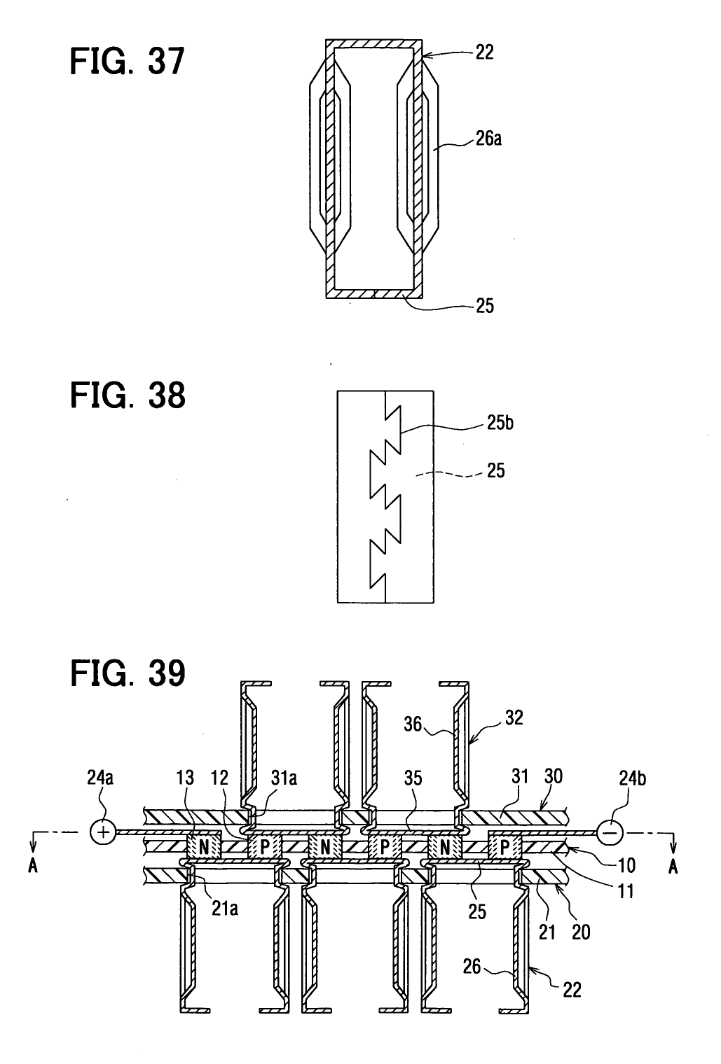

Instead of the structure of the above-described embodiment, the electrode member 22 of a shape illustrated in FIG. 37 and FIG. 38 may be adopted. FIG. 37 and FIG. 38 show a sectional view and a bottom view of the electrode member 22. A similar structure may be used for the electrode member 32. The electrode member 22 of the embodiment is formed in a shape that can be called a tubular shape or a box shape. The tubular-shaped electrode member 22 acts like a spring so as to be retained in the hole in the insulating substrate by its own elasticity. A plate material can be formed into the electrode member 22. For example, a dovetail fitting portion 25b as shown in the figure may be provided in the joining portion.

### Twentieth Embodiment

A thermoelectric converter in a twentieth embodiment of the present invention will be described below. In the descriptions of the following embodiments, the components having functions or shapes identical to those of the components described in the foregoing first embodiment are indicated with the same reference numerals and the description is omitted.

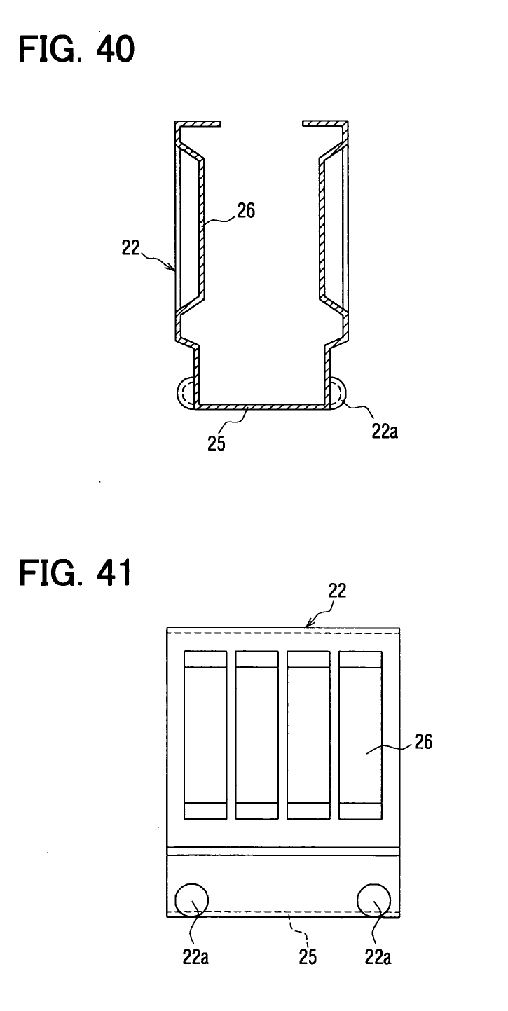

FIG. 39 shows a sectional view of this embodiment. FIG. 40 is an enlarged sectional view of an electrode member. FIG. 41 is an enlarged sectional view of the electrode member. In this embodiment, the heat-absorbing electrode member 22 and the heat-dissipating electrode member 32 have protrusions for engaging with the insulating substrates 21, 31. The heat-absorbing electrode member 22 and the heat-dissipating electrode member 32 are identical in shape. Therefore, their shape will be described in detail using the heat-absorbing electrode member 22 as an example.

As shown in FIG. 39, the heat-absorbing electrode member 22 is formed in a C-shape cross-section. The heat-absorbing electrode member 22 has a rectangular plate-shaped electrode 25 connected to thermoelectric elements 12, 13, and two fins rising from the two ends of the electrode 25 in a direction at approximately right angles. The fins, which are each formed in a plate shape, have louvers 26 formed for promoting the heat exchange. A recess is formed in a portion in which the fins and the insulating substrate 21 are opposite to each other. The recess engages with a hole 21a in the insulating substrate 21. The heat-absorbing electrode member 22 is provided with a part extending beyond the hole 21a on the face of the insulating substrate 21 closer to the thermoelectric elements 12, 13, and also a part extending beyond the hole 21a on the other face of the insulating substrate 21 at a distance from the thermoelectric elements 12, 13. As a result, the heat-absorbing electrode member 22 engages with the insulating substrate 21 and is retained therein. The leading ends of the fins provided on the two sides of the heat-absorbing electrode member 22 are bent inward to become closer to each other. However, a sufficient space is given between the leading ends. The rear face of the electrode 25 is almost fully viewed from between the leading ends. As a result, it is possible to linearly reach the rear face of the electrode 25.

As shown in FIG. 40 and FIG. 41, the heat-absorbing electrode member 22 before mounted on the insulating substrate 21 has sphere-shaped protrusions 22a. The protrusions 22a protrude outward in the direction of the two sides of the heat-absorbing electrode member 22 in the plane direction of the electrode 25. These protrusions 22a provides the part extending beyond the hole 21a on the face of the insulating substrate 21 closer to the thermoelectric elements 12, 13. The heat-absorbing electrode member 22 is shaped narrower in the portion close to the electrode 25 to form a necking portion. The convex portion placed above the necking portion in the figures provides the part extending beyond the hole 21a on the other face of the insulating substrate 21 at a distance from the thermoelectric elements 12, 13. The protrusion 22a may be formed in a shape having a triangular cross section.

An open space is formed on the rear face of the electrode 25 in the vertical direction in the figure. As a result, a member can be made to reach directly the rear face of the electrode 25 from the vertical direction in the figure. In this embodiment, the leading end of a mount apparatus is connected to the rear face of the electrode 25. The leading end of the mount apparatus retains the rear face of the electrode 25 and carries the heat-absorbing electrode member 22 to mount it on the second insulating substrate 21. For example, the leading end of the mount apparatus is capable of adsorbing the rear face of the electrode 25 to retain it.

The heat-absorbing electrode member 22 after being formed in the shape shown in the figure is mounted on the insulating substrate 21 by the mount apparatus. For the mount apparatus, a generally available apparatus for mounting electronic components or a robot apparatus may be used. In the assembly process-step, the mount apparatus presses one by one the plurality of the heat-absorbing electrode members 22 into the holes 21a of the second insulating substrate 21. At this point, the protrusions 22a are changed in shape within its elastic range. For this reason, the heat-absorbing electrode member 22 pressed into the insulating substrate 21 is retained without coming away from the insulating substrate 21. After that, as in the cases of the foregoing embodiments, the stacking process-step and the joining process-step are performed.

According to this embodiment, the electrode members 22, 32 are easily handled in the assembly process-step. For this reason, it is possible to improve the productivity.

### Twenty-First Embodiment

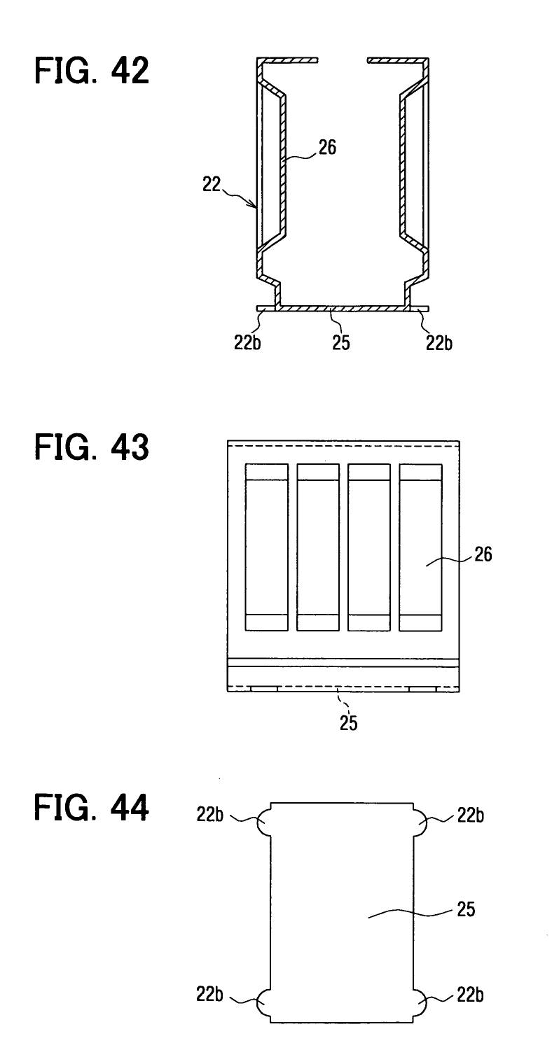

A thermoelectric converter in a twenty-first embodiment of the present invention is described. FIG. 42 shows a sectional view of an electrode member of this embodiment. FIG. 43 is a side view of the electrode member. FIG. 44 is a bottom view of the electrode member. In this embodiment, the heat-absorbing electrode member 22 and the heat-dissipating electrode member 32 are identical in shape. The electrode members 22, 32 of this embodiment may be used instead of the electrode members of the foregoing embodiments.

In this embodiment, tongue-shaped protrusions 22b extending beyond a hole 21a in the insulating substrate 21 are formed on an extension of the electrode 25. When the heat-absorbing electrode member 22 is pressed into, the protrusions 22b are changed in shape within its elastic range together with the electrode 25, and produce a part extending beyond the hole 21a on the face of the insulating substrate 21 closer to the thermoelectric elements 12, 13. The protrusions 22b can be formed by making arc-shaped incisions in the plate material which is a blank for the electrode member 22, and then bending the base of the arc shape at approximately right angles. The protrusions 22b are formed outside the electrode 25.

### Twenty-Second Embodiment

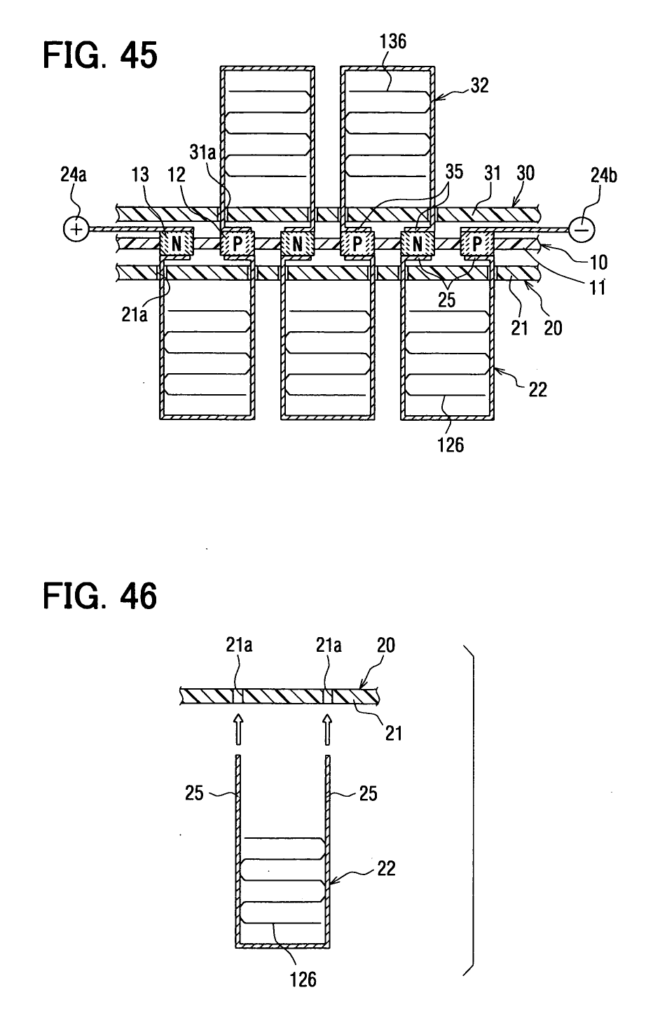

A thermoelectric converter in a twenty-second embodiment of the present invention will be described. FIG. 45 is a sectional view of an electrode member of this embodiment. FIG. 46 is a side view of the electrode member.

In this embodiment, the heat-absorbing electrode member 22 and the heat-dissipating electrode member 32 are constituted as a current-carrying passage as a whole. The electrode members 22, 32 are each formed in a C shape, and have the electrodes 25, 35 formed at the leading ends of the two arms of each electrode member. In this embodiment, corrugated fins 126, 136 are each interposed between the two arms of each of the C-shaped electrode members 22, 32 for promoting the heat exchange. As shown in FIG. 46, the electrodes 25 are formed by inserting the two arms of each of the electrode members 22, 32 in holes 21a, 31a in the insulating substrates 21, 31, and then bending each protruding portion at right angles into an L shape. In this embodiment, the protruding portions are bent inward so as to come closer to each other.

According to this embodiment, the electrode members 22, 32 are easily handled. For this reason, it is possible to improve the productivity.

### Twenty-Third Embodiment

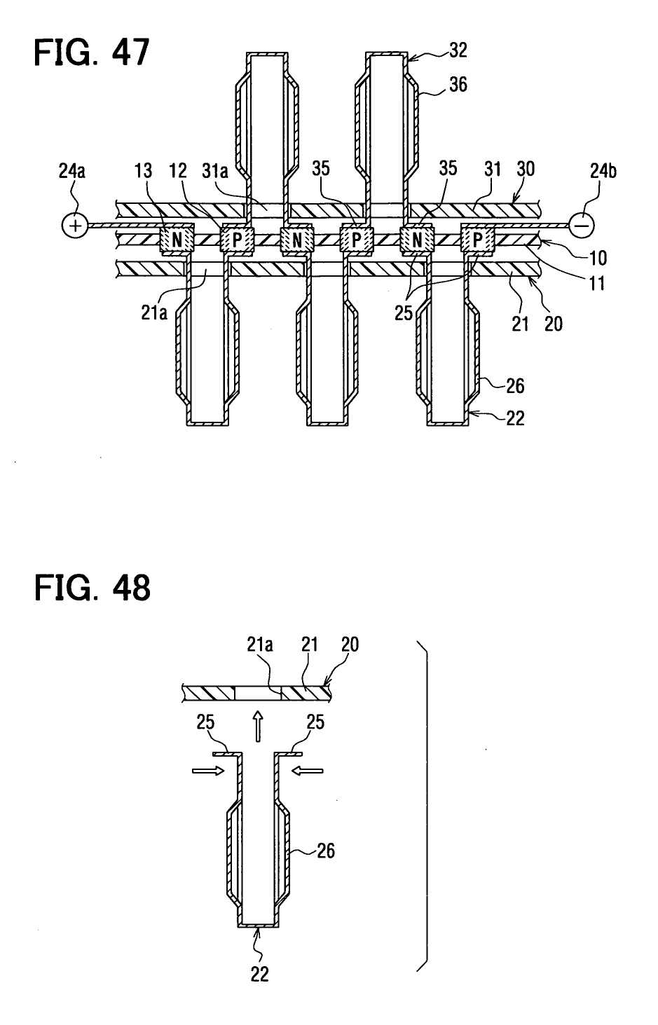

A thermoelectric converter in a twenty-third embodiment of the present invention will be described. FIG. 47 is a sectional view of an electrode member of the embodiment. FIG. 48 is a side view of the electrode member.

In this embodiment, the heat-absorbing electrode member 22 and the heat-dissipating electrode member 32 are entirely constituted as a current-carrying passage. The electrode members 22, 32 are each formed in a C shape, and have the electrodes 25, 35 each formed at the leading ends of the two arms of each electrode member. In this embodiment, louvers 26, 36 are each formed in the two arms of each of the C-shaped electrode members 22, 32. To form the electrodes 25, 35, the two arms of each of the electrode members 22, 32 are each bent at right angles into an L shape so as to open outward. As a result, the electrode members 22, 32 have a shape having flange-shaped electrodes 25, 35. Such a shape can be called an approximate hat shape, for example.

In the assembly process-step, each of the electrode members 22, 32 is pinched by a mount apparatus so as to close the two arms as shown in FIG. 48. As a result, the distance between the two electrodes 25 is narrowed so as to enable their insertion into a hole 21a. After the electrode members 22, 32 are inserted into the holes 21a, 31a, the electrode members 22, 32 are restored by their own elasticity, or alternately are subjected to a process for forcibly opening the two arms to the shape shown in the figure.

According to this embodiment, the electrode members 22, 32 are easily handled. For this reason, it is possible to improve the productivity in the assembly process-step.

### Twenty-Fourth Embodiment

A thermoelectric converter in a twenty-fourth embodiment of the present invention will be described below. In the descriptions of the following embodiment, the components having functions or shapes identical to those of the components described in the aforementioned first embodiment are indicated with the same reference numerals and the description is omitted.

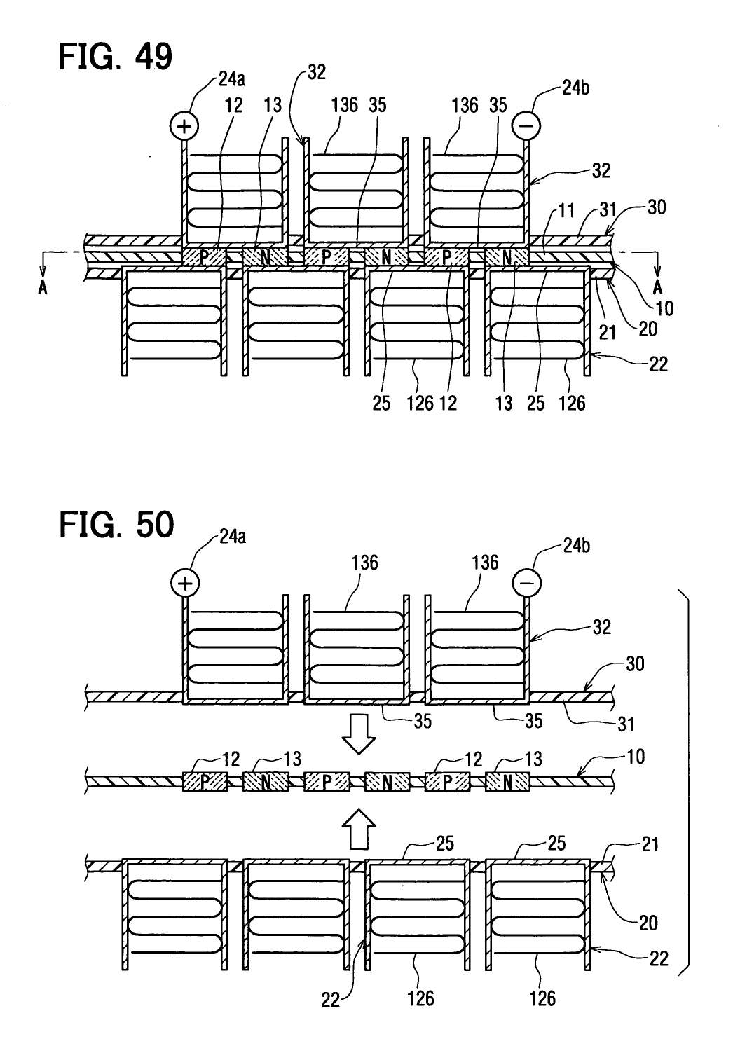

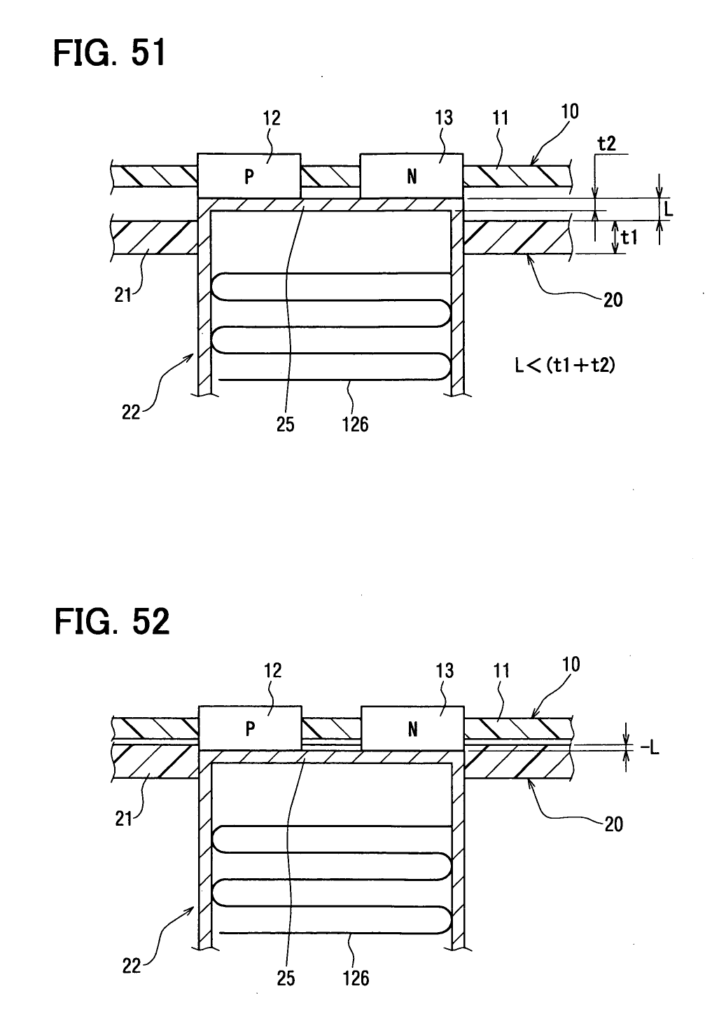

FIG. 49 shows a sectional view of this embodiment. FIG. 50 is an exploded view of the embodiment. FIG. 51 is a partially enlarged sectional view of the embodiment. In this embodiment, the heat-absorbing electrode substrate 20 and the heat-dissipating electrode substrate 30 differ from each other only in the placement of the electrode members, and have approximately the same structure. The following description concentrates on the heat-absorbing electrode member 22, and the reference numerals in the structure of the heat dissipating side are parenthesized. The heat-absorbing electrode member 22 and the heat-dissipating electrode member 32 are identical in shape.

In this embodiment, the heat-absorbing electrode member 22 (32) is shaped in a simple C-shape cross section. A corrugated fin 126 (136) is retained between the two arms of the heat-absorbing electrode member 22 (32). The two arms of the heat-absorbing electrode member 22 (32) and the corrugated fin 126 provide a heat exchanging area for heat exchange.

In this embodiment, the heat-absorbing electrode member 22 (32) is placed so as to protrude from the insulating substrate 21 (31) by a predetermined dimension. The amount of protrusion L is controlled to be equal to or less than a predetermined value. The heat-absorbing electrode member 22 (32) can be positioned and fixed to the insulating substrate 21 (31) by either bonding with an adhesive or mechanical engagement. The insulating substrate 21 (31) has a thickness t1. The electrode 25 (35) of the heat-absorbing electrode member 22 (32) has a thickness t2. In this embodiment, the amount of protrusion L is controlled such that the relationship between the amount of protrusion L, the thickness t1 and the thickness t2 becomes (t1+t2)>L. In this embodiment, the amount of protrusion L is set sufficiently smaller than the size (t1+t2). The amount of protrusion L corresponds approximately to the thickness t2 of the electrode 25 (35). The control of the amount of protrusion L of at least the heat-absorbing electrode member 22 is efficacious. This is because rather, it is possibly desirable that the heat-dissipating electrode member 32 receives a large amount of heat transfer.

With this structure, because the amount of protrusion of the electrode 25 (35) is minimized, a transfer of undesired heat to the electrode 25 (35) is inhibited. For example, radiant heat from the thermoelectric elements 12, 13, or heat transfer caused by air convection in the thermoelectric elements 12, 13 is inhibited. In particular, the control of a smaller amount of protrusion L of the electrode 25 on the heat-absorbing electrode member 22 which is on the low temperature side produces an advantage when used for supply of low temperature.

### Twenty-Fifth Embodiment

FIG. 52 is a sectional view of a twenty-fifth embodiment. In this embodiment, the heat-absorbing electrode members 22 are seated below the face of the insulating substrate 21 closer to the thermoelectric elements 12, 13. The thermoelectric elements 12, 13 protrude from the insulating substrate 11. This structure has the advantage of the suppression of heat transfer from the thermoelectric elements 12, 13 to the heat-absorbing electrode members 22.

### Twenty-Sixth Embodiment

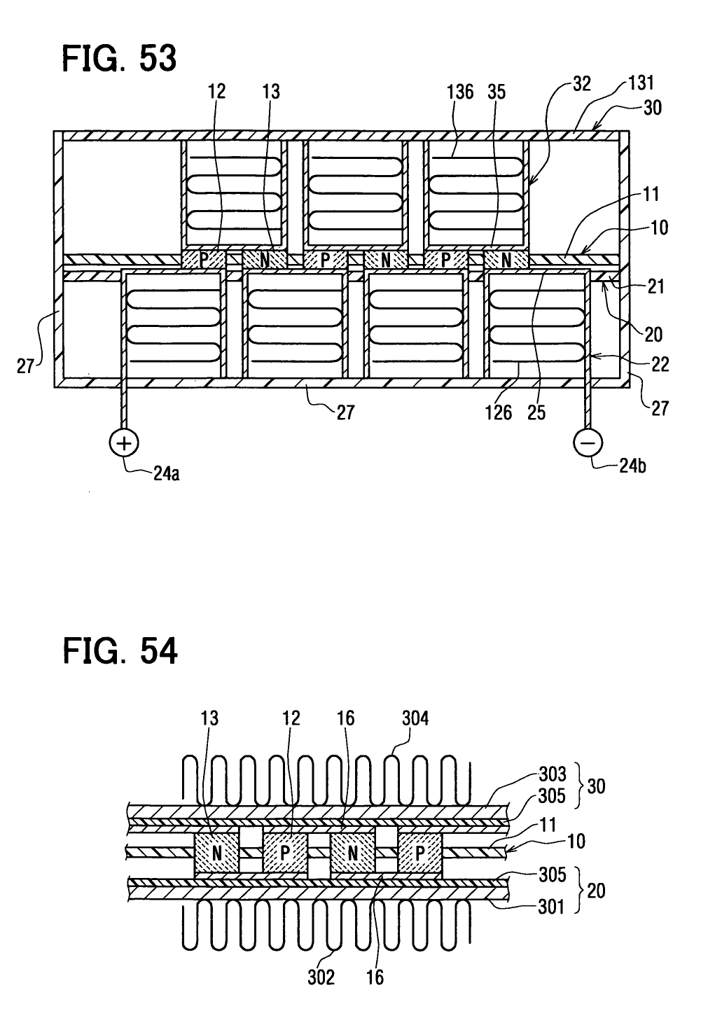

A thermoelectric converter in a twenty-sixth embodiment of the present invention will be described. FIG. 53 shows a sectional view of this embodiment. In this embodiment, the heat-absorbing electrode substrate 20 is structured as in the case of the aforementioned embodiment. However, the heat-dissipating electrode substrate 30 has an insulating substrate 131 placed at a distance from the thermoelectric elements 12, 13. In this embodiment, an air passage defined by a casing member 27 is formed between the insulating substrate 11 and the insulating substrate 131. As a result, the thermoelectric elements 12, 13 are placed in direct contact with air serving as a heat exchange medium on the side of the heat-dissipating electrode substrate 30. This structure is effective in promoting heat dissipation from the thermoelectric elements 12, 13.

In this embodiment, the distance between the thermoelectric elements 12, 13 and the insulating substrate 21 on the heat-absorbing side is set adequately smaller than the distance between the thermoelectric elements 12, 13 and the insulating substrate 131 on the heat-dissipating side. This structure produces the operational effects of inhibiting heat transfer toward the heat absorbing side in which low temperature results, and of advancing heat transfer toward the heat dissipating side in which high temperature results. In addition, because of the adoption of the structure in which the air serving as a heat exchange medium on the heat-dissipating side is made to flow in such a way as to come into direct contact with the thermoelectric elements 12, 13, the operational effect of promoting the heat dissipation is additionally achieved.

### Twenty-Seventh Embodiment

FIG. 54 is a sectional view of a thermoelectric converter according to a twenty-seventh embodiment of the present invention. In this embodiment, the heat-absorbing substrate 20 is constituted of a metal plate 301 made of an excellent heat conductive material, and a corrugated fin 302 joined to the metal plate 301. The heat-dissipating substrate 30 is constituted of a metal plate 303 made of an excellent heat conductive material, and a corrugated fin 304 joined to the metal plate 303. The plurality of the thermoelectric elements 12, 13 of the thermoelectric element substrate 10 are connected in series by the plurality of the electrode members 16. An insulating layer 305 is provided on the face of the metal plate 301 closer to the thermoelectric element substrate 10. Likewise, an insulating layer 305 is provided on the face of the metal plate 303 closer to the thermoelectric element substrate 10. The heat-absorbing substrate 20 is joined through the insulating layer 305 to the heat absorbing side of the thermoelectric element substrate 10. The heat-absorbing substrate 30 is joined through the insulating layer 305 to the heat dissipating side of the thermoelectric element substrate 10. For joining onto the insulating layer 305, either bonding using an adhesive or a joining material such as solder may be used in accordance with the materials of the insulating layer 305.

With this structure, the first insulating substrate 11 inhibits the heat transfer from the high temperature side to the low temperature side.

The metal plates 301, 303 are made of a material having satisfactory thermal conductivity such as copper, aluminum, silver or brass. Further, the insulating layer 305 can be provided by the bonding of a resin film having electrical insulating properties, for example. Alternatively, for the insulating layer 305, a solid insulating film formed by the use of a depositing method such as a diamond-like-carbon coating (DCL) may be adopted. Alternatively, the insulating layer 305 may be provided by using an aerosol deposition technique for deposition of alumina (Al₂O₃) or aluminum nitride (AlN). Alternatively, a ceramic coating, for example, silica-alumina liquid ceramics may be applied by a dipping technique or the like, and then dried to form a film.

### Twenty-Eighth Embodiment

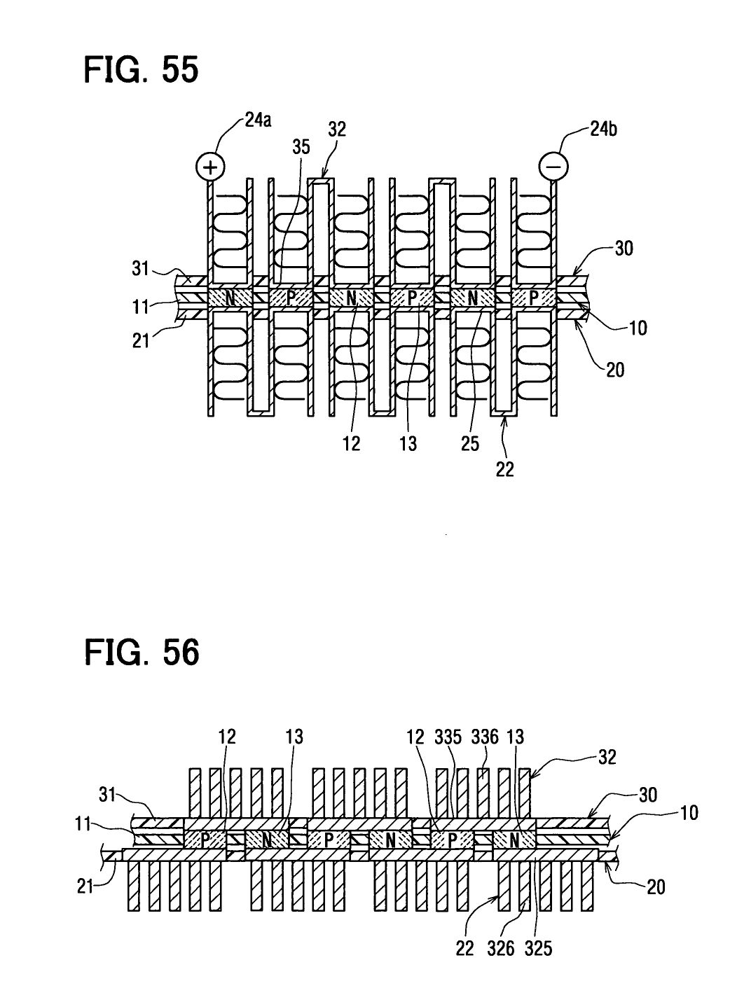

FIG. 55 is a sectional view showing a thermoelectric converter of a twenty-eighth embodiment. In this embodiment, the heat-absorbing electrode member 22 and the heat-dissipating electrode member 32 are each formed in a W shape. The amount of protrusion L from the insulating substrates 21, 31 is controlled. With this structure, an electrode portion for connection between the adjacent thermoelectric elements 12, 13 is not exposed on the side facing the thermoelectric elements 12, 13. In consequence, it is in particular possible to inhibit the heat transfer toward the heat-absorbing electrode members 22.

### Twenty-Ninth Embodiment

FIG. 56 is a sectional view illustrating a thermoelectric converter of a twenty-ninth embodiment. In this embodiment, the heat-absorbing electrode member 22 and the heat-dissipating electrode member 32 are equipped with a plurality of heat-exchange fin members 326, 336. The heat-absorbing electrode member 22 includes an electrode member 325 and the plurality of the heat-exchange fin members 326 joined to the electrode member 325 with the capability of conducting heat. The heat-dissipating electrode member 32 includes an electrode member 335 and the plurality of the heat-exchange fin members 336 joined to the electrode member 335 with the capability of conducting heat. In this structure, the amount of protrusion L of the electrode members 325, 335 is controlled.

### Thirtieth Embodiment

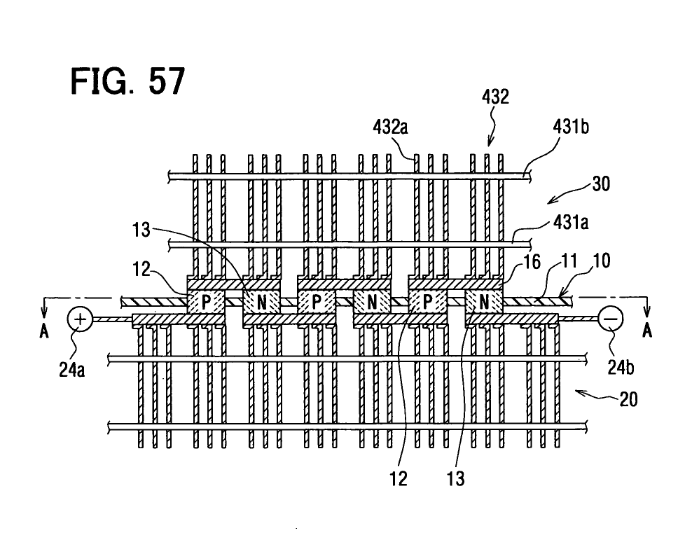

A thermoelectric converter in a thirtieth embodiment of the present invention will be described below. In the following description of the embodiment, the components having functions or shapes identical to those of the components described in the first embodiment described earlier are indicated with the same reference numerals and the description is omitted. FIG. 57 is a sectional view illustrating the embodiment.

The thermoelectric converter of this embodiment includes the thermoelectric element substrate 10, the heat-absorbing electrode substrate 20 and the heat-dissipating electrode substrate 30. The heat-absorbing electrode substrate 20 and the heat-dissipating electrode substrate 30 are respectively stacked on the two surfaces of the thermoelectric element substrate 10, and a thermal connection and an electrical connection are made between them. The heat-absorbing electrode substrate 20 and the heat-dissipating electrode substrate 30 are assembled from approximately the same structural components, but differ in placement in correspondence with a current-carrying passage. In the following description, the heat-dissipating electrode substrate 30 is described by way of example.

The thermoelectric element substrate 10 includes the plurality of the P-type thermoelectric elements 12 and the plurality of the N-type thermoelectric elements 13 retained by the insulating substrate 11 made of resin material having electrical insulating properties. The plurality of the thermoelectric elements 12, 13 are arranged in grid or matrix form. The plurality of the thermoelectric elements 12, 13 are arranged in alternate positions along a predetermined current-carrying passage. The plurality of the electrode members 16 connect the plurality of the thermoelectric elements 12, 13 in series along the current-carrying passage. Each of the electrode members 16 is joined, by soldering, to an end face of the P-type thermoelectric element 12 and an end face of the N-type thermoelectric element 13 which are adjacent to each other so as to bridge them.

A plurality of heat exchange members 432 are joined to each of the electrode members 16 by soldering or an adhesive, between which heat can be conducted. The heat exchange members 432 are formed of a metal material having outstanding thermal conductivity, for example, copper, aluminum or the like. The heat exchange members 432 are joined to the face of the electrode member 16 at a distance from the thermoelectric elements 12, 13. In this embodiment, the six heat exchange members 432 are joined to the electrode member 16. The three heat exchange members 432 are joined to a portion of the reverse side of the electrode member 16 corresponding to the joining area to which the P-type thermoelectric element 12 is joined. The other three heat exchange members 432 are joined to a portion of the reverse side of the electrode member 16 corresponding to the joining area to which the N-type thermoelectric element 13 is joined. The heat exchange members 432 provide a plurality of heat-transfer paths that extend separately from the vicinity of the thermoelectric elements 12, 13. This structure has an advantage because the low temperature or high temperature provided by the thermoelectric elements 12, 13 is thermally transferred efficiently.

The heat exchange members 432 of this embodiment are respectively plate members 432a each obtained by forming a flat plate in an L shape. The plate members 432a extend in the vertical direction of the sheet of the figure. The plate members 432a provide air passages in a direction perpendicular to the sheet. Each of the plate members 432a has through holes in a position closer to its proximal end and in a position closer to its distal end. These through holes of a plurality of the plate members 432a are drilled in alignment with each other. As a result, passages extend through the plurality of the plate members 432a. Rod-shaped fastening members 431a, 431b made of an electrical insulating material are placed in the through holes. The fastening members 431a, 431b frictionally engage with the plurality of the plate members 432a so as to integrally link the plurality of the plate members 432a together and lock the plate members 432a to keep spacing between them. The fastening members 431a, 431b are formed of, for example, a glass epoxy, a PPS resin, an LCP resin, a PET resin or the like.

In this embodiment, the thermoelectric element substrate 10 is initially fabricated. Then the plurality of the electrode members 16 are joined to provide a predetermined current-carrying path. On the other hand, the fastening members 431a, 431b are disposed in the through holes of the plurality of the plate members 432a so as to skewer them. Then the plurality of the plate members 432a are arranged in a predetermined positional relationship illustrated in the figure. As a result, it is possible to collectively handle the plurality of the plate members 432a. Thus, the heat-absorbing electrode substrate 20 and the heat-dissipating electrode substrate 30 are independently fabricated. Then the heat-absorbing electrode substrate 20 and the heat-dissipating electrode substrate 30 are respectively stacked on the two sides of the thermoelectric substrate 10. Then the plurality of the plate members 432a and the plurality of the electrode members 16 are all together joined to each other.

### Thirty-First Embodiment

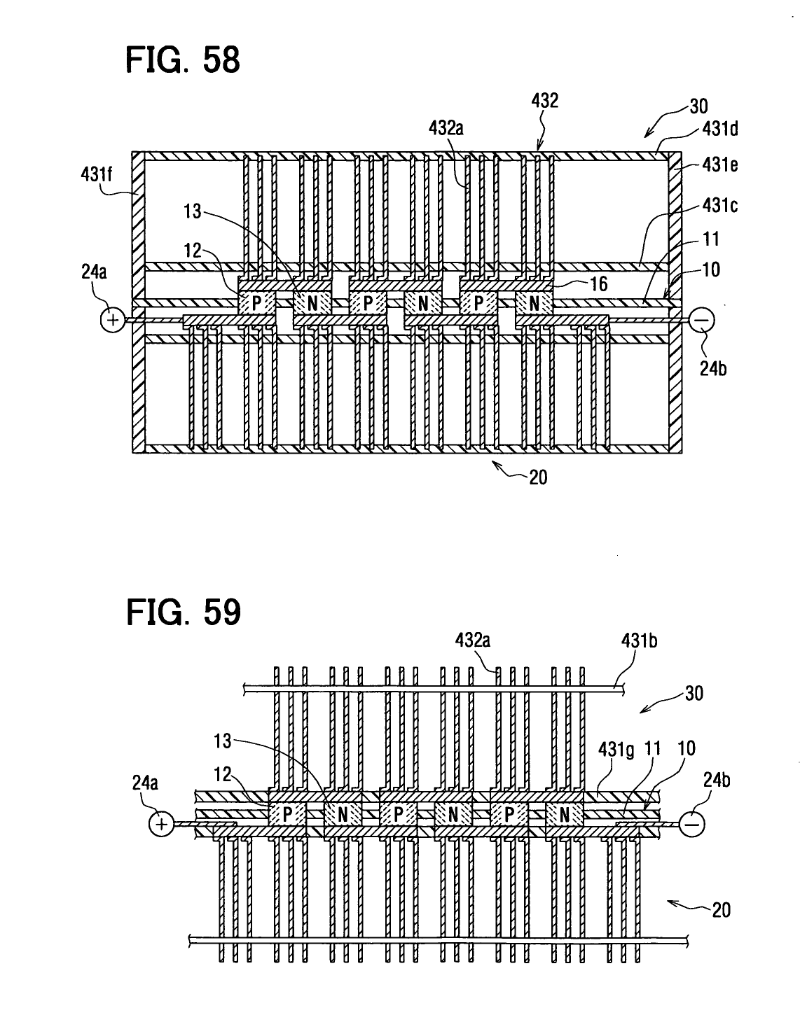

FIG. 58 is a sectional view illustrating a thirty-first embodiment of the present invention. In this embodiment, plate-shaped fastening members 431c, 431d are used instead of the rod-shaped fastening members 431a, 431b. The fastening members 431c, 431d are made of a material of insulation properties. The fastening member 431c has through holes formed in positions where the plate members 432a are arranged, so that the plate members 432a are inserted through the through holes for arrangement. The plurality of the plate members 432a are inserted into, fixed to and electrically insulated from the fastening member 431c. The fastening member 431d has groove-shaped holes arranged in positions where the plate members 432a are arranged so as to receive the leading ends of the plate members 432a. The plurality of the plate members 432a are inserted into, fixed to and electrically insulated from the fastening member 431d. The fastening member 431c provides a partition wall extending in parallel to the insulating substrate 11. The second fastening member 431d, together with side walls 431e, 431f, provides a casing member, which defines an air passage.

### Thirty-Second Embodiment

FIG. 59 is a sectional view illustrating a thermoelectric converter of a thirty-second embodiment of the present invention. In this embodiment, both the rod-shaped fastening member 431b and a plate-shaped fastening member 431g are used as a fastening member. The fastening member 431g has through holes in positions corresponding to the plurality of the electrode members 16, and the electrode members 16 are received and fixed by the through holes.

### Thirty-Third Embodiment

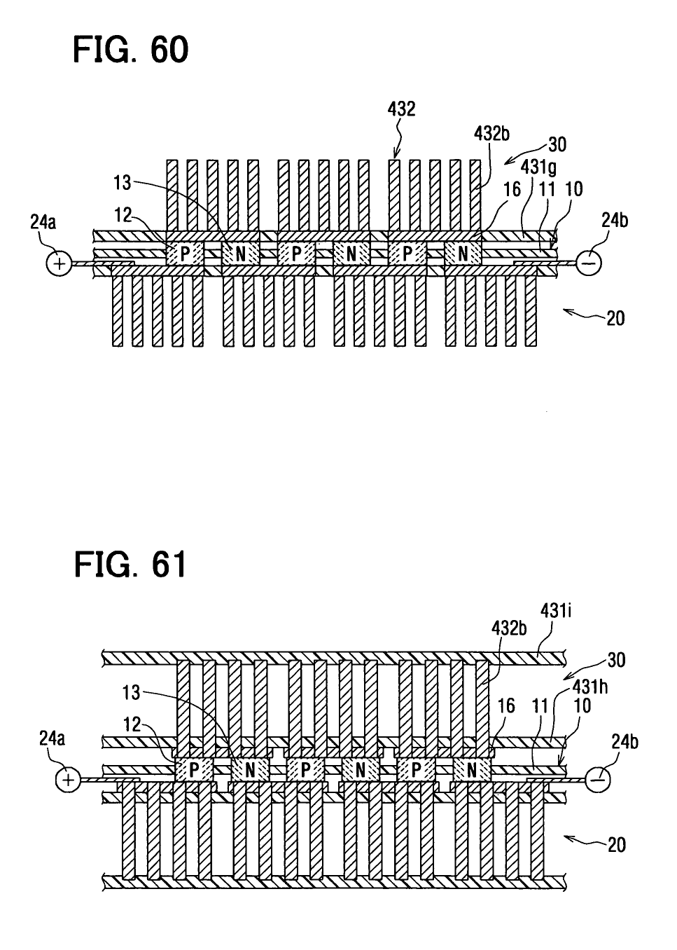

FIG. 60 is a sectional view illustrating a thermoelectric converter of a thirty-third embodiment of the present invention. In this embodiment, pin members 432b serving as the rod-shaped heat-exchange members are used instead of the plate-shaped heat exchange members 432a. The pin members 432b are joined to the electrode members 16 at their end faces with the capability of conducting heat. The plurality of the pin members 432b are all together joined to the single electrode member 16 by soldering.

### Thirty-Fourth Embodiment

FIG. 61 is a sectional view illustrating a thermoelectric converter of a thirty-fourth embodiment of the present invention. In this embodiment, the electrode members 16 have through holes drilled in positions where the pin members 432b are arranged. The pin members 432b are disposed in and fixed to the through holes. The pin members 432b are able to reach directly the end faces of the thermoelectric elements 12, 13. In this embodiment, the end faces of the pin members 432b are joined directly to the end faces of the thermoelectric elements 12, 13. The plurality of the pin members 432b are fixed by plate-shaped fastening members 431h, 431i. The fastening member 431h has a plurality of holes through which the pin members 432b pass. The fastening member 431i has a plurality of recesses that receive the leading ends of the pin members 432b. According to this embodiment, the pin member 432b serving as the plurality of the heat exchange members are able to be collectively handled by the fastening members 431g, 431i. Further, it is possible to provide the outstanding heat conductivity because the pin member 432b serving as the plurality of the heat exchange members are joined directly to end faces of the thermoelectric elements 12, 13.

### Thirty-Fifth Embodiment

A thermoelectric converter in a thirty-fifth embodiment of the present invention will be described below. In the following description of the embodiment, the components having functions or shapes identical to those of the components described in the first embodiment described earlier are indicated with the same reference numerals and the description is omitted. In the thermoelectric converter of this embodiment, the heat-absorbing electrode group is disposed on one face of the thermoelectric element substrate 10, and the heat-dissipating electrode group is disposed on the other face. The heat-absorbing electrode group and the heat-dissipating electrode group are formed by arranging a plurality of components which serve as the heat-exchange members of the same shape or which are called electrode members. The arrangement of the components in the heat-absorbing electrode group and the heat-dissipating electrode group is dissymmetric because the series connection between the plurality of the thermoelectric elements 12, 13 is provided.

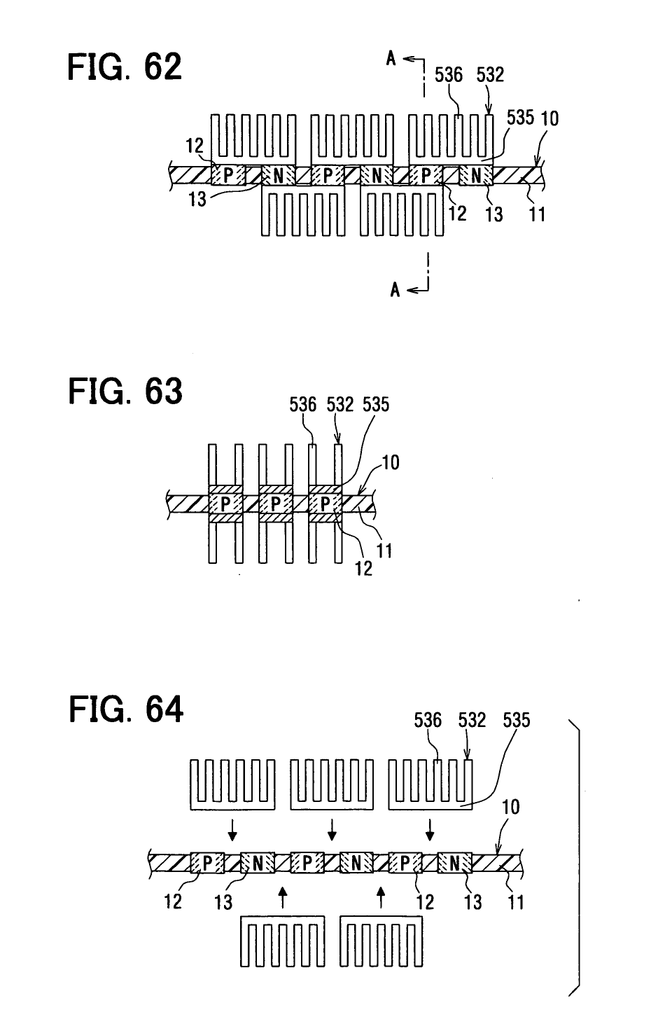

FIG. 62 is a sectional view illustrating the thermoelectric converter of this embodiment. FIG. 63 is another sectional view illustrating the thermoelectric converter of this embodiment. A cross section A-A of FIG. 62 is shown in FIG. 63. FIG. 64 is an exploded view illustrating the thermoelectric converter of this embodiment.

The thermoelectric element substrate 10 includes the plurality of the P-type thermoelectric elements 12 and the plurality of the N-type thermoelectric elements 13 retained by the insulating substrate 11 made of resin material of electrical insulating properties. For the structure of the thermoelectric element substrate 10, the description in other embodiments can be referred to.

In this embodiment, the thermoelectric elements 12, 13 are electrically connected by electrode members 532 which are also called the heat exchange members. The electrode member 532 has a plate shaped electrode 535 for providing the electrical connection. In addition, the electrode member 532, which serves as a heat transfer member or a heat exchange member transferring the low temperature or high temperature provided by the thermoelectric elements 12, 13, and performing heat exchange with air to transfer the low temperature or high temperature to the air, includes a heat exchanger portion 536 for heat exchange.

The heat exchanger portion 536 is also called the heat-absorbing area for transferring the low temperature to the air or the heat-dissipating area for transferring the low temperature to the air. The heat exchanger portion 536 extends outward from the two parallel sides of the electrode 535 in the vertical direction. The heat exchanger portion 536 is shaped from a flat plate. The heat exchanger portion 536 is formed as a plurality of protrusions which are also expressed as a plurality of pins. As shown in FIG. 63, the heat exchanger portion 536 has two rows of protrusions. As shown in FIG. 62, each of the rows has six protrusions. The 12 protrusions are arranged on the single electrode 535. The heat exchanger portion 536 is formed on the rear face of the electrode 535 in such a way as to provide an open space expanding from the electrode 535 in the vertical direction. As a result, it is possible to linearly reach the rear face of the electrode 535 from the vertical direction. This rear space is used as a path on which the leading end of a mount apparatus reaches the rear face of the electrode member 532 in order to grasp the electrode member 532.

FIG. 64 is a flow chart illustrating a method for manufacturing the thermoelectric converter. The electrode member 532 is fabricated from a plate material. The material 20a, which is in a state of coiled belt, is carried in. The top left block in the figure shows the supply process-step. Then the material is subjected to the blanking process. In this blanking process-step, the material 20a is cut into predetermined shapes. At this point, the predetermined shape is given by shearing. As shown in the figure, a region corresponding to the electrode 535 and a plurality of parts corresponding to the heat exchanger portion 536 are formed. In the upper stage in the second block, a plan view of the material 20a is shown. The material 20a is subjected to the punching process to form a plurality of slits corresponding to the gaps in the heat exchanger portion 536. In this process-step, the dimension in the width direction of the material 20a is defined. This process-step is also called the shearing process-step.

Next, the bending process-step is performed. In this process-step, as shown in the figure, the heat exchanger portion 536 located at the two sides of the electrode 535 are bent at approximately right angles. A shape having the electrode 535 at the bottom face and the heat exchanger portion 536 at the side walls is obtained. Then the blanking process is performed. In this blanking process, the upper end of the heat exchanger 536 is cut off, so that the material 20a is divided into the plurality of the electrode members 532. Each of the above-described shearing, bending and blanking process-steps can be performed through the pressing process. A pair of press dies for the pressing process and the material 20a interposed between the press dies are shown in the second block. In the initial shearing process-step, the slit portions may not be cut away, and the slit portions may be cut and raised to form louvers, for example. Further, in the pressing process, as an alternative to the pressing process method using a pair of dies moving toward each other, the roller process in which a material is inserted into a pair of rotational rollers for a cutting or bending process may be used.

Before, after or at the same time as the above process-step, a process-step for assembling the thermoelectric element substrate 10 which is shown in the bottom left block in the figure is performed. In this process-step, the plurality of the thermoelectric elements 12, 13 are mounted in the insulating substrate 11. The plurality of the thermoelectric elements 12, 13 are retained by the leading end of a mount apparatus, and inserted into and fixed in holes in the insulating substrate 11. Then the leading end of the mount apparatus retains the rear face of the electrode 535 of the electrode member 532. For example, the mount apparatus is equipped with a vacuum-type adsorbing portion at its leading end. The mount apparatus disposes and secures the electrode 535 so as to make a connection between the adjacent thermoelectric elements 12, 13. At this point, the mount apparatus can strongly press the electrode 535 against the thermoelectric elements 12, 13 from the rear face of the electrode 535. In this embodiment, the electrode 535 and the thermoelectric elements 12, 13 are joined to each other by solder. The process-step of mounting the electrode members 532 is performed on one face of the thermoelectric element substrate 10, then the thermoelectric element substrate 10 is turned upside down, and then the process-step of mounting the electrode members 532 is also performed on the other face of the thermoelectric element substrate 10. A thin and uniform coating of past solder may be applied in advance to either the end faces of the thermoelectric elements 12, 13 or the underside of the electrode 535, or both of them by screen printing. After that, the process-step of mounting the electrode members 532 is performed, and further the joining process-step is performed. The joining process-step may be performed on each electrode member 532, or performed all together on all the electrode members 532 after having been mounted.

In this embodiment, the plurality of the thermoelectric elements 12, 13 are connected in series by use of the electrode members 532 each having the heat exchanger portion 536 and the electrode 535 formed integrally. For this reason, a high productivity can be provided. In addition, an excellent thermal conductivity between the electrode 535 and the heat exchange portion 536 can be provided. Further, the electrode 535 can be retained from its rear face and be pressed against. For this reason, a high productivity can be provided.

### Thirty-Sixth Embodiment

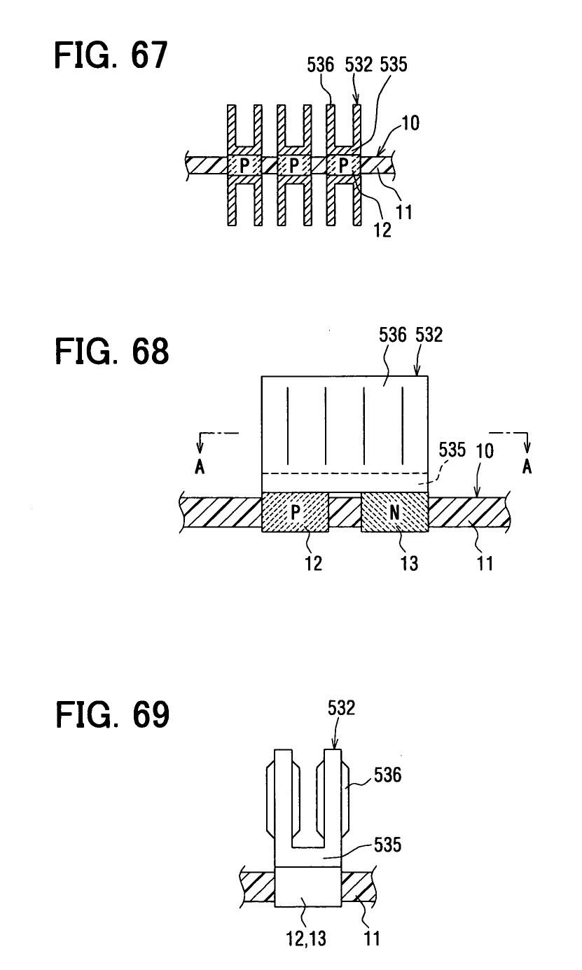

FIG. 66 is a sectional view of a thermoelectric converter of a thirty-sixth embodiment. FIG. 67 is another sectional view of the thermoelectric converter of this embodiment. FIG. 67 is the sectional view taken along the A-A line in FIG. 66. In this embodiment, the heat exchange portion 536 is provided in a plate form.

### Thirty-Seventh Embodiment

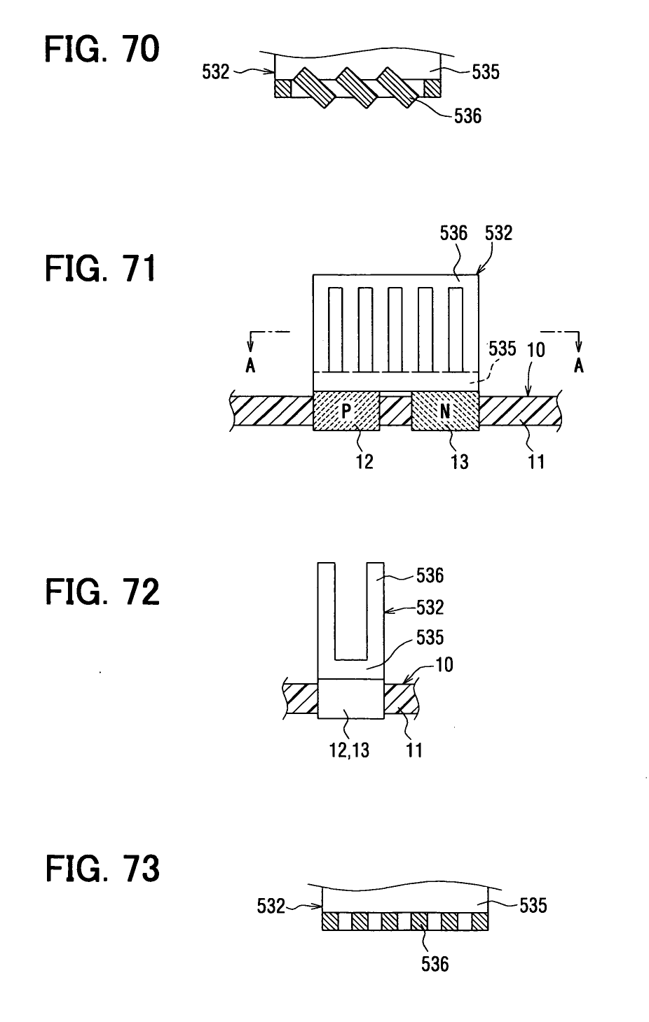

FIG. 68 is a sectional view of a thermoelectric converter of a thirty-seventh embodiment. FIG. 69 is another sectional view of the thermoelectric converter of this embodiment. FIG. 70 is a sectional view of a heat exchange portion of the thermoelectric converter of this embodiment. FIG. 70 is the sectional view taken along the A-A line in FIG. 68. In this embodiment, the heat exchange portion 536 is shaped in a form of a louver having a plurality of inclined plates. The louver-shaped heat exchanger portion 536 can be shaped by cutting and raising a flat plate.

### Thirty-Eighth Embodiment

FIG. 71 is a sectional view of a thermoelectric converter of a thirty-eighth embodiment. FIG. 72 is another sectional view of the thermoelectric converter of this embodiment. FIG. 73 is a sectional view of a heat exchanger portion of the thermoelectric converter of this embodiment. FIG. 73 is the sectional view taken along the A-A line in FIG. 71. In this embodiment, the heat exchange portion 536 is formed in a shape having a plurality of slit-shaped through holes.

### Thirty-Ninth Embodiment

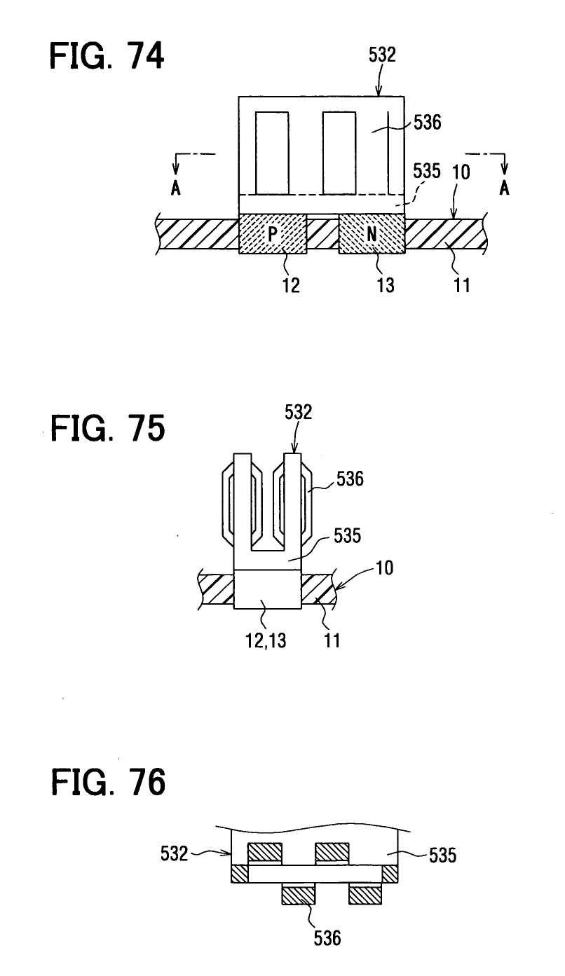

FIG. 74 is a sectional view of a thermoelectric converter of a thirty-ninth embodiment. FIG. 75 is another sectional view of the thermoelectric converter of this embodiment. FIG. 76 is a sectional view of a heat exchanger portion of the thermoelectric converter of this embodiment. FIG. 76 is the sectional view taken along the A-A line in FIG. 74. In this embodiment, the heat exchange portion 536 is formed in a shape having a plurality of offset fins.

### Fortieth Embodiment

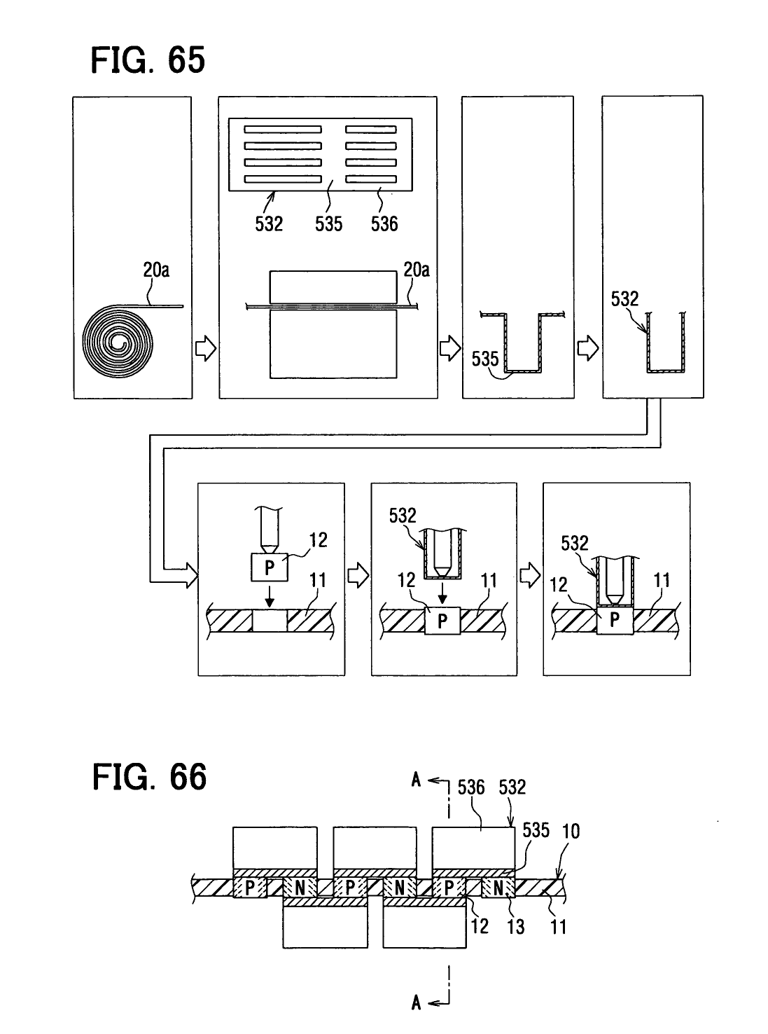

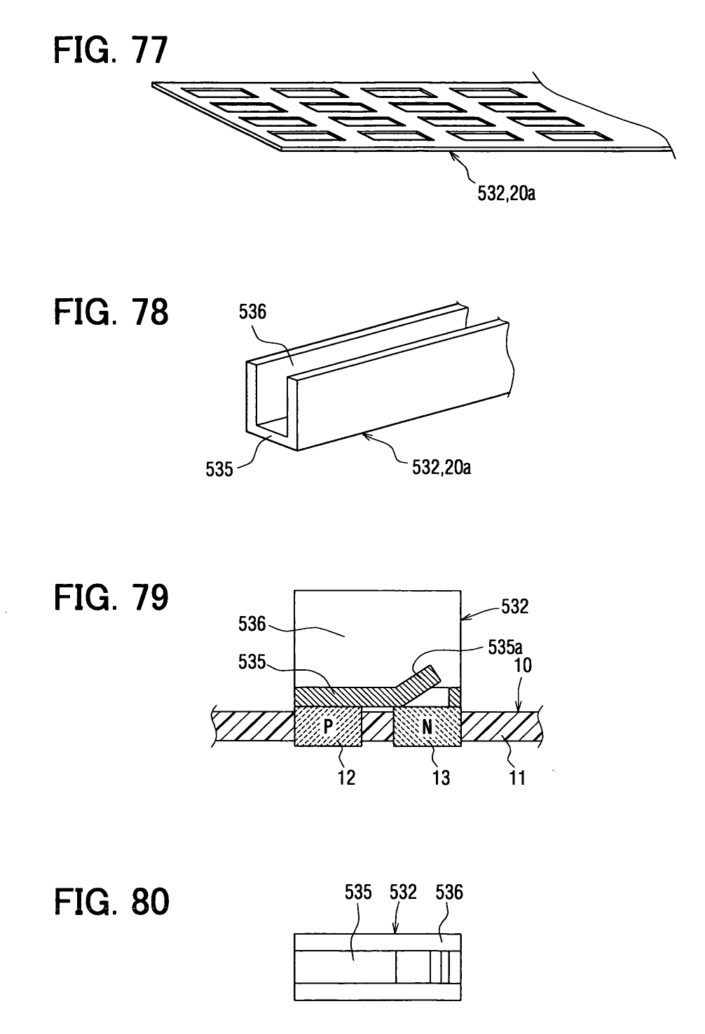

Instead of the pressing process described in the foregoing embodiments, the electrode member 532 may be processed into a predetermined shape by the etching process. The etching process can be performed in the second process-step of the manufacturing process-steps shown in FIG. 65, for example. In the etching process, the material 20a is immersed in an etching tank filled with an etching liquid. For example, the shape shown in FIG. 77 can be obtained by the etching process. In this embodiment, the etching process can be used to form a large number of through holes as fine structure for promoting heat exchange in the heat exchanger portion 536. The material 20a is subjected to the etching process, and then to the pressing process. Through the pressing process the material 20a is subjected to the bending process and the blanking process to provide the electrode member 532 of various types described in the foregoing embodiments.

### Forty-First Embodiment

Instead of the pressing process described in the foregoing embodiments, the electrode member 532 may be processed into a predetermined shape by the extruding process. For example, instead of the first process-step to the third process-step of the manufacturing process-steps shown in FIG. 65, a bracket-type extruded material 20a shown in FIG. 78 is fed. The extruded material 20a is manufactured by a well-known extruding process-step. The extruded material 20a is fed in a rod form. The extruded material 20a is cut to a length required for the electrode member 532. For this cutting, the blanking process by the pressing process may be used.

### Forty-Second Embodiment

FIG. 79 is a sectional view of a thermoelectric converter of a forty-second embodiment. FIG. 80 is a plan view of a heat exchanger portion of the embodiment. In this embodiment, an auxiliary heat exchanger portion 535a is formed in a part of the electrode 535. The auxiliary heat exchanger portion 535a is beveled and raised from the electrode 535 toward the direction of extension of the heat exchanger portion 536. The auxiliary heat exchanger portion 535a is formed such that a space for permitting contact of the leading end of the mount apparatus remains on the rear face of the electrode 535 and also an area for allowing the leading end of the mount apparatus to hold the electrode member 532 remains on the rear face of the plate-shaped electrode 535.

1. A thermoelectric converter comprising:
a thermoelectric element assembly provided with a retaining plate that retains a plurality of P-type thermoelectric elements and a plurality of N-type thermoelectric elements in a predetermined arrangement pattern;
a heat-exchange element assembly provided with a plurality of heat exchange elements and a retaining plate retaining the plurality of the heat exchange elements, the plurality of the heat exchange elements being retained by being mounted in holes drilled in the retaining plate in a predetermined arrangement condition corresponding to an arrangement condition of the plurality of the P-type thermoelectric elements and plurality of the N-type thermoelectric elements; and
a joining member that joins all together a plurality of joining sites between the plurality of the P-type and N-type thermoelectric elements of the thermoelectric element assembly and the plurality of the heat exchange elements of the heat-exchange element assembly in a state in which the thermoelectric element assembly and the heat-exchange element assembly are stacked on each other, wherein
a predetermined gap is formed as a thermal insulating layer between the retaining plate of the thermoelectric element assembly and the retaining plate of the heat-exchange element assembly.

2. A thermoelectric converter according to claim 1, wherein:
the thermoelectric element assembly is provided with a plurality of electrode members making series electrical connection between the plurality of the P-type thermoelectric elements and the plurality of the N-type thermoelectric elements;
each of the plurality of the heat exchange elements is respectively provided to a corresponding one of the plurality of the electrode members; and
the joining member is one of a plurality of joining members, each of which joins between a corresponding one of the plurality of the heat exchange elements and a corresponding one of the plurality of the electrode members.

3. A thermoelectric converter according to claim 1, wherein:
each of the heat exchange elements is provided with an electrode, which makes series electrical connection between the plurality of the P-type thermoelectric elements and the plurality of the N-type thermoelectric elements, and a heat exchanger portion, which extends from the electrode for exchanging heat with a heat exchange medium; and
the joining member joins between the electrode of the heat exchange element, one of the P-type thermoelectric elements, and one of the N-type thermoelectric elements to each other.

4. A thermoelectric converter according to claim 1, wherein:
the heat-exchange element assembly includes a heat-absorbing side heat-exchange element assembly placed in a heat absorbing side and a heat-dissipating side heat-exchange element assembly placed in a heat dissipating side; and
the joining member is provided with a first joining member that joins all together a plurality of joining sites between the thermoelectric element assembly and the heat-absorbing side heat-exchange element assembly in a state in which the thermoelectric element assembly and the heat-absorbing side heat-exchange element assembly are stacked on each other, and a second joining member that joins all together a plurality of joining sites between the thermoelectric element assembly and the heat-dissipating side heat-exchange element assembly in a state in which the thermoelectric element assembly and the heat-dissipating side heat-exchange element assembly are stacked on each other.

5. A thermoelectric converter according to claim 1, wherein:
the retaining plate of the heat-exchange element assembly provides a wall for blocking a flow of a heat exchange medium between a heat absorbing side and a heat dissipating side of the thermoelectric element assembly.

6. A thermoelectric converter according to claim 1, wherein:
the retaining plate of the thermoelectric element assembly provides a wall for blocking a flow of a heat exchange medium between a heat absorbing side and a heat dissipating side of the thermoelectric element assembly.

7. (canceled)

8. A thermoelectric converter according to claim 4, wherein:
the retaining plate of the heat-absorbing side heat-exchange element assembly provides a heat-absorbing-side wall for blocking a flow of a heat exchange medium between the heat absorbing side and the heat dissipating side of the thermoelectric element assembly;
the retaining plate of the heat-dissipating side heat-exchange element assembly provides a heat-dissipating-side wall for blocking a flow of the heat exchange medium between the heat absorbing side and the heat dissipating side of the thermoelectric element assembly; and
a predetermined gap is formed as a thermal insulating layer between the heat-absorbing-side wall and the heat-dissipating-side wall.

9. A thermoelectric converter according to claim 1, wherein:
the heat exchange element has a plate-shaped portion extending in a flow direction of a heat exchange medium;
the heat exchange portion is formed in the plate-shaped portion; and
the hole in the retaining plate, which retains the heat exchange elements, retains a part of the plate-shaped portion of the heat exchange element, in which the heat exchange portion is not formed, wherein
the heat exchange portion extends outward beyond an aperture width of the hole.

10. A thermoelectric converter according to claim 9, wherein a majority of the plurality of the P-type thermoelectric elements and the plurality of the N-type thermoelectric elements is arranged so as to be connected in series in a flow direction of the heat exchange medium.

11. A thermoelectric converter, comprising:
a thermoelectric element substrate provided with rows of thermoelectric element groups, each of which includes a plurality of P-type thermoelectric elements and a plurality of N-type thermoelectric elements alternately arranged in through holes in a first insulating substrate made of an insulating material;
a heat-absorbing electrode substrate structured in such a way that a plurality of first heat-absorbing electrode members, each of which has a heat-absorbing electrode for making electrical connection between the N-type thermoelectric element and the P-type thermoelectric element which are arranged adjacent to each other, and each of which also has a heat absorbing portion for exchanging heat transferred from the heat-absorbing electrode, is mounted into holes drilled in a second insulating substrate made of an insulating material so as to be arranged in a generally grid form; and
a heat-dissipating electrode substrate structured in such a way that a plurality of first heat-dissipating electrode members, each of which has a heat-dissipating electrode for making electrical connection between the P-type thermoelectric element and the N-type thermoelectric element which are arranged adjacent to each other, and each of which also has a heat dissipating portion for exchanging heat transferred from the heat-dissipating electrode, is mounted into holes drilled in a third insulating substrate made of an insulating material so as to be arranged in a generally grid form, wherein
the thermoelectric element substrate is assembled to be sandwiched between the heat-absorbing electrode substrate and the heat-dissipating electrode substrate such that the heat-absorbing electrode of the heat-absorbing electrode substrate makes connection in series between the N-type thermoelectric element and the P-type thermoelectric element which are arranged adjacent to each other while the heat-dissipating electrode of the heat-dissipating electrode substrate makes connection in series between the P-type thermoelectric element and the N-type thermoelectric element which are arranged adjacent to each other, and predetermined gaps as thermal insulating layers are provided between the second insulating substrate of the heat-absorbing electrode substrate and the first insulating substrate of the thermoelectric element substrate, and between the third insulating substrate of the heat-dissipating electrode substrate and the first insulating substrate of the thermoelectric element substrate.

12. A thermoelectric converter according to claim 11, wherein:
an electrode member, which is made of a plate-shaped electrically-conductive material and makes electrical connection between the adjacent thermoelectric elements, is joined to two end faces of the adjacent thermoelectric elements in the thermoelectric element substrate; and
when the thermoelectric element substrate is assembled to be sandwiched between the heat-absorbing electrode substrate and the heat-dissipating electrode substrate,
the heat-absorbing electrode of the heat-absorbing electrode substrate connects in series the N-type thermoelectric element and the P-type thermoelectric element, arranged adjacent to each other, through the electrode member, and
the heat-dissipating electrode of the heat-dissipating electrode substrate connects in series the P-type thermoelectric element and the N-type thermoelectric element, arranged adjacent to each other, through the electrode member.

13. A thermoelectric converter according to claim 11, wherein:
an electrode member, which is made of a plate-shaped electrically-conductive material and makes electrical connection between the adjacent thermoelectric elements of the thermoelectric element substrate, is joined to an end face of the heat-absorbing electrode in the heat-absorbing electrode substrate;
an electrode member, which is made of a plate-shaped electrically-conductive material and makes electrical connection between the adjacent thermoelectric elements of the thermoelectric element substrate, is joined to an end face of the heat-dissipating electrode in the heat-dissipating electrode substrate;
when the thermoelectric element substrate is assembled to be sandwiched between the heat-absorbing electrode substrate and the heat-dissipating electrode substrate,
the heat-absorbing electrode of the heat-absorbing electrode substrate connects in series the N-type thermoelectric element and the P-type thermoelectric element, arranged adjacent to each other, through the electrode member, and
the heat-dissipating electrode of the heat-dissipating electrode substrate connects in series the P-type thermoelectric element and the N-type thermoelectric element, arranged adjacent to each other, through the electrode member.

14. A thermoelectric converter according to claim 13, wherein:
the second insulating substrate and the third insulating substrate are formed by integral molding in such a way that the electrode member is arranged in a generally grid form and a recessed groove is formed in an end face side of the electrode member;
the heat-absorbing electrode is fitted into the groove and joined to an end face of the electrode member; and
the heat-dissipating electrode is fitted into the groove and joined to an end face of the electrode member.

15. A thermoelectric converter according to claim 11, further comprising:
an electrode member, which is made of a plate-shaped electrically-conductive material and makes electrical connection between the adjacent thermoelectric elements of the thermoelectric element substrate, and
an electrode substrate structured in such a way that a plurality of the electrode members are arranged in a generally grid form in a fourth insulating substrate made of an insulating material, wherein:
when the heat-absorbing electrode substrate, the electrode substrate, the thermoelectric element substrate, the electrode substrate and the heat-dissipating electrode substrate are stacked to combine together,
the heat-absorbing electrode of the heat-absorbing electrode substrate connects in series the N-type thermoelectric element and P-type thermoelectric element, which are adjacent to each other, through the electrode member retained in the fourth insulating substrate, and the heat-dissipating electrode of the heat-dissipating electrode substrate connects in series the adjacent P-type thermoelectric element and N-type thermoelectric element, which are adjacent to each other, through the electrode member retained in the fourth insulating substrate.

16. A thermoelectric converter according to claim 12, wherein:
the electrode member is shaped to have a thickness greater than each of plate thicknesses of the heat-absorbing electrode formed in the first heat-absorbing electrode member and the heat-dissipating electrode formed in the first heat-dissipating electrode member.

17. A thermoelectric converter according to claim 16, wherein each of the heat-absorbing electrode and the heat-dissipating electrode has a plate-thickness of 0.1 to 0.3 mm, but the electrode member has a plate-thickness of at least 0.2 to 0.5 mm, which is thicker than that of each of the heat-absorbing electrode and the heat-dissipating electrode.

18. A thermoelectric converter according to claim 12, wherein:
the electrode member and the heat-absorbing electrode, and the electrode member and the heat-dissipating electrode are joined to each other through insulating coating layers made of an insulating material.

19. A thermoelectric converter according to claim 11, wherein:
in the first insulating substrate a plurality of engagement holes M are formed for alternately arranging the P-type thermoelectric elements and the N-type thermoelectric elements in a generally grid form; and
in the thermoelectric element substrate, before the heat-absorbing electrode substrate and the heat-dissipating electrode substrate are combined, the plurality of the P-type thermoelectric elements and the plurality of the N-type thermoelectric elements are alternately arranged in the engagement holes to form the rows of the thermoelectric element groups.

20. A thermoelectric converter according to claim 11, wherein:
the thermoelectric element substrate is formed by alternately arranging the plurality of the P-type thermoelectric elements each having a rod shape and the plurality of the N-type thermoelectric elements each having a rod shape in a molding die in a generally grid form, then performing a molding process for infusing an insulating material into the molding die to form an uncut thermoelectric element substrate, and then performing a cutting process for cutting the uncut thermoelectric element substrate into plates each having a desired thickness.

21. A thermoelectric converter according to claim 11, wherein:
as a material forming the first insulating substrate, a plurality of sheets having a plurality of grooves extending linearly, in which the P-type thermoelectric elements each having a rod shape and the N-type thermoelectric elements each having a rod shape are alternately arranged, are prepared; and
the thermoelectric element substrate is formed by arranging alternately the P-type thermoelectric elements each having a rod shape and the N-type thermoelectric elements each having a rod shape in the grooves of the material, then integrating the plurality of the sheets of the material, which forms the first insulating substrate, through joining, and then performing a cutting process to form the first insulating substrate having a desired plate-thickness.

22. A thermoelectric converter according to claim 11, wherein:
convex portions each having a protrusion shape are formed on both faces of the thermoelectric element substrate between the P-type thermoelectric element and the N-type thermoelectric element which are adjacent to each other;
fitting portions, which fit with the convex portions, are formed in the heat-absorbing electrode and the heat-dissipating electrode; and
the first heat-absorbing electrode member and the first heat-dissipating electrode member make the fitting portions fit with the convex portions.

23. A thermoelectric converter according to claim 11, wherein:
the heat-absorbing electrode substrate is structured in such a way that an end face of the second insulating substrate is placed near a joining portion of the heat-absorbing electrode; and
the heat-dissipating electrode substrate is structured in such a way that an end face of the third insulating substrate is placed near a joining portion of the heat-dissipating electrode.

24. A thermoelectric converter according to claim 11, wherein:
the heat-absorbing electrode substrate is structured in such a way that one end face of the second insulating substrate is placed to the other end opposite the heat-absorbing electrode; and
the heat-dissipating electrode substrate is structured in such a way that one end face of the third insulating substrate is placed to the other end opposite the heat-dissipating electrode.

25. A thermoelectric converter according to claim 11, wherein:
the thermoelectric element substrate serves as a dividing wall and a casing member is provided to form air duct passages on both sides of the thermoelectric element substrate; and
the casing member covers either the first heat-absorbing electrode members or the first heat-dissipating electrode members.

26. A thermoelectric converter according to claim 11, wherein:
a whole shape of each of the first heat-absorbing electrode member and the first heat-dissipating electrode member is formed in an approximate U shape;
the heat-absorbing electrode of a flat shape or the heat-dissipating electrode of a flat shape is formed on the bottom of the corresponding U shape; and
a molding process is perform to form either a louver shape or an offset shape in a flat face extending outward from the heat-absorbing electrode or the heat-dissipating electrode.

27. A thermoelectric converter according to claim 11, wherein;
to form the first heat-absorbing electrode member and the first heat-dissipating electrode member, a plurality of the heat-absorbing electrodes or a plurality of the heat-dissipating electrodes are linked to be formed in a band shape extending along at least the thermoelectric element groups, and are joined to the second or third insulating substrate; and
then the heat-absorbing electrodes or the heat-dissipating electrodes are electrically insulated from each other.

28. A thermoelectric converter according to claim 11, wherein:
the first heat-absorbing electrode member is constituted of the heat-absorbing electrode formed in a flat-plate shape and a heat-absorbing heat-exchange member exchanging heat generated at the heat-absorbing electrode;
the first heat-dissipating electrode member is constituted of the heat-dissipating electrode formed in a flat-plate shape and a heat-dissipating heat-exchange member exchanging heat generated at the heat-dissipating electrode; and
the heat-absorbing heat-exchange member and the heat-dissipating heat-exchange member are provided on the second or the third insulating substrate to be thermally conductively coupled to the heat-absorbing electrode or the heat-dissipating electrode.

29. A thermoelectric converter according to claim 11, wherein:
the first heat-absorbing electrode member is structured in such a way that the first heat-absorbing electrode member is divided into at least two or more of the heat-absorbing electrodes and the heat absorbing portions, which are formed integrally from a flat-plate-shaped plate material to be disposed as an L shape on the second insulating substrate, and each of the heat-absorbing electrodes is pressed into a substrate hole drilled in the second insulating substrate and then is bent along an end face of the second insulating substrate, whereby each of the heat-absorbing electrodes is formed and the heat-absorbing electrodes are coupled to each other; and
the first heat-dissipating electrode member is structured in such a way that the first heat-dissipating electrode member is divided into at least two or more of the heat-dissipating electrodes and the heat dissipating portions, which are formed integrally from a flat-plate-shaped plate material to be disposed as an L shape on the third insulating substrate, and each of the heat-dissipating electrodes is pressed into a substrate hole drilled in the third insulating substrate and then is bent along an end face of the third insulating substrate, whereby each of the heat-dissipating electrodes is formed and the heat-dissipating electrodes are coupled to each other.

30. A thermoelectric converter according to claim 29, characterized in that wherein:
the plurality of the heat-absorbing electrodes are coupled to each other through a coupling portion when the heat-absorbing electrode and the heat absorbing portion of the first heat-absorbing electrode member are integrally formed; and
the plurality of the heat-dissipating electrodes are coupled to each other through a coupling portion when the heat-dissipating electrode and the heat dissipating portion of the first heat-dissipating electrode member are integrally formed.

31. A thermoelectric converter according to claim 11, wherein:
the heat-absorbing electrode substrate is subjected to a potting process using a sealing material made of a resin material applied to a gap between the outer surface of the first heat-absorbing electrode member and the second insulating substrate.

32. A thermoelectric converter according to claim 11, wherein:
any one of the thermoelectric element substrate, the heat-absorbing electrode substrate, the heat-dissipating electrode substrate and the electrode substrate is made up of a combination of a plurality of segmented units.

33-47. (canceled)

48. A thermoelectric converter according to claim 3, wherein, in the heat exchange element assembly, a joining face between the electrode and both the P-type thermoelectric element and the N-type thermoelectric element is desirably located away from an end face of the retaining plate within a range of a protruding length, which is calculated by adding a plate thickness of the retaining plate of the heat-exchange element assembly to a plate thickness of the electrode, and more desirably is located inwardly relative to the end face of the retaining plate.

49-61. (canceled)
